(19) United States
(12) Patent Application Publication
(10) Pub. No.: US 2026/0032990 A1
(43) Pub. Date: Jan. 29, 2026

(54) SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/342,681

(22) Filed: Sep. 29, 2025

Related U.S. Application Data
(63) Continuation of application No. PCT/JP2024/012558, filed on Mar. 28, 2024.

(30) Foreign Application Priority Data
Mar. 30, 2023 (JP) 2023-056618

(51) Int. Cl. H10D 84/00; H10D 62/10; H10D 62/832

(52) U.S. Cl. CPC H10D 84/144; H10D 62/107; H10D 62/127; H10D 62/8325

(57) ABSTRACT

A semiconductor device includes a chip that has a main surface, a high concentration region of a first conductivity type that is formed in a surface layer portion of the main surface on an inner portion side of the chip, and a low concentration region of the first conductivity type that is formed in the surface layer portion of the main surface on a peripheral edge portion side of the chip, and has an impurity concentration lower than an impurity concentration of the high concentration region.

### CROSS-REFERENCE TO RELATED APPLICATIONS

The present application is a bypass continuation of International Patent Application No. PCT/JP2024/012558 filed on Mar. 28, 2024, which claims priority to Japanese Patent Application No. 2023-056618 filed on Mar. 30, 2023 in the Japan Patent Office, and the entire contents of these applications are hereby incorporated herein by reference.

### BACKGROUND

### 1. Field of the Disclosure

The present disclosure relates to a semiconductor device.

### 2. Description of the Related Art

US2008/0277669A1 discloses a semiconductor device having a termination structure in an outer peripheral region of a drift layer.

### BRIEF DESCRIPTION OF DRAWINGS

FIG. 1 is a plan view illustrating a semiconductor device according to a first embodiment.

FIG. 2 is a cross-sectional view taken along line II-II illustrated in FIG. 1.

FIG. 3 is a cross-sectional view obtained by removing structures other than a chip from the cross-sectional view illustrated in FIG. 2.

FIG. 4 is a plan view illustrating a layout example of a first main surface 3.

FIG. 5 is a plan view illustrating a layout example of a high concentration region and a low concentration region.

FIG. 6 is an enlarged plan view illustrating a main portion of the first main surface.

FIG. 7 is an enlarged plan view illustrating another main portion of the first main surface.

FIG. 8 is a cross-sectional view taken along line VIII-VIII illustrated in FIG. 7.

FIG. 9 is an enlarged cross-sectional view illustrating a main portion of FIG. 8.

FIG. 10 is a cross-sectional view taken along line X-X illustrated in FIG. 7.

FIG. 11 is an enlarged cross-sectional view illustrating a main portion of FIG. 10.

FIG. 12 is a cross-sectional view illustrating a main portion of a semiconductor device according to a second embodiment.

FIG. 13 is a cross-sectional view illustrating a main portion of a semiconductor device according to a third embodiment.

FIG. 14 is a cross-sectional view illustrating a modification example of the semiconductor device illustrated in FIG. 13.

FIG. 15 is a cross-sectional view illustrating a main portion of a semiconductor device according to a fourth embodiment.

FIG. 16 is an enlarged plan view illustrating a main portion of a semiconductor device according to a fifth embodiment.

FIG. 17 is a cross-sectional view taken along line XVII-XVII illustrated in FIG. 16.

FIG. 18 is a plan view illustrating a semiconductor device according to a sixth embodiment.

FIG. 19 is a cross-sectional view taken along line XIX-XIX illustrated in FIG. 18.

FIG. 20 is a cross-sectional view illustrating a semiconductor device according to a seventh embodiment.

FIG. 21 is a cross-sectional view illustrating a semiconductor device according to an eighth embodiment.

FIG. 22 is a cross-sectional view illustrating a semiconductor device according to a ninth embodiment.

FIG. 23 is a cross-sectional view illustrating a modification example of an outer body region.

FIG. 24 is a cross-sectional view illustrating a modification example of a field region.

FIG. 25 is a cross-sectional view illustrating a first modification example of a source pad electrode.

FIG. 26 is a cross-sectional view illustrating a second modification example of the source pad electrode.

### DETAILED DESCRIPTION OF THE PREFERRED EMBODIMENTS

Hereinafter, specific embodiments will be described in detail with reference to attached drawings. The attached drawings are all schematic views and are not strictly illustrated, and relative positional relationships, scales, proportions, angles, etc., thereof do not always match. Identical reference signs are given to corresponding structures among the attached drawings, and duplicate descriptions thereof shall be omitted or simplified. For the structures, whose description has been omitted or simplified, the description given before the omission or simplification shall apply.

When the wording “substantially” is used in the present specification, the wording includes a numerical value (shape) equal to a numerical value (shape) of a comparison target and also includes numerical errors (shape errors) in a range of +10% with the numerical value (shape) of the comparison target as a reference. Although the wordings “first,” “second,” “third,” etc., are used in the following description, these are indicators added to names of respective structures in order to clarify the order of description and are not added with an intention of restricting the names of the respective structures.

In the following description, a “p-type” or an “n-type” is used to indicate a conductivity type of a semiconductor (impurity). However, the “p-type” may be referred to as a “first conductivity type,” and the “n-type” may be referred to as a “second conductivity type.” As a matter of course, the “n-type” may be referred to as a “first conductivity type,” and the “p-type” may be referred to as a “second conductivity type.” The “p-type” is a conductivity type caused by a trivalent element, and the “n-type” is a conductivity type caused by a pentavalent element. The trivalent element is at least one of boron, aluminum, gallium, and indium. The pentavalent element is at least one of nitrogen, phosphorus, arsenic, antimony, and bismuth.

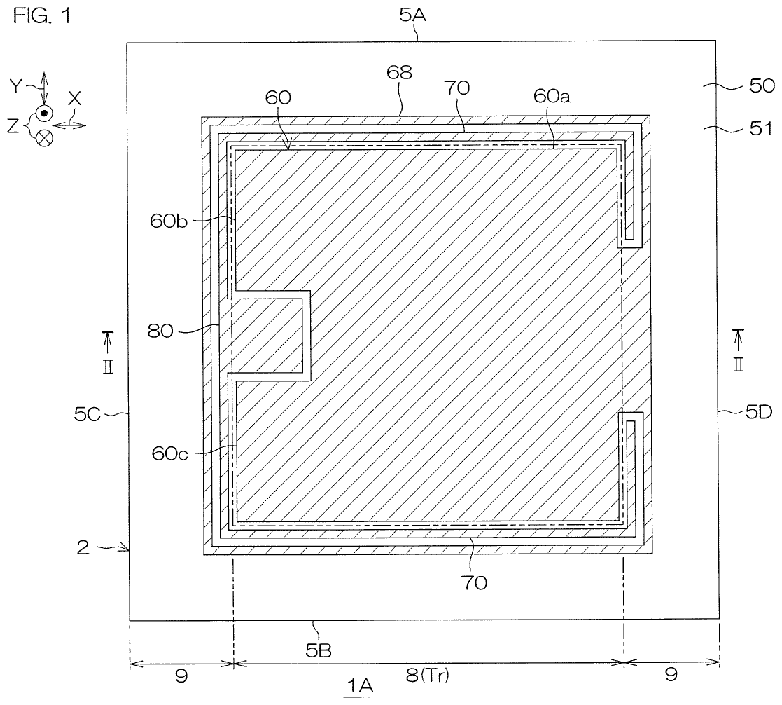

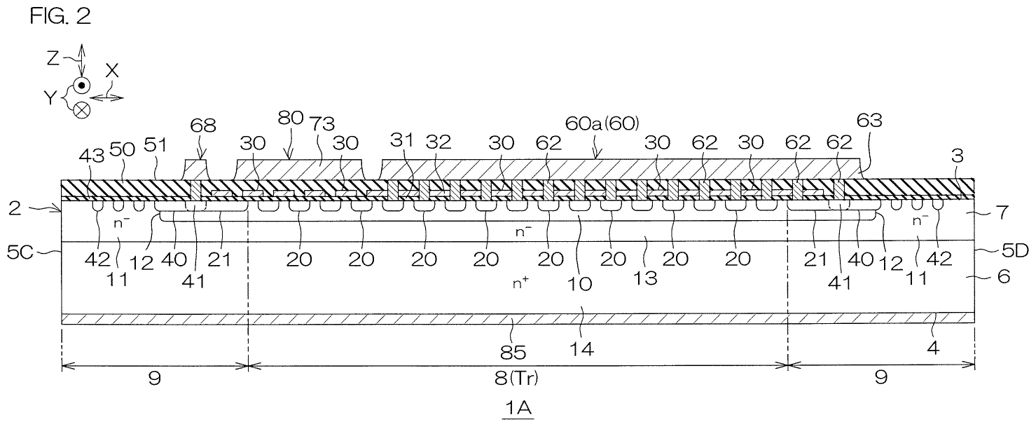

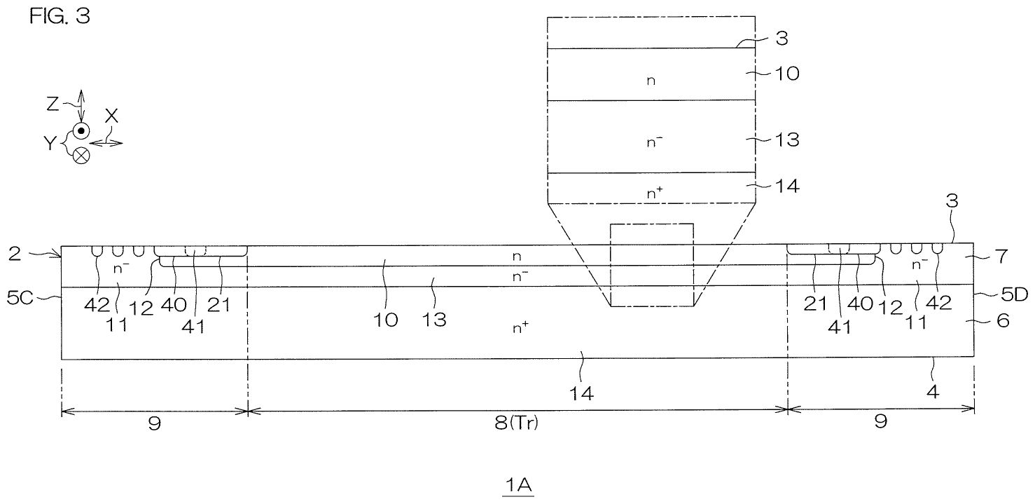

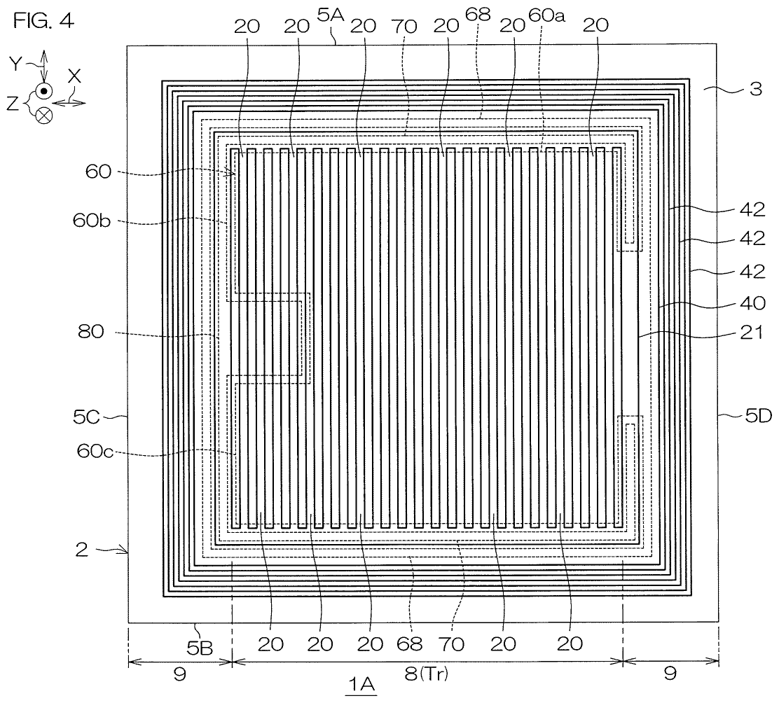

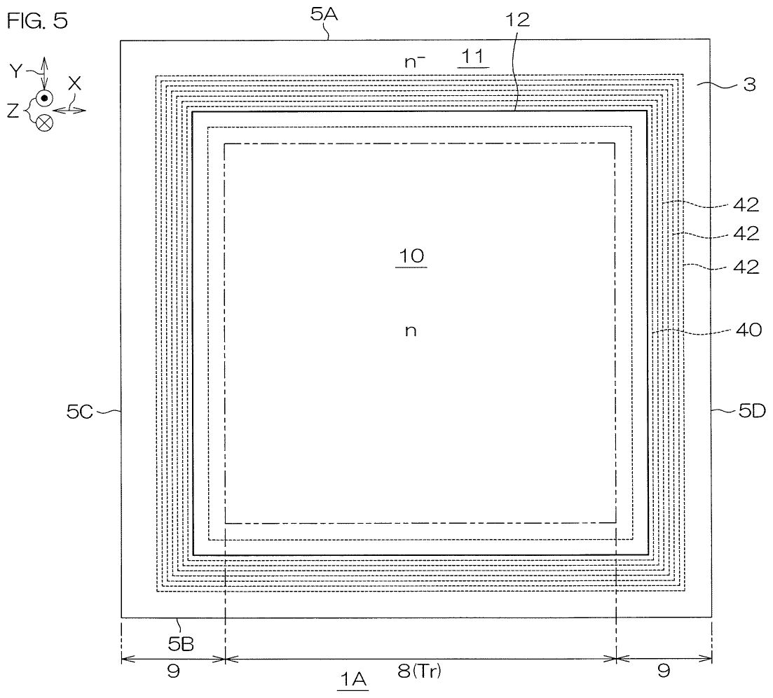

FIG. 1 is a plan view illustrating a semiconductor device 1A according to a first embodiment. FIG. 2 is a cross-sectional view taken along line II-II illustrated in FIG. 1. FIG. 3 is a cross-sectional view obtained by removing structures other than a chip 2 from the cross-sectional view illustrated in FIG. 2. FIG. 4 is a plan view illustrating a layout example of a first main surface 3. FIG. 5 is a plan view illustrating a layout example of a high concentration region 10 and a low concentration region 11.

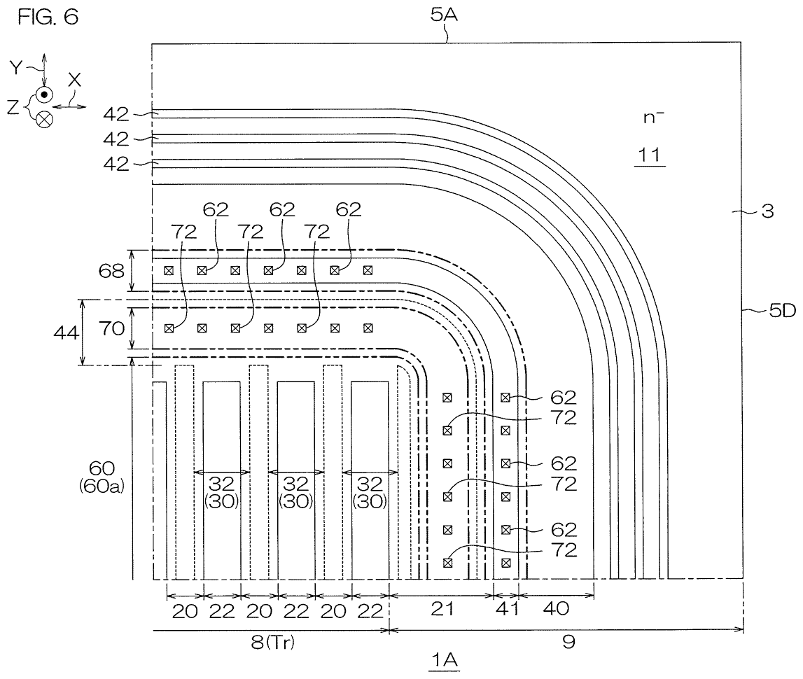

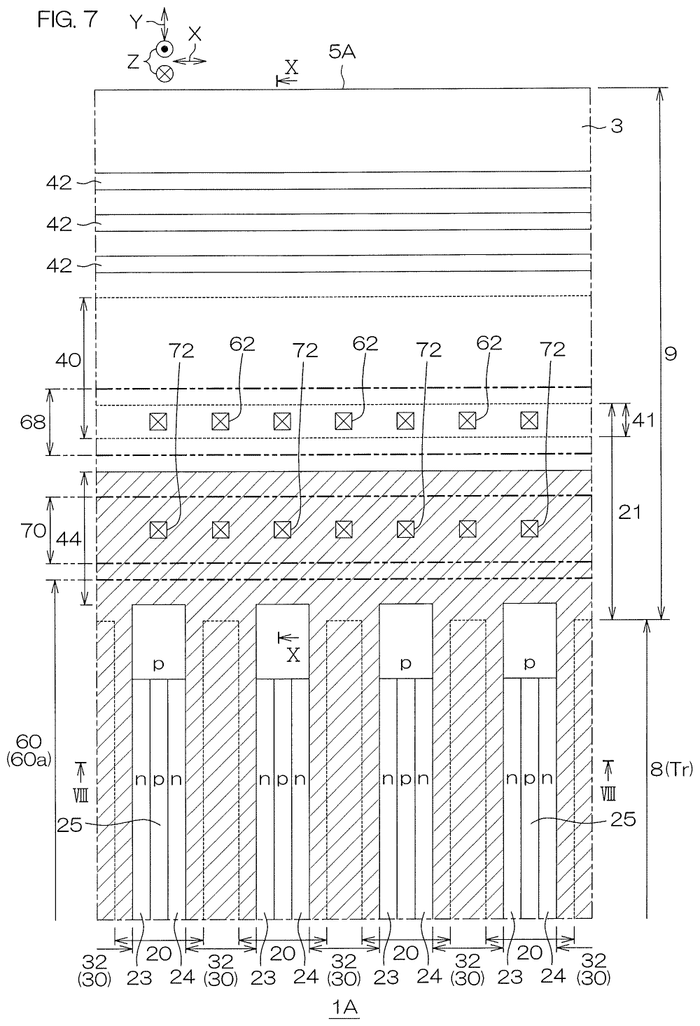

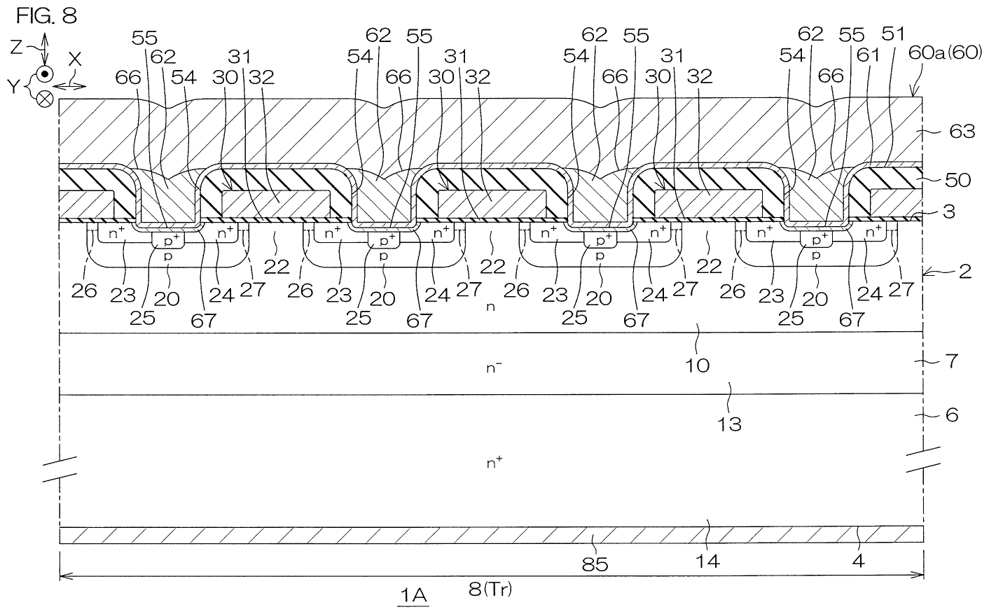

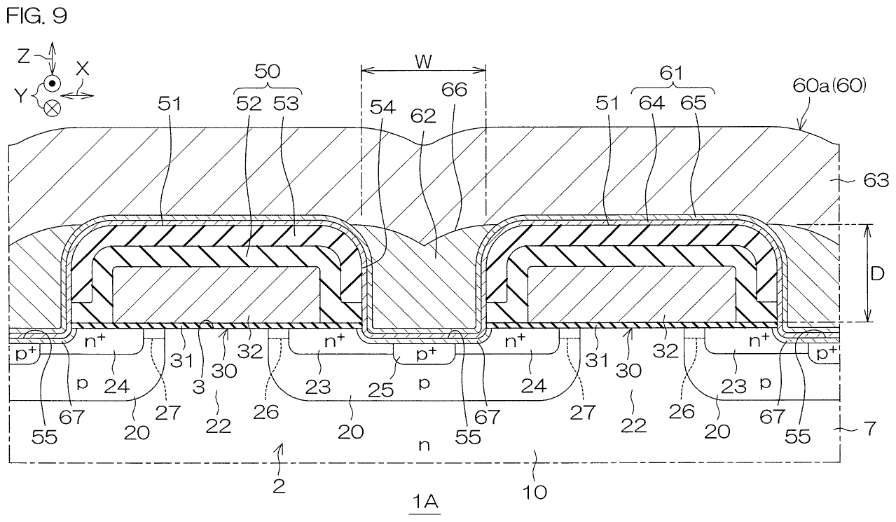

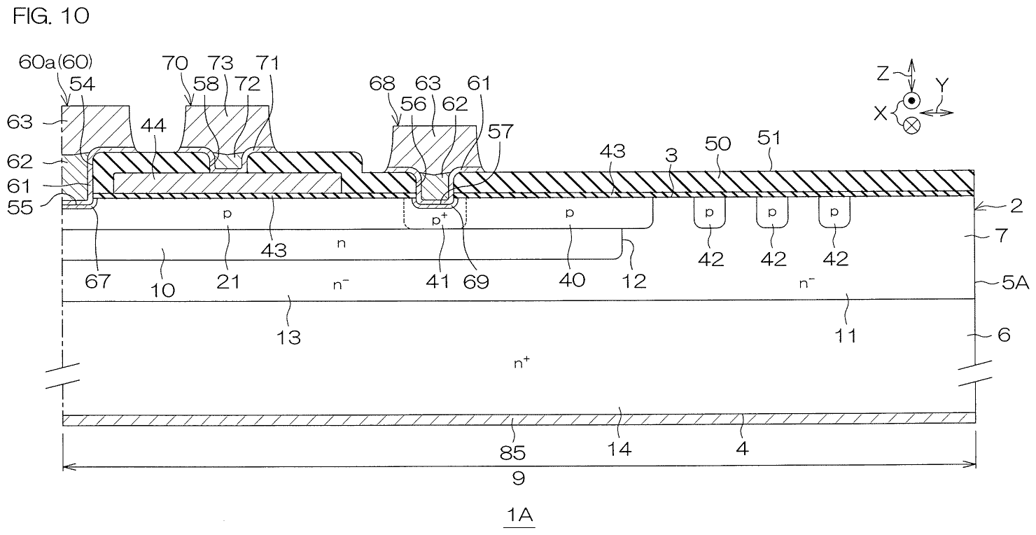

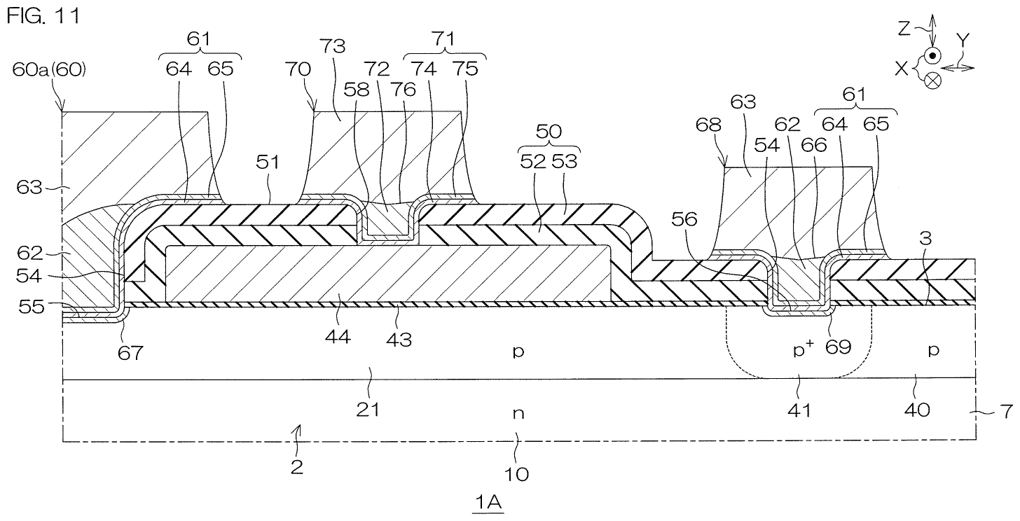

FIG. 6 is an enlarged plan view illustrating a main portion of the first main surface 3. FIG. 7 is an enlarged plan view illustrating another main portion of the first main surface 3. FIG. 8 is a cross-sectional view taken along line VIII-VIII illustrated in FIG. 7. FIG. 9 is an enlarged cross-sectional view illustrating a main portion of FIG. 8. FIG. 10 is a cross-sectional view taken along line X-X illustrated in FIG. 7. FIG. 11 is an enlarged cross-sectional view illustrating a main portion of FIG. 10.

Referring to FIG. 1 to FIG. 11, the semiconductor device 1A is a semiconductor switching device having a transistor structure Tr of an insulated-gate-type as an example of a device structure. The transistor structure Tr has a vertical structure. The semiconductor device 1A is an SiC semiconductor device including a chip 2 made of an SiC single crystal. The chip 2 may be referred to as an “SiC chip” or as a “semiconductor chip.”

In this embodiment, the chip 2 is made of an SiC single crystal, which is a hexagonal crystal, and is formed in a rectangular parallelepiped shape. The hexagonal SiC single crystal includes a plurality of types of polytypes including 2 hexagonal (H)-SiC single crystal, 4H-SiC single crystal, 6H-SiC single crystal, and the like. In this embodiment, an example in which the chip 2 is made of 4H-SiC single crystal is described, but the chip 2 may be made of another polytype.

The chip 2 has a first main surface 3 on one side, a second main surface 4 on the other side, and first to fourth side surfaces 5A to 5D connecting the first main surface 3 and the second main surface 4. In a plan view when viewed from a vertical direction Z (hereinafter, referred to simply as “plan view”), the first main surface 3 and the second main surface 4 are formed in quadrangle shapes. The vertical direction Z is also a thickness direction of the chip 2 and a normal direction to the first main surface 3 (the second main surface 4). The first main surface 3 and the second main surface 4 may be formed in a square shape or a rectangular shape in a plan view.

Preferably, the first main surface 3 and the second main surface 4 are formed by c-planes of the SiC single crystal. In this case, preferably, the first main surface 3 is formed by a silicon plane ((0001) plane) of the SiC single crystal, and the second main surface 4 is formed by a carbon plane ((000-1) plane) of the SiC single crystal.

The first side surface 5A and the second side surface 5B extend in a first direction X along the first main surface 3, and oppose each other in a second direction Y intersecting the first direction X along the first main surface 3. Specifically, the second direction Y is orthogonal to the first direction X. The third side surface 5C and the fourth side surface 5D extend in the second direction Y, and oppose each other in the first direction X.

In this embodiment, the first direction X is an m-axis direction ([1-100] direction) of the SiC single crystal, and the second direction Y is an a-axis direction ([11-20] direction) of the SiC single crystal. As a matter of course, the first direction X may be the a-axis direction of the SiC single crystal, and the second direction Y may be the m-axis direction of the SiC single crystal.

The chip 2 (the first main surface 3 and the second main surface 4) has an off angle by being inclined at a predetermined angle in a predetermined off direction with respect to the c-plane of the SiC single crystal. That is, a c-axis ((0001) axis) of the SiC single crystal is inclined by the off angle toward the off direction from the vertical axis. Also, the c-plane of the SiC single crystal is inclined by the off angle with respect to the horizontal plane.

Preferably, the off direction is the a-axis direction (that is, the second direction Y) of the SiC single crystal. The off angle may be larger than 0° and equal to or smaller than 10°. The off angle may have a value in at least one range among a range larger than 0° and equal to or smaller 1°, a range of 1° or larger and 2.5° or smaller, a range of 2.5° or larger and 5° or smaller, a range of 5° or larger and 7.5° or smaller, and a range of 7.5° or larger and 10° or smaller.

Preferably, the off angle is equal to or smaller than 5°. It is particularly preferable that the off angle is in a range of 2° or larger and 4.5° or smaller. The off angle is typically set in a range of 4° +0.1°. This description does not exclude an embodiment in which the off angle is 0° (that is, an embodiment in which the first main surface 3 is a just surface with respect to the c-plane). In this embodiment, the chip 2 has a laminated structure including a first semiconductor

layer 6 and a second semiconductor layer 7. The first semiconductor layer 6 is made of a substrate (SiC substrate) including an SiC single crystal (semiconductor single crystal), and has the off direction and the off angle described above. The first semiconductor layer 6 forms the second main surface 4, and forms a part of the first to fourth side surfaces 5A to 5D.

The first semiconductor layer 6 may have a thickness of 10 μm or thicker and 500 μm or thinner. The thickness of the first semiconductor layer 6 may have a value in at least one range among a range of 10 μm or thicker and 50 μm or thinner, a range of 50 μm or thicker and 100 μm or thinner, a range of 100 μm or thicker and 150 μm or thinner, a range of 150 μm or thicker and 200 μm or thinner, a range of 200 μm or thicker and 300 μm or thinner, a range of 300 μm or thicker and 400 μm or thinner, and a range of 400 μm or thicker and 500 μm or thinner.

The second semiconductor layer 7 is made of an epitaxial layer (SiC epitaxial layer) including an SiC single crystal (semiconductor single crystal), and is laminated on the first semiconductor layer 6. The second semiconductor layer 7 has the off direction and the off angle described above. The second semiconductor layer 7 forms the first main surface 3, and forms a part of the first to fourth side surfaces 5A to 5D. Preferably, the second semiconductor layer 7 has a thickness thinner than the thickness of the first semiconductor layer 6. As a matter of course, the thickness of the second semiconductor layer 7 may be thicker than the thickness of the first semiconductor layer 6.

The thickness of the second semiconductor layer 7 may be in a range of 5 μm or thicker and 50 μm or thinner. The thickness of the second semiconductor layer 7 may have a value in at least one range among a range of 5 μm or thicker and 10 μm or thinner, a range of 10 μm or thicker and 15 μm or thinner, a range of 15 μm or thicker and 20 μm or thinner, a range of 20 μm or thicker and 25 μm or thinner, a range of 25 μm or thicker and 30 μm or thinner, a range of 30 μm or thicker and 35 μm or thinner, a range of 35 μm or thicker and 40 μm or thinner, a range of 40 μm or thicker and 45 μm or thinner, and a range of 45 μm or thicker and 50 μm or thinner.

The semiconductor device 1A includes an active region 8 that is set in the chip 2 (first main surface 3). The active region 8 is set in an inner portion of the chip 2 (first main surface 3). The active region 8 is a region that has a device structure (transistor structure Tr) and in which an output current (drain current) is to be generated.

The active region 8 is set in an inner portion of the chip 2 at an interval from a peripheral edge (the first to fourth side surfaces 5A to 5D) of the chip 2 in a plan view. The active region 8 is set in a polygonal shape (in this embodiment, a quadrangle shape) having four sides parallel to the peripheral edge of the chip 2 in a plan view. Preferably, a planar area of the active region 8 is equal to or larger than 50% and equal to or smaller than 90% of a planar area of the first main surface 3.

The semiconductor device 1A includes an outer peripheral region 9 that is set outside the active region 8 in the chip 2. The outer peripheral region 9 is a region that does not include the device structure (transistor structure Tr). The outer peripheral region 9 is set in peripheral edge portions of the chip 2 (first main surface 3). That is, the outer peripheral region 9 is provided in a region between the peripheral edge of the chip 2 and the active region 8 in a plan view. The outer peripheral region 9 extends in a band shape along the active region 8 in a plan view, and is set in a polygonal round shape (in this embodiment, a quadrangular round shape) that surrounds the active region 8.

The semiconductor device 1A includes an n-type high concentration region 10 that has a

relatively high first impurity concentration and is formed in a surface layer portion of the first main surface 3. A drain potential as a high potential (first potential) is to be applied to the high concentration region 10. The high concentration region 10 may be referred to as a “first region,” a “first drift region,” a “first high concentration drift region,” etc. The first impurity concentration may be 1×10¹⁶ cm⁻³ or higher and 5×10¹⁷ cm⁻³ or lower.

The high concentration region 10 is formed on an inner portion side of the chip 2. Specifically, the high concentration region 10 is formed in the surface layer portion of the first main surface 3 in the active region 8, and extends in a layer shape along the first main surface 3. The high concentration region 10 is formed as a low resistance region (first low resistance region) having a relatively low resistance value in the active region 8. Preferably, the high concentration region 10 is formed in the entire active region 8. The high concentration region 10 may extend to be substantially perpendicular to the first main surface 3 in a cross-sectional view.

In this embodiment, the high concentration region 10 is led out from the active region 8 to the outer peripheral region 9, and has a portion that is located in the surface layer portion of the first main surface 3 in the outer peripheral region 9. The high concentration region 10 is led out from the active region 8 to the outer peripheral region 9 over the entire periphery, and is formed at an interval inwardly from the peripheral edge of the first main surface 3.

Preferably, the high concentration region 10 is formed at an interval inwardly from at least one of the first to fourth side faces 5A to 5D. In this embodiment, the high concentration region 10 is formed at intervals inwardly from entire peripheries of the first to fourth side surfaces 5A to 5D, and has a peripheral edge portion that surrounds the active region 8.

In this embodiment, the high concentration region 10 is formed in the second semiconductor layer 7. For example, the high concentration region 10 may be formed by introducing n-type impurities into the surface layer portion of the second semiconductor layer 7 (for example, the n-type second semiconductor layer 7). The high concentration region 10 is formed at an interval from a bottom portion of the second semiconductor layer 7 toward the first main surface 3 side, and opposes the first semiconductor layer 6 across a portion of the second semiconductor layer 7.

Preferably, the high concentration region 10 is formed at an interval from a depth position of an intermediate portion of the second semiconductor layer 7 toward the first main surface side. That is, preferably, a thickness of the high concentration region 10 is thinner than ½ of the thickness of the second semiconductor layer 7. As a matter of course, the high concentration region 10 may traverse the depth position of the intermediate portion of the second semiconductor layer 7 in the thickness direction. That is, the thickness of the high concentration region 10 may be thicker than ½ of the thickness of the second semiconductor layer 7.

The high concentration region 10 may have a thickness in a range of 0.1 μm or thicker and 5 μm or thinner. The thickness of the high concentration region 10 may have a value in at least one range among a range of 0.1 μm or thicker and 0.5 μm or thinner, a range of 0.5 μm or thicker and 1 μm or thinner, a range of 1 μm or thicker and 1.5 μm or thinner, a range of 1.5 μm or thicker and 2 μm or thinner, a range of 2 μm or thicker and 2.5 μm or thinner, a range of 2.5 μm or thicker and 3 μm or thinner, a range of 3 μm or thicker and 3.5 μm or thinner, a range of 3.5 μm or thicker and 4 μm or thinner, a range of 4 μm or thicker and 4.5 μm or thinner, and a range of 4.5 μm or thicker and 5 μm or thinner.

The semiconductor device 1A includes an n-type low concentration region 11 that has a second impurity concentration lower than the first impurity concentration of the high concentration region 10 and is formed in the surface layer portion of the first main surface 3. The low concentration region 11 may be referred to as a “second region,” a “second drift region,” a “first low concentration drift region,” etc. The second impurity concentration may be in a range of 1×10¹⁵ cm⁻³ or higher and 5×10¹⁶ cm⁻³ or lower.

The low concentration region 11 is formed on the peripheral edge portion side of the chip 2 with respect to the high concentration region 10. Specifically, the low concentration region 11 is formed in the surface layer portion of the first main surface 3 in the outer peripheral region 9, and extends in a layer shape along the first main surface 3. The low concentration region 11 is located in a region between the peripheral edge of the first main surface 3 and the high concentration region 10. The low concentration region 11 is formed as a high resistance region (first high resistance region) having a resistance value higher than that of the high concentration region 10 in the outer peripheral region 9.

The low concentration region 11 extends in a band shape along the high concentration region 10 (active region 8) in a plan view. The low concentration region 11 includes a portion extending in a band shape in the first direction X and a portion extending in a band shape in the second direction Y in a plan view, and defines the high concentration region 10 (active region 8) from a plurality of directions. In this embodiment, the low concentration region 11 is formed in a round shape (specifically, a quadrangular round shape) that surrounds the high concentration region 10 (active region 8) in a plan view.

The low concentration region 11 has an inner edge portion at an inner side of the first main surface 3 and an outer edge portion at a peripheral edge side of the first main surface 3. The inner edge portion of the low concentration region 11 is connected to the peripheral edge portion of the high concentration region 10. Thereby, the low concentration region 11 is electrically connected to the high concentration region 10. In this embodiment, the low concentration region 11 is connected to the high concentration region 10 in the outer peripheral region 9. Preferably, the outer edge portion of the low concentration region 11 is exposed from at least one of the first to fourth side surfaces 5A to 5D. In this embodiment, the outer edge portion of the low concentration region 11 is exposed from all of the first to fourth side surfaces 5A to 5D.

In this embodiment, the low concentration region 11 traverses the depth position of the bottom portion of the high concentration region 10 in the thickness direction, and is formed to be deeper than the high concentration region 10. That is, the low concentration region 11 has a bottom portion that is located below the bottom portion of the high concentration region 10 (on the second main surface 4 side). In the low concentration region 11, a region boundary portion 12 with the high concentration region 10 that extends in the thickness direction of the chip 2 is formed (refer to FIG. 10). In this embodiment, the region boundary portion 12 is formed at an interval from the bottom portion of the low concentration region 11 toward the first main surface 3 side.

The region boundary portion 12 is formed to be substantially perpendicular to the first main surface 3. Specifically, the region boundary portion 12 has an upper end portion, a lower end portion, and an extension portion. The upper end portion is located on the first main surface 3 side. The lower end portion is located on the second main surface 4 side, and is located on substantially the same straight line as the upper end portion in the thickness direction. The extension portion extends to be substantially perpendicular to the first main surface 3 between the upper end portion and the lower end portion.

In this embodiment, the low concentration region 11 is formed in the second semiconductor layer 7. Preferably, the low concentration region 11 may traverse the depth position of the intermediate portion of the second semiconductor layer 7 in the thickness direction. That is, preferably, a thickness of the low concentration region 11 is equal to or thicker than ½ of the thickness of the second semiconductor layer 7. In this embodiment, the low concentration region 11 is formed in the entire thickness range of the second semiconductor layer 7 between the first main surface 3 and the bottom portion of the second semiconductor layer 7 (the first semiconductor layer 6), and is connected to the first semiconductor layer 6.

For example, the high concentration region 10 may be formed by introducing n-type impurities into the surface layer portion of the second semiconductor layer 7 (for example, the n-type second semiconductor layer 7). In this embodiment, the low concentration region 11 is formed using the n-type second semiconductor layer 7, and has a thickness corresponding to the thickness of the second semiconductor layer 7. In this embodiment, the semiconductor device 1A has a single layer structure including the low concentration region 11 in the peripheral edge portion (outer peripheral region 9) of the second semiconductor layer 7.

The semiconductor device 1A includes an n-type inner low concentration region 13 that is formed in a region below the high concentration region 10 in the surface layer portion of the first main surface 3. The inner low concentration region 13 may be referred to as a “third region,” a “third drift region,” a “second low concentration drift region,” etc. The third impurity concentration may be in a range of 1×10¹⁵ cm⁻³ or higher and 5×10¹⁶ cm⁻³ or lower.

The inner low concentration region 13 is formed on an inner portion side of the chip 2 with respect to the low concentration region 11. Specifically, the inner low concentration region 13 is formed in a region below the high concentration region 10 in the active region 8. The inner low concentration region 13 is formed as a high resistance region (second high resistance region) having a resistance value higher than that of the high concentration region 10 in the active region 8. The inner low concentration region 13 extends in a layer shape along the high concentration region 10, and is connected to the high concentration region 10 in the thickness direction. Thereby, the inner low concentration region 13 is electrically connected to the high concentration region 10.

Preferably, the inner low concentration region 13 is formed in the entire region below the high concentration region 10, and is connected to the entire region of the high concentration region 10 in the thickness direction. In this embodiment, the inner low concentration region 13 is formed in the entire region of the active region 8. The inner low concentration region 13 is further led out from the active region 8 to the outer peripheral region 9, and is connected to a region on the bottom portion side of the low concentration region 11 in the outer peripheral region 9.

Thereby, the inner low concentration region 13 is electrically connected to the low concentration region 11. In this embodiment, the inner low concentration region 13 is led out from the active region 8 to the outer peripheral region 9 in the entire periphery, and is connected to an inner edge portion of the low concentration region 11 over the entire periphery. Preferably, the third impurity concentration of the inner low concentration region 13 is substantially equal to the second impurity concentration of the region on the bottom portion side of the low concentration region 11.

In this embodiment, the inner low concentration region 13 is formed in the second semiconductor layer 7. The inner low concentration region 13 is formed in the entire thickness range of the second semiconductor layer 7 between the high concentration region 10 and the bottom portion of the second semiconductor layer 7 (the first semiconductor layer 6), and is connected to the first semiconductor layer 6.

For example, the inner low concentration region 13 may be formed by introducing n-type impurities into the surface layer portion of the second semiconductor layer 7 (for example, the n-type second semiconductor layer 7). In this embodiment, the inner low concentration region 13 is formed using a portion (a region on the bottom portion side) of the n-type second semiconductor layer 7. The semiconductor device 1A has a multilayer structure including the high concentration region 10 and the inner low concentration region 13 in an inner portion of the second semiconductor layer 7 (active region 8).

The semiconductor device 1A includes an n-type base region 14 that is formed in a region (surface layer portion) on the second main surface 4 side in the chip 2. The base region 14 may be referred to as a “fourth region,” a “drain region,” etc. The base region 14 has a fourth impurity concentration higher than the first impurity concentration of the high concentration region 10. The fourth impurity concentration may be in a range of 5×10¹⁷ cm⁻³ or higher and 3×10¹⁹ cm⁻³ or lower.

The base region 14 is formed in a region below the high concentration region 10 on the inner portion side of the chip 2, and is electrically connected to the high concentration region 10. The base region 14 is led out from the region below the high concentration region 10 to a peripheral edge side of the chip 2, and includes a portion that is located in a region below the low concentration region 11. The base region 14 is electrically connected to the low concentration region 11 on the peripheral edge portion side of the chip 2.

That is, the base region 14 includes a portion that is electrically connected to the high concentration region 10 in the active region 8. In this embodiment, the base region 14 is connected to the inner low concentration region 13 in the active region 8, and is electrically connected to the high concentration region 10 via the inner low concentration region 13. Also, the base region 14 is led out from the active region 8 to the outer peripheral region 9, and includes a portion that is electrically connected to the low concentration region 11 in the outer peripheral region 9. The base region 14 is formed as a low resistance region having a relatively low resistance value in both of the active region 8 and the outer peripheral region 9.

The base region 14 extends in a layer shape along the second main surface 4, is exposed from the second main surface 4 of the chip 2, and is exposed from a part of the first to fourth side surfaces 5A to 5D of the chip 2. The base region 14 has a thickness thicker than the thickness of the high concentration region 10, the thickness of the low concentration region 11, and the thickness of the inner low concentration region 13.

In this embodiment, the base region 14 is formed in the first semiconductor layer 6. The base region 14 is formed in the entire thickness range between the lower end of the first semiconductor layer 6 (second main surface 4) and the upper end of the first semiconductor layer 6 (second semiconductor layer 7), and is connected to the second semiconductor layer 7. In this embodiment, the base region 14 is formed using the n-type first semiconductor layer 6, and has a thickness corresponding to the thickness of the first semiconductor layer 6.

The semiconductor device 1A includes a plurality of p-type body regions 20 that are formed in the surface layer portion of the first main surface 3 in the active region 8. The body regions 20 are formed in the surface layer portion of the high concentration region 10. A source potential as a low potential (second potential) different from the high potential (first potential) is to be applied to the body regions 20.

The body regions 20 are arranged at intervals in the first direction X, and are respectively formed in a band shape extending in the second direction Y. That is, the body regions 20 are arranged in a stripe shape extending in the second direction Y. Also, the extension direction of the body regions 20 coincides with the off direction of the SiC single crystal.

The body regions 20 are formed at an interval from the bottom portion of the high concentration region 10 toward the first main surface 3 side, and oppose the inner low concentration region 13 (base region 14) across a portion of the high concentration region 10. Preferably, the body regions 20 are formed at an interval from an intermediate portion of the high concentration region 10 toward the first main surface 3 side. As a matter of course, the body regions 20 may traverse the depth position of the intermediate portion of the high concentration region 10 in the thickness direction. The body regions 20 are exposed from the first main surface 3.

Each of the body regions 20 may have a width of 1 μm or wider and 10 μm or narrower. The width of the body region 20 may have a value in at least one range among a range of 1 μm or wider and 2 μm or narrower, a range of 2 μm or wider and 3 μm or narrower, a range of 3 μm or wider and 4 μm or narrower, a range of 4 μm or wider and 5 μm or narrower, a range of 5 μm or wider and 6 μm or narrower, a range of 6 μm or wider and 7 μm or narrower, a range of 7 μm or wider and 8 μm or narrower, a range of 8 μm or wider and 9 μm or narrower, and a range of 9 μm or wider and 10 μm or narrower. Preferably, the width of the body region 20 is in a range of 2 μm or wider and 5 μm or narrower.

Each of the body regions 20 may have a thickness (depth) of 0.1 μm or thicker and 2.5 μm or thinner. The thickness of the body region 20 may have a value in at least one range among a range of 0.1 μm or thicker and 0.5 μm or thinner, a range of 0.5 μm or thicker and 1 μm or thinner, a range of 1 μm or thicker and 1.5 μm or thinner, a range of 1.5 μm or thicker and 2 μm or thinner, and a range of 2 μm or thicker and 2.5 μm or thinner. Preferably, the thickness of the body region 20 is in a range of 0.5 μm or thicker and 1.5 μm or thinner.

Each of the body regions 20 forms a pn-junction portion (a pn-junction diode, a body diode) with the high concentration region 10. The body regions 20 expand a depletion layer to the high concentration region 10 when a reverse bias voltage is to be applied to the pn-junction portions. The depletion layer extends from the high concentration region 10 side toward the low concentration region 11 side in a horizontal direction along the first main surface 3.

That is, a range of the depletion layer is expanded toward the peripheral edge portion side of the chip 2 by the low concentration region 11. In a case of a device structure having a vertical structure, a lateral withstand voltage is required on the peripheral edge portion side (the outer peripheral region 9 side) of the chip 2. In this respect, according to the low concentration region 11, a withstand voltage on the peripheral edge portion side (the outer peripheral region 9 side) of the chip 2 is increased, and a breakdown voltage is improved.

In this embodiment, the depletion layer extends from the high concentration region 10 to the inner low concentration region 13 in the thickness direction of the chip 2. That is, the range of the depletion layer is expanded by the inner low concentration region 13. In a case of a device structure having a vertical structure, a vertical withstand voltage is required on the inner portion (active region 8) side of the chip 2. In this respect, according to the inner low concentration region 13, a withstand voltage on the inner portion side (active region 8 side) of the chip 2 is increased, and a breakdown voltage is improved.

The semiconductor device 1A includes a p-type outer body region 21 that is formed in the surface layer portion of the first main surface 3 in the outer peripheral region 9. The outer body region 21 are formed in one or both of the surface layer portion of the high concentration region 10 and the surface layer portion of the low concentration region 11. In this embodiment, the outer body region 21 is formed in the surface layer portion of the high concentration region 10.

Preferably, the outer body region 21 has a p-type impurity concentration substantially equal to the p-type impurity concentration of the body region 20. As a matter of course, the p-type impurity concentration of the outer body region 21 may be lower than the p-type impurity concentration of the body region 20, or may be higher than the p-type impurity concentration of the body region 20.

The outer body region 21 is formed at an interval from the peripheral edge (first to fourth side surfaces 5A to 5D) of the first main surface 3 toward the active region 8 side in the surface layer portion of the high concentration region 10, and extends in a band shape along the active region 8. The outer body region 21 includes a portion extending in a band shape in the first direction X and a portion extending in a band shape in the second direction Y in a plan view, and defines the active region 8 from a plurality of directions.

In this embodiment, the outer body region 21 surrounds the active region 8 in a plan view, and is defined in a polygonal round shape (in this embodiment, a quadrangular round shape) having four sides parallel to the peripheral edge of the first main surface 3. That is, the outer body region 21 forms a boundary portion between the active region 8 and the outer peripheral region 9. The outer body region 21 may include an edge portion that connects the portion extending in the first direction X and the portion extending in the second direction Y in an arc shape (preferably, a quarter arc shape) in a plan view (refer to FIG. 6).

The outer body region 21 includes an inner edge portion on the active region 8 side and an outer edge portion on the peripheral edge side of the first main surface 3. The inner edge portion of the outer body region 21 is connected to the body regions 20 in a portion extending in the first direction X. That is, the outer body region 21 is electrically connected to the body regions 20 in the surface layer portion of the high concentration region 10.

An outer edge portion of the outer body region 21 is formed at an interval from the peripheral edge of the high concentration region 10 toward the active region 8 side. That is, the outer edge portion of the outer body region 21 is formed at an interval from the low concentration region 11. Also, the entire region of the outer body region 21 is located in the high concentration region 10. The edge portion of the outer body region 21 is located in the surface layer portion of the high concentration region 10.

Preferably, the outer body region 21 has a width wider than the width of the body region 20. The width of the body region 20 is a width in a direction orthogonal to the extension direction (that is, the first direction X). The width of the outer body region 21 is a width in a direction orthogonal to the extension direction. As a matter of course, the width of the outer body region 21 may be substantially equal to the width of the body region 20, or may be narrower than the thickness of the body region 20.

A ratio of the width of the outer body region 21 to the width of the body region 20 may be 1 or larger and 50 or smaller. The ratio of the width may have a value in at least one range among a range of 1 or larger and 10 or smaller, a range of 10 or larger and 20 or smaller, a range of 20 or larger and 30 or smaller, a range of 30 or larger and 40 or smaller, and a range of 40 or larger and 50 or smaller. Preferably, the ratio of the width is in a range of 10 or larger. Preferably, the ratio of the width is in a range of 20 or larger and 40 or smaller.

The outer body region 21 is formed at an interval from the bottom portion of the high concentration region 10 toward the first main surface 3 side, and opposes the inner low concentration region 13 (base region 14) across a portion of the high concentration region 10. Preferably, the outer body region 21 is formed at an interval from the intermediate portion of the high concentration region 10 toward the first main surface 3 side. As a matter of course, the outer body region 21 may traverse the depth position of the intermediate portion of the high concentration region 10 in the thickness direction. The outer body region 21 are exposed from the first main surface 3.

Preferably, the outer body region 21 has a thickness (depth) substantially equal to the thickness (depth) of the body region 20. As a matter of course, the thickness of the outer body region 21 may be thinner than the thickness of the body region 20, or may be thicker than the thickness of the body region 20.

The outer body region 21 forms a pn-junction portion (a pn-junction diode, a body diode) with the high concentration region 10. The outer body region 21 expands a depletion layer to the high concentration region 10 when a reverse bias voltage is to be applied to the pn-junction portion. The depletion layer of the outer body region 21 is integrated with the depletion layers of the body regions 20, and extends in the horizontal direction and the thickness direction. A range of the depletion layer of the outer body region 21 is expanded toward the peripheral edge portion side of the chip 2 by the low concentration region 11. Thereby, the breakdown voltage is improved on the peripheral edge portion (outer peripheral region 9) side of the chip 2.

In this embodiment, the depletion layer of the outer body region 21 extends from the high concentration region 10 to the inner low concentration region 13 in the thickness direction of the chip 2. That is, the range of the depletion layer of the outer body region 21 is expanded by the inner low concentration region 13. Thereby, the breakdown voltage is improved on the inner portion side (active region 8 side) of the chip 2.

The semiconductor device 1A includes a plurality of n-type surface layer drift regions 22 formed in the surface layer portion of the first main surface 3. The surface layer drift regions 22 are defined in regions between the body regions 20 adjacent to each other in the first direction X in the surface layer portion of the high concentration region 10. Specifically, the surface layer drift regions 22 are defined by the body regions 20 and the outer body region 21 in the surface layer portion of the high concentration region 10.

In this embodiment, each of the surface layer drift regions 22 includes a portion of the high concentration region 10. As a matter of course, the surface layer drift regions 22 may have an n-type impurity concentration higher than the n-type impurity concentration of the high concentration region 10, or may have an n-type impurity concentration lower than the n-type impurity concentration of the high concentration region 10.

The surface layer drift regions 22 are arranged at intervals in the first direction X, and are respectively formed in a band shape extending in the second direction Y. That is, the surface layer drift regions 22 are formed in a stripe shape extending in the second direction Y. Each of the surface layer drift regions 22 forms an n-type (pnp-type) JFET structure with the body regions 20 located on both sides. A JFET resistance component of the JFET structure is reduced by the high concentration region 10.

The surface layer drift regions 22 may have a width of 0.1 μm or wider and 5 μm or narrower. The width of the surface layer drift region 22 may have a value in at least one range among a range of 0.1 μm or wider and 0.5 μm or narrower, a range of 0.5 μm or wider and 1 μm or narrower, a range of 1 μm or wider and 1.5 μm or narrower, a range of 1.5 μm or wider and 2 μm or narrower, a range of 2 μm or wider and 2.5 μm or narrower, a range of 2.5 μm or wider and 3 μm or narrower, a range of 3 μm or wider and 3.5 μm or narrower, a range of 3.5 μm or wider and 4 μm or narrower, a range of 4 μm or wider and 4.5 μm or narrower, and a range of 4.5 μm or wider and 5 μm or narrower.

The semiconductor device 1A includes a plurality of n-type source regions 23 and 24 that are respectively formed in the surface layer portions of the body regions 20. The source regions 23 and 24 have an n-type impurity concentration higher than the n-type impurity concentration of the high concentration region 10. The source potential is to be applied to the source regions 23 and 24.

The source regions 23 and 24 include first source regions 23 located on one side (the third side surface 5C side) in the first direction X and second source regions 24 located on the other side (the fourth side surface 5D side) in the first direction X in the surface layer portions of the body regions 20. In this embodiment, in the first direction X, one first source region 23 is formed on one end side of the body region 20, and one second source region 24 is formed on the other end side of the body region 20.

The first source region 23 is formed at an interval from one end of the body region 20 toward the other end side of the body region 20, and extends in a band shape along the extension direction of the body region 20. The first source region 23 is formed at an interval from the outer body region 21 in the second direction Y. That is, the first source region 23 is not formed in the outer body region 21. The first source region 23 is formed at an interval from the bottom portion of the body region 20 toward the first main surface 3 side, and opposes the high concentration region 10 across a portion of the body region 20.

The second source region 24 is formed at an interval from the first source region 23 toward the other end side of the body region 20. The second source region 24 is formed at an interval from the other end of the body region 20 toward one end side of the body region 20, and extend in a band shape along the extension direction of the body region 20. The second source region 24 is formed at an interval from the outer body region 21 in the second direction Y. That is, the second source region 24 is not formed in the outer body region 21. The second source region 24 is formed at an interval from the bottom portion of the body region 20 toward the first main surface 3 side, and opposes the high concentration region 10 across a portion of the body region 20.

In a case where the first source regions 23 are formed in one body region 20, the first source regions 23 may be formed at intervals in the extension direction of the body region 20. In this case, each of the first source regions 23 may be formed in a band shape extending in the second direction Y. Similarly, in a case where the second source regions 24 are formed in one body region 20, the second source regions 24 may be formed at intervals in the extension direction of the body region 20. In this case, each of the second source regions 24 may be formed in a band shape extending in the second direction Y.

The semiconductor device 1A includes a plurality of p-type contact regions 25 that are respectively formed in the surface layer portions of the body regions 20 in the active region 8. The contact region 25 may be referred to as a “back gate region.” The source potential is to be applied to the contact regions 25. The contact region 25 has a p-type impurity concentration higher than the p-type impurity concentration of the body region 20.

In this embodiment, one contact region 25 is interposed in a region between the first source region 23 and the second source region 24 in the surface layer portion of the corresponding body region 20. The contact regions 25 extend in a band shape along the extension direction of the body region 20 (the source regions 23 and 24).

The contact region 25 is formed at an interval from the outer body region 21 in the second direction Y. That is, the contact region 25 is not formed in the outer body region 21. The contact region 25 is formed at an interval from the bottom portion of the body region 20 toward the first main surface 3 side, and oppose the high concentration region 10 across a portion of the body region 20.

In a case where the contact regions 25 are formed in one body region 20, the contact regions 25 may be formed at intervals in the extension direction of the body region 20. In this case, each of the contact regions 25 may be formed in a band shape extending in the second direction Y.

The semiconductor device 1A includes a plurality of p-type channel regions 26 and 27 that are formed in the surface layer portion of the first main surface 3. The channel regions 26 and 27 are respectively defined in the surface layer portions of the body regions 20 in regions between end portions of the body regions 20 (the surface layer drift regions 22) and peripheral edge of the source regions 23 and 24. In this embodiment, the channel regions 26 and 27 are arranged at intervals in the first direction X, and are respectively formed in a band shape extending in the second direction Y. That is, the channel regions 26 and 27 are arranged in a stripe shape extending in the second direction Y.

The channel regions 26 and 27 include a plurality of first channel regions 26 and a plurality of second channel regions 27. The first channel regions 26 are respectively defined in regions between the one ends (surface layer drift regions 22) of the body regions 20 and the first source regions 23, and form a current path extending in the horizontal direction. The second channel regions 27 are respectively defined in regions between the other ends (surface layer drift regions 22) of the body regions 20 and the second source regions 24, and form a current path extending in the horizontal direction.

The semiconductor device 1A includes a plurality of gate structures 30 of planar-electrode-type that are arranged on the first main surface 3 in the active region 8. The gate structures 30 are arranged at intervals in the first direction X, and are respectively formed in a band shape extending in the second direction Y. That is, the gate structures 30 are arranged in a stripe shape extending in the second direction Y. Also, the extension direction of the gate structures 30 coincides with the off direction of the SiC single crystal.

Each of the gate structures 30 is arranged on at least one of the channel regions 26 and 27. In this embodiment, each of the gate structures 30 is arranged across one surface layer drift region 22 such that the gate structure 30 straddles two adjacent body regions 20, and covers the channel regions 26 and 27.

Specifically, each of the gate structures 30 is arranged to straddle the first source region 23 on one body region 20 side and the second source region 24 on the other body region 20 side, and covers the surface layer drift region 22, the first source region 23, the second source region 24, the first channel region 26, and the second channel region 27.

Hereinafter, a configuration of one gate structure 30 will be described. The gate structure 30 has a laminated structure including an insulating film 31 and a gate electrode 32. The insulating film 31 may include at least one among a silicon oxide film, a silicon nitride film, and a silicon oxynitride film. In this embodiment, the insulating film 31 has a single layer structure including a silicon oxide film. It is particularly preferable that the insulating film 31 includes a silicon oxide film made of an oxide of the chip 2.

The insulating film 31 covers the first main surface 3 in a film shape, and is arranged on at least one of the channel regions 26 and 27. In this embodiment, the insulating film 31 is arranged across one surface layer drift region 22 such that the insulating film 31 straddles two adjacent body regions 20, and covers the channel regions 26 and 27.

Specifically, the insulating film 31 is arranged to straddle the first source region 23 on one body region 20 side and the second source region 24 on the other body region 20 side, and covers the surface layer drift region 22, the first source region 23, the second source region 24, the first channel region 26, and the second channel region 27.

The insulating film 31 partially covers the first source region 23 at an interval from the contact region 25, and exposes a portion of the first source region 23 and the contact region 25 from the first main surface 3. The insulating film 31 partially covers the second source region 24 at an interval from the contact region 25, and exposes a portion of the second source region 24 and the contact region 25 from the first main surface 3.

The insulating film 31 may have a thickness in a range of 10 nm or thicker and 150 nm or thinner. The thickness of the insulating film 31 may have a value in at least one range among a range of 10 nm or thicker and 25 nm or thinner, a range of 25 nm or thicker and 50 nm or thinner, a range of 50 nm or thicker and 75 nm or thinner, a range of 75 nm or thicker and 100 nm or thinner, a range of 100 nm or thicker and 125 nm or thinner, and a range of 125 nm or thicker and 150 nm or thinner. Preferably, the thickness of the insulating film 31 is in a range of 25 nm or thicker and 75 nm or thinner.

The gate electrode 32 is arranged on the insulating film 31, and opposes at least one of the channel regions 26 and 27 across the insulating film 31. A gate potential as a control potential is to be applied to the gate electrode 32. The gate electrode 32 may include either one or both of p-type conductive polysilicon and n-type conductive polysilicon. The conductivity type of the gate electrode 32 is adjusted according to a gate threshold voltage to be achieved.

The gate electrode 32 is formed in a band shape extending in the second direction Y. In this embodiment, the gate electrode 32 is formed at an interval inwardly from both end portions of the insulating film 31 in the first direction X, and exposes the both end portions of the insulating film 31. The gate electrode 32 is arranged on the insulating film 31 across one surface layer drift region 22 such that the gate electrode 32 straddles two adjacent body regions 20, and opposes the channel regions 26 and 27 across the insulating film 31.

Specifically, the gate electrode 32 is arranged to straddle the first source region 23 on one body region 20 side and the second source region 24 on the other body region 20 side, and opposes the surface layer drift region 22, the first source region 23, the second source region 24, the first channel region 26, and the second channel region 27 across the insulating film 31.

The gate electrode 32 controls inversion and non-inversion of the channel regions 26 and 27 in response to the gate potential. When the gate potential is applied to the gate electrode 32, the channel regions 26 and 27 enter into an ON state, and a drain current flows between the high concentration region 10 and the source regions 23 and 24 via the channel regions 26 and 27 (body region 20). As described above, the transistor structure Tr of a planar-gate-type including the high concentration region 10 is formed in the inner portion (active region 8) of the chip 2.

Referring to FIG. 6 to FIG. 11, the semiconductor device 1A includes a p-type terminal region 40 that is formed in the first main surface 3 in the outer peripheral region 9. The terminal region 40 may be referred to as a “well region,” a “terminal well region,” etc. The terminal region 40 is formed in one or both of the surface layer portion of the high concentration region 10 and the surface layer portion of the low concentration region 11 in the outer peripheral region 9. In this embodiment, the terminal region 40 is formed in the surface layer portion of the high concentration region 10 in the outer peripheral region 9.

The terminal region 40 may have a p-type impurity concentration different from the p-type impurity concentration of the body region 20. The p-type impurity concentration of the terminal region 40 may be higher than the p-type impurity concentration of the body region 20. The p-type impurity concentration of the terminal region 40 may be lower than the p-type impurity concentration of the body region 20. As a matter of course, the p-type impurity concentration of the terminal region 40 may be substantially equal to the p-type impurity concentration of the body region 20.

The terminal region 40 may have a p-type impurity concentration different from the p-type impurity concentration of the outer body region 20. The p-type impurity concentration of the terminal region 40 may be higher than the p-type impurity concentration of the outer body region 21. The p-type impurity concentration of the terminal region 40 may be lower than the p-type impurity concentration of the outer body region 21. As a matter of course, the p-type impurity concentration of the terminal region 40 may be substantially equal to the p-type impurity concentration of the outer body region 21.

The terminal region 40 is formed in a region between the peripheral edge of the first main surface 3 and the outer body region 21 at an interval inwardly from the peripheral edge of the first main surface 3. The terminal region 40 extends in a band shape along the outer body region 21 in a plan view. The terminal region 40 includes a portion extending in a band shape in the first direction X and a portion extending in a band shape in the second direction Y in a plan view, and defines the active region 8 from a plurality of directions.

In this embodiment, the terminal region 40 surrounds the outer body region 21 in a plan

view, and is defined in a polygonal round shape (in this embodiment, a quadrangular round shape) having four sides parallel to the peripheral edge of the first main surface 3. The terminal region 40 may include an edge portion that connects the portion extending in the first direction X and the portion extending in the second direction Y in an arc shape (preferably, a quarter arc shape) in a plan view (refer to FIG. 6).

The terminal region 40 is formed at an interval from the bottom portion of the high concentration region 10 toward the first main surface 3 side, and opposes the inner low concentration region 13 across a portion of the high concentration region 10. Preferably, the terminal region 40 is formed at an interval from the intermediate portion of the high concentration region 10 toward the first main surface 3 side. As a matter of course, the terminal region 40 may traverse the depth position of the intermediate portion of the high concentration region 10 in the thickness direction. The terminal region 40 may have a thickness (depth) substantially equal to the thickness (depth) of the outer body region 21. The thickness of the terminal region 40 may be thicker than the thickness of the outer body region 21, or may be thinner than the thickness of the outer body region 21.

The terminal region 40 includes an inner edge portion on the active region 8 side and an outer edge portion on the peripheral edge side of the first main surface 3. The inner edge portion of the terminal region 40 is connected to the outer edge portion of the outer body region 21 in the surface layer portion of the high concentration region 10. Thereby, the terminal region 40 is electrically connected to the outer body region 21. That is, in this embodiment, the terminal region 40 is electrically connected to the body regions 20 via the outer body region 21.

In this embodiment, the inner edge portion of the terminal region 40 is connected to the outer edge portion of the outer body region 21 over the entire periphery. In a case where the terminal region 40 has a p-type impurity concentration substantially equal to the p-type impurity concentration of the outer body region 21, the terminal region 40 may be considered as a portion (lead-out portion) of the outer body region 21.

The terminal region 40 (inner edge portion) includes an overlap region 41 overlapping the outer edge portion of the outer body region 21 in the surface layer portion of the high concentration region 10. The overlap region 41 is a high concentration region including the outer edge portion of the outer body region 21 and the inner edge portion of the terminal region 40. That is, the overlap region 41 includes both of the p-type impurity of the outer body region 21 and the p-type impurity of the terminal region 40, and has a p-type impurity concentration higher than both of the p-type impurity concentration of the outer body region 21 and the p-type impurity concentration of the terminal region 40.

The p-type impurity concentration of the overlap region 41 is higher than the p-type impurity concentration of the body region 20. The p-type impurity concentration of the overlap region 41 may be lower than the p-type impurity concentration of the contact region 25. As a matter of course, the p-type impurity concentration of the overlap region 41 may be higher than the p-type impurity concentration of the contact region 25.

The overlap region 41 extends in a band shape along the outer body region 21 in a plan view. The overlap region 41 includes a portion extending in a band shape in the first direction X and a portion extending in a band shape in the second direction Y in a plan view, and defines the active region 8 from a plurality of directions. In this embodiment, the overlap region 41 is defined in a polygonal round shape (in this embodiment, a quadrangular round shape) having four sides parallel to the peripheral edge of the first main surface 3.

The overlap region 41 may include an edge portion that connects the portion extending in the first direction X and the portion extending in the second direction Y in an arc shape (preferably, a quarter arc shape) in a plan view (refer to FIG. 6). Preferably, a width of the overlap region 41 is wider than the width of the body region 20. As a matter of course, the width of the overlap region 41 may be narrower than the width of the body region 20.

The terminal region 40 forms a pn-junction portion (a pn-junction diode, a body diode) with the high concentration region 10. The terminal region 40 expands a depletion layer to the high concentration region 10 when a reverse bias voltage is to be applied to the pn-junction portion. The depletion layer of the terminal region 40 is integrated with the depletion layers of the body regions 20 and the depletion layer of the outer body region 21, and extends in the horizontal direction and the thickness direction. A range of the depletion layer of the terminal region 40 is expanded toward the peripheral edge portion side of the chip 2 by the low concentration region 11. Thereby, the breakdown voltage is improved on the peripheral edge portion (outer peripheral region 9) side of the chip 2.

In this embodiment, the depletion layer of the terminal region 40 extends from the high concentration region 10 to the inner low concentration region 13 in the thickness direction of the chip 2. The range of the depletion layer of the terminal region 40 is also expanded by the inner low concentration region 13 in the outer peripheral region 9. Thereby, the breakdown voltage is improved on the peripheral edge portion (outer peripheral region 9) side of the chip 2.

Preferably, the outer edge portion of the terminal region 40 traverses the peripheral edge portion of the high concentration region 10, and is located in the low concentration region 11. That is, preferably, the terminal region 40 is located in the surface layer portion of the low concentration region 11 in the outer peripheral region 9, and includes a portion (outer edge portion) that forms a pn-junction portion with the low concentration region 11 (refer to FIG. 10). The edge portion of the outer edge portion of the terminal region 40 is located in the surface layer portion of the low concentration region 11.

According to this configuration, the depletion layer directly extends from the terminal region 40 to the low concentration region 11. Therefore, the range of the depletion layer is appropriately expanded in the peripheral edge portion (outer peripheral region 9) of the chip 2. As a matter of course, the outer edge portion of the terminal region 40 may be formed at an interval from the peripheral edge portion of the high concentration region 10 toward the active region 8 side, and may be located in the high concentration region 10.

The semiconductor device 1A may include a p-type well region (46) having a relatively high concentration instead of the overlap region 41. In this case, the well region (46) has a p-type impurity concentration higher than both of the p-type impurity concentration of the outer body region 21 and the p-type impurity concentration of the terminal region 40. The p-type impurity concentration of the well region (46) is higher than the p-type impurity concentration of the body region 20.

The p-type impurity concentration of the well region (46) may be substantially equal to the p-type impurity concentration of the contact region 25. As a matter of course, the p-type impurity concentration of the well region (46) may be lower than the p-type impurity concentration of the contact region 25, or may be higher than the p-type impurity concentration of the contact region 25.

The well region (46) may be formed in any one or both of the surface layer portion of the outer body region 21 and the surface layer portion of the terminal region 40. Such a configuration is effective in a case where the terminal region 40 has a p-type impurity concentration substantially equal to the p-type impurity concentration of the outer body region 21 and is formed as a portion (lead-out portion) of the outer body region 21.

The semiconductor device 1A includes at least one p-type field region 42 that is formed in the surface layer portion of the first main surface 3 in the outer peripheral region 9. A plurality of field regions 42 may be formed in an electrically floating state. The field regions 42 may be fixed to the source potential.

The number of the field region 42 is arbitrary. The number of the field region 42 may be 1 or more and 20 or less. The number of the field region 42 may have a value in at least one range among a range of 1 or more and 5 or less, a range of 5 or more and 10 or less, a range of 10 or more and 15 or less, and a range of 15 or more and 20 or less. The number of the field region 42 is typically 1 or more and 8 or less. In this embodiment, the semiconductor device 1A includes three field regions 42.

The field regions 42 are formed in the surface layer portion of the low concentration region 11. The field regions 42 are formed in a region between the peripheral edge of the first main surface 3 and the active region 8 at intervals inwardly from the peripheral edge of the first main surface 3. The field regions 42 are formed in a region between the peripheral edge of the first main surface 3 and the outer body region 21.

Specifically, the field regions 42 are arranged at an interval from the high concentration region 10 toward the peripheral edge side of the first main surface 3 in a region between the peripheral edge of the first main surface 3 and the high concentration region 10. More specifically, the field regions 42 are arranged at an interval from the terminal region 40 toward the peripheral edge side of the first main surface 3 in a region between the peripheral edge of the first main surface 3 and the terminal region 40. That is, the field regions 42 are not formed in the high concentration region 10.

The field regions 42 are formed in band shapes extending along the active region 8 (terminal region 40) in a plan view. Each of the field regions 47 includes a portion extending in a band shape in the first direction X and a portion extending in a band shape in the second direction Y. In this embodiment, the field regions 47 are formed in a polygonal round shape (in this embodiment, a quadrangular round shape) surrounding the active region 8 (terminal region 45) in a plan view.

The field regions 42 may include an edge portion that connects the portion extending in the first direction X and the portion extending in the second direction Y in an arc shape (preferably, a quarter arc shape) (refer to FIG. 6). The edge portions of the field regions 42 are located in the surface layer portion of the low concentration region 11. The field regions 42 are formed at an interval from the bottom portion of the low concentration region 11 toward the first main surface 3 side, and oppose the base region 14 across a portion of the low concentration region 11.

The field regions 42 are formed at an interval from the depth position of the bottom portion of the high concentration region 10 toward the first main surface 3 side. Preferably, the field regions 42 are formed at an interval from the depth position of the intermediate portion of the high concentration region 10 toward the first main surface 3 side. As a matter of course, the field regions 42 may traverse the depth position of the intermediate portion of the high concentration region 10 in the thickness direction.

Each of the field regions 42 forms a pn-junction portion (a pn-junction diode) with the low concentration region 11. Each of the field regions 42 expands a depletion layer toward the low concentration region 11 when a reverse bias voltage is applied. The depletion layers of the field regions 42 are integrated with the depletion layer of the terminal region 40, and extend in the horizontal direction and the thickness direction. A range of the depletion layer of each of the field regions 42 is expanded by the low concentration region 11. Thereby, the breakdown voltage is improved on the peripheral edge portion (outer peripheral region 9) side of the chip 2.

According to the low concentration region 11, since the range of the depletion layer is expanded, the number of the field regions 42 can be reduced. Thereby, an arca occupied by the outer peripheral region 9 in the chip 2 is reduced, and an area occupied by the active region 8 in the chip 2 is increased. Therefore, electrical characteristics of the transistor structure Tr (device structure) formed in the active region 8 are improved. Such a configuration is also effective in realizing miniaturization of the chip 2.

The widths, the depths, the intervals, the p-type impurity concentration, etc., of the field regions 42 are arbitrary, and can take various values according to the electric field to be relaxed. The widths of the field regions 42 may be substantially constant, or may be non-uniform. The widths of the field regions 42 may gradually increase toward the peripheral edge side of the first main surface 3. The widths of the field regions 42 may gradually decrease toward the peripheral edge side of the first main surface 3.

The depths of the field regions 42 may be substantially constant, or may be non-uniform. The depths of the field regions 42 may gradually increase toward the peripheral edge side of the first main surface 3. The depths of the field regions 42 may gradually decrease toward the peripheral edge side of the first main surface 3. As a matter of course, the field regions 42 may include a relatively shallow portion and a deep portion that is deeper than the shallow portion. The shallow portion may be formed on the inner side, and the deep portion may be formed on the peripheral edge side. The shallow portion may be formed on the peripheral edge side, and the deep portion may be formed on the inner side.

The intervals of the field regions 42 may be substantially constant, or may be non-uniform. The intervals of the field regions 42 may gradually increase toward the peripheral edge side of the first main surface 3. The intervals of the field regions 42 may gradually decrease toward the peripheral edge side of the first main surface 3.

The p-type impurity concentrations of the field regions 47 may be substantially constant, or may be non-uniform. The p-type impurity concentrations of the field regions 42 may gradually increase toward the peripheral edge side of the first main surface 3. The p-type impurity concentrations of the field regions 42 may gradually decrease toward the peripheral edge side of the first main surface 3.

The p-type impurity concentrations of the field regions 42 may be substantially equal to the p-type impurity concentration of the body region 20 (outer body region 21). The p-type impurity concentrations of the field regions 42 may be higher than the p-type impurity concentration of the body region 20 (outer body region 21), or may be lower than the p-type impurity concentration of the body region 20 (outer body region 21). The p-type impurity concentrations of the field regions 42 may be substantially equal to the p-type impurity concentration of the terminal region 40. The p-type impurity concentrations of the field regions 42 may be higher than the p-type impurity concentration of the terminal region 40, or may be lower than the p-type impurity concentration of the terminal region 40.

The semiconductor device 1A includes an outer peripheral insulating film 43 that covers the first main surface 3 in the outer peripheral region 9. The outer peripheral insulating film 43 may include at least one among a silicon oxide film, a silicon nitride film, and a silicon oxynitride film. In this embodiment, the outer peripheral insulating film 43 has a single layer structure including a silicon oxide film. It is particularly preferable that the outer peripheral insulating film 43 includes a silicon oxide film which is made of an oxide of the chip 2. Preferably, the outer peripheral insulating film 43 is made of the same kind of insulating material as the insulating material of the insulating film 31. Preferably, the outer peripheral insulating film 43 has a thickness substantially equal to the thickness of the insulating film 31.

The outer peripheral insulating film 43 covers the first main surface 3 in a film shape in the outer peripheral region 9. The outer peripheral insulating film 43 collectively covers the high concentration region 10, the low concentration region 11, the outer body region 21, the terminal region 40, and the field regions 42. The outer peripheral insulating film 43 is connected to the insulating films 31 on the active region 8 side. Specifically, the outer peripheral insulating film 51 is integrally formed with the insulating films 31, and forms one insulating film with the insulating films 31.

The semiconductor device 1A includes a gate wiring 44 arranged on the first main surface 3 in the outer peripheral region 9. The gate wiring 44 is selectively drawn onto the first main surface 3, and includes a portion extending in a direction different from the extending direction of the gate electrodes 32. The gate wiring 44 is connected to the gate electrodes 32, and applies a gate signal to the gate electrodes 32. The gate wiring 44 may be referred to as a “second gate electrode,” etc.

The gate wiring 44 may include either one or both of p-type conductive polysilicon and n-type conductive polysilicon. Preferably, the gate wiring 44 has the same conductivity type as the conductivity type of the gate electrode 32.

The gate wiring 44 is arranged on the outer peripheral insulating film 43 at an interval from the peripheral edge of the first main surface 3 toward the active region 8 side in the outer peripheral region 9. Specifically, the gate wiring 44 is arranged at an interval from the low concentration region 11 toward the active region 8 side in a plan view. In this embodiment, the gate wiring 44 is arranged at an interval from the terminal region 40 toward the active region 8 side, and is arranged on a portion of the outer peripheral insulating film 43 that covers the outer body region 21.

That is, the gate wiring 44 opposes the outer body region 21 across the outer peripheral insulating film 43. Also, the gate wiring 44 opposes the high concentration region 10 (the inner low concentration region 13) in the lamination direction, and does not oppose the low concentration region 11 in the lamination direction. The gate wiring 44 may partially oppose the terminal region 40 in the lamination direction.

The gate wiring 44 extends in a band shape along the active region 8 in a plan view. The gate wiring 44 includes a portion extending in a band shape in the first direction X and a portion extending in a band shape in the second direction Y in a plan view, and defines the active region 8 from a plurality of directions. In this embodiment, the gate wiring 44 surrounds the active region 8 in a plan view, and is defined in a polygonal round shape (in this embodiment, a quadrangular round shape) having four sides parallel to the peripheral edge of the first main surface 3. The gate wiring 44 may have an end shape or an endless shape.

In this embodiment, the gate wiring 44 extends in a band shape (in this embodiment, a round shape) along the outer body region 21 in a plan view, and opposes the outer body region 21 across the outer peripheral insulating film 43 in the lamination direction over the entire region in the extension direction. The gate wiring 44 may include an edge portion that connects the portion extending in the first direction X and the portion extending in the second direction Y in an arc shape (preferably, a quarter arc shape) in a plan view (refer to FIG. 6).

The gate wiring 44 is formed to be narrower than the outer body region 21 in a plan view, and is arranged on the outer body region 21 at an interval from the inner edge portion and the outer edge portion of the outer body region 21. That is, in this embodiment, the gate electrodes 32 are led out onto the outer body region 21, and the gate wiring 44 is connected to the gate electrodes 32 on the outer body region 21.

Preferably, a thickness of the gate wiring 44 is substantially equal to the thickness of the gate electrode 32. Preferably, a width of the gate wiring 44 is wider than the width of the gate electrode 32. The width of the gate wiring 44 is a width in a direction orthogonal to the extension direction. For example, the ratio of the width of the gate wiring 44 to the width of the gate electrode 32 may be 1 or larger and 50 or smaller.

The ratio of the width may have a value in at least one range among a range of 1 or larger and 10 or smaller, a range of 10 or larger and 20 or smaller, a range of 20 or larger and 30 or smaller, a range of 30 or larger and 40 or smaller, and a range of 40 or larger and 50 or smaller. The ratio of the width may be 5 or larger. The ratio of the width may be 20 or larger and 40 or smaller. As a matter of course, the width of the gate wiring 44 may be equal to or narrower than the width of the gate electrode 32. The width of the gate wiring 44 may be wider than the width of the outer body region 21.

The semiconductor device 1A includes an interlayer film 50 of insulating property that covers the first main surface 3. The interlayer film 50 may be referred to as an “interlayer insulating film,” an “intermediate insulating film,” etc. The interlayer film 70 has an insulating surface 71 extending along the first main surface 3. The interlayer film 50 collectively covers the active region 8 and the outer peripheral region 9 on the first main surface 3.

The interlayer film 50 covers the gate structures 30 in the active region 8. The interlayer film 50 collectively covers the high concentration region 10, the low concentration region 11, the outer body region 21, the terminal region 40, and the field regions 42 across the outer peripheral insulating film 43 in the outer peripheral region 9. The interlayer film 50 covers the gate wiring 44 in the outer peripheral region 9. The interlayer film 50 is continuous with the first to fourth side surfaces 5A to 5D. The interlayer film 50 may be formed at an interval inwardly from the first to fourth side surfaces 5A to 5D, and expose the peripheral edge portion (low concentration region 11) of the first main surface 3.

In this embodiment, the interlayer film 50 has a laminated structure including a first oxide film 52 (first insulating film) and a second oxide film 53 (second insulating film) laminated in this order from the first main surface 3 side. That is, the interlayer film 50 has an insulating surface 51 formed by the second oxide film 53. The first oxide film 52 has a single layer structure made of a silicon oxide film with no impurity added. The first oxide film 52 may be referred to as a non-doped silicate glass film (NSG). In this embodiment, the first oxide film 52 has a thickness thinner than the thickness of the gate electrode 32. As a matter of course, the thickness of the first oxide film 52 may be thicker than the thickness of the gate electrode 32.

The first oxide film 52 collectively covers the active region 8 and the outer peripheral region 9. The first oxide film 52 collectively covers the gate structures 30 in the active region 8. The first oxide film 52 covers both of the insulating film 31 and the gate electrode 32 of each gate structure 30 in a film shape.

The first oxide film 52 has a portion that covers the insulating film 31 (first main surface 3) in a film shape along the horizontal direction. The first oxide film 52 covers the insulating film 31 at an interval from a height position of the electrode surface (upper end) of the gate electrode 32 toward the insulating film 31 side. The first oxide film 52 has a portion extending in a film shape in the lamination direction along the side wall of the gate electrode 32.

The first oxide film 52 has a portion that covers the electrode surface of the gate electrode 32 in a film shape along the horizontal direction. Preferably, the first oxide film 52 has an arc corner portion that is curved in an arc shape in a portion that covers the corner portion of the gate electrode 32. The arc corner portion may have a center of curvature on the gate electrode 32 side.

The first oxide film 52 collectively covers the high concentration region 10, the low concentration region 11, the outer body region 21, the terminal region 40, and the field regions 42 across the outer peripheral insulating film 43 in the outer peripheral region 9. The first oxide film 52 covers the gate wiring 44 in the outer peripheral region 9.

The first oxide film 52 has a portion that covers the outer peripheral insulating film 43 (first main surface 3) in a film shape along the horizontal direction. The first oxide film 52 covers the outer peripheral insulating film 43 at an interval from a height position of the wiring surface (upper end) of the gate wiring 44 toward the outer peripheral insulating film 43 side. The first oxide film 52 has a portion extending in a film shape in the lamination direction along the side wall of the gate wiring 44.

The first oxide film 52 has a portion that covers the wiring surface of the gate wiring 44 in a film shape along the horizontal direction. Preferably, the first oxide film 52 has an arc corner portion that is curved in an arc shape in a portion that covers the corner portion of the gate wiring 44. The arc corner portion may have a center of curvature on the gate wiring 44 side.

The second oxide film 53 may have a single layer structure made of a silicon oxide film containing phosphorus or a laminated structure including a silicon oxide film containing phosphorus. The silicon oxide film containing phosphorus may contain boron. The silicon oxide film containing phosphorus may be referred to as a phosphorus silicon glass film (PSG film). The silicon oxide film containing both of phosphorus and boron may be referred to as a boron phosphorus silicon glass film (BPSG film).

The second oxide film 53 may have a single layer structure including a PSG film or a BPSG film laminated on the first oxide film 52. The second oxide film 53 may have a laminated structure including a PSG film laminated on the first oxide film 52 and a BPSG film laminated on the PSG film. The second oxide film 53 may have a laminated structure including a BPSG film laminated on the first oxide film 52 and a PSG film laminated on the BPSG film.

In this embodiment, the second oxide film 53 has a single layer structure made of a PSG film as an example. A thickness of the second oxide film 53 may be thicker than the thickness of the first oxide film 52. The second oxide film 53 may have a thickness thinner than the thickness of the first oxide film 52. The thickness of the second oxide film 53 may be thicker than the thickness of the gate electrode 32. The second oxide film 53 may have a thickness thinner than the thickness of the gate electrode 32.

The second oxide film 53 covers the first oxide film 52 in a film shape, and collectively covers the active region 8 and the outer peripheral region 9 across the first oxide film 52. The second oxide film 53 collectively covers the gate structures 30 across the first oxide film 52 in the active region 8. Specifically, the second oxide film 53 covers both of the insulating film 31 and the gate electrode 32 in a film shape across the first oxide film 52.

The second oxide film 53 has a portion that covers the insulating film 31 across the first oxide film 52. The second oxide film 53 extends in a film shape in the lamination direction along the side wall of the gate electrode 32, and has a portion that covers the side wall of the gate electrode 32 across the first oxide film 52. The second oxide film 53 extends in a film shape along the horizontal direction along the electrode surface of the gate electrode 32, and has a portion that covers the electrode surface of the gate electrode 32 across the first oxide film 52. Preferably, the second oxide film 53 has an arc corner portion that is curved in an arc shape in a portion that covers the corner portion of the gate electrode 32. The arc corner portion may have a center of curvature on the gate electrode 32 side.

The second oxide film 53 collectively covers the high concentration region 10, the low concentration region 11, the outer body region 21, the terminal region 40, and the field regions 42 across the outer peripheral insulating film 43 and the first oxide film 52 in the outer peripheral region 9. The second oxide film 53 covers the gate wiring 44 across the first oxide film 52 in the outer peripheral region 9.

The second oxide film 53 has a portion that covers the outer peripheral insulating film 43 across the first oxide film 52. The second oxide film 53 extends in a film shape in the lamination direction along the side wall of the gate wiring 44, and has a portion that covers the side wall of the gate wiring 44 across the first oxide film 52. The second oxide film 53 extends in a film shape in the horizontal direction along the wiring surface of the gate wiring 44, and has a portion that covers the wiring surface of the gate wiring 44 across the first oxide film 52. Preferably, the second oxide film 53 has an arc corner portion that is curved in an arc shape in a portion that covers the corner portion of the gate wiring 44. The arc corner portion may have a center of curvature on the gate wiring 44 side.

The semiconductor device 1A includes a plurality of source openings 54 formed in the interlayer film 50 in the active region 8. The source openings 54 are formed at intervals from the gate electrodes 32 in regions on sides of the gate electrodes 32, and expose the first main surface 3 (chip 2). Specifically, the source openings 54 penetrate the insulating film 31 and the interlayer film 50 in regions between the gate electrodes 32.

The source openings 54 have wall surfaces that penetrate both of the first oxide film 52 and the second oxide film 53 and are defined by both of the first oxide film 52 and the second oxide film 53. Each of the source openings 54 has an opening end defined by the arc corner portion of the interlayer film 50. Each of the source openings 54 exposes the corresponding source regions 23 and 24 and the corresponding contact region 25.

In this embodiment, the source openings 54 are formed at intervals in the first direction X, and are respectively formed in a band shape extending in the second direction Y. That is, the source openings 54 are formed in a stripe shape extending in the second direction Y. The source openings 54 are formed at intervals from the gate wiring 44 in the second direction Y. That is, the source openings 54 are formed in regions surrounded by the gate electrodes 32 and the gate wiring 44.

The source openings 54 may be formed in regions between two gate structures 30 adjacent to each other in the first direction X. In this case, the source openings 54 may be formed at intervals in a line in the second direction Y. Further, in this case, each source opening 54 may be formed in a quadrangular shape (square shape) in a plan view, a rectangular shape extending in the first direction X, a rectangular shape extending in the second direction Y, a hexagonal shape, a circular shape, etc.

The source opening 54 may have a width W of 0.1 μm or wider and 3 μm or narrower. The width W of the source opening 54 may have a value in at least one range among a range of 0.1 μm or wider and 0.25 μm or narrower, a range of 0.25 μm or wider and 0.5 μm or narrower, a range of 0.5 μm or wider and 0.75 μm or narrower, a range of 0.75 μm or wider and 1 μm or narrower, a range of 1 μm or wider and 1.25 μm or narrower, a range of 1.25 μm or wider and 1.5 μm or narrower, a range of 1.5 μm or wider and 1.75 μm or narrower, a range of 1.75 μm or wider and 2 μm or narrower, a range of 2 μm or wider and 2.25 μm or narrower, a range of 2.25 μm or wider and 2.5 μm or narrower, a range of 2.5 μm or wider and 2.75 μm or narrower, and a range of 2.75 μm or wider and 3 μm or narrower. Preferably, the width W of the source opening 54 is in a range of 0.2 μm or wider and 1 μm or narrower.

The source opening 54 may have a depth D of 0.1 μm or deeper and 2 μm or shallower. The depth D of the source opening 54 may have a value in at least one range among a range of 0.1 μm or deeper and 0.25 μm or shallower, a range of 0.25 μm or deeper and 0.5 μm or shallower, a range of 0.5 μm or deeper and 0.75 μm or shallower, a range of 0.75 μm or deeper and 1 μm or shallower, a range of 1 μm or deeper and 1.25 μm or shallower, a range of 1.25 μm or deeper and 1.5 μm or shallower, a range of 1.5 μm or deeper and 1.75 μm or shallower, and a range of 1.75 μm or deeper and 2 μm or shallower. Preferably, the depth D of the source opening 54 is in a range of 0.5 μm or deeper and 1 μm or shallower.

Preferably, the source opening 54 has an aspect ratio D/W of 0.5 or larger and 3 or smaller. The aspect ratio D/W is defined by a ratio of the depth D of the source opening 54 to the width W of the source opening 54. The aspect ratio D/W may have a value in at least one range among a range of 0.5 or larger and 0.75 or smaller, a range of 0.75 or larger and 1 or smaller, a range of 1 or larger and 1.25 or smaller, a range of 1.25 or larger and 1.5 or smaller, a range of 1.5 or larger and 1.75 or smaller, a range of 1.75 or larger and 2 or smaller, a range of 2 or larger and 2.25 or smaller, a range of 2.25 or larger and 2.5 or smaller, a range of 2.5 or larger and 2.75 or smaller, and a range of 2.75 or larger and 3 or smaller.

Preferably, the aspect ratio D/W is larger than 1. That is, preferably, each of the source openings 54 has the depth D deeper than the width W, and is formed in a vertically long shape in a cross-sectional view. According to this configuration, the gate structures 30 are arranged at a narrow pitch. Preferably, the aspect ratio D/W of the vertically-long source opening 54 is larger than 1 and 2 or smaller.

The semiconductor device 1A includes a plurality of source recesses 55 that are respectively formed in portions of the first main surface 3 exposed from the source openings 54. The semiconductor device 1A does not necessarily include the source recess 55. Therefore, a configuration without the source recess 55 may be adopted.

Each of the source recesses 55 has a planar shape that matches the planar shape of the corresponding source opening 54, and is recessed from the first main surface 3 toward the second main surface 4 side. The source recess 55 is formed at an interval from the bottom portion of the corresponding body region 20 toward the first main surface 3 side, and respectively expose the corresponding source regions 23 and 24 and the corresponding contact region 25. Specifically, the source recess 55 is formed at an interval from the bottom portions of the corresponding source regions 23 and 24 (contact regions 25) toward the first main surface 3 side.

The semiconductor device 1A includes at least one (in this embodiment, a plurality of) outer openings 56 formed in the interlayer film 50 in the outer peripheral region 9. The outer openings 56 are formed in a portion of the interlayer film 50 that cover the terminal region 40. The outer openings 56 penetrate the interlayer film 50, and expose the terminal region 40. In this embodiment, the outer openings 56 are formed in a portion of the interlayer film 50 that cover the overlap region 41 of the terminal region 40, and expose the overlap region 41.

The outer openings 56 may expose the outer body region 21 instead of or in addition to the terminal region 40 (overlap region 41). The outer openings 56 have wall surfaces that penetrate both of the first oxide film 52 and the second oxide film 53 and are defined by both of the first oxide film 52 and the second oxide film 53. Each of the outer openings 56 has an opening end defined by the arc corner portion of the interlayer film 50.

The outer openings 56 are formed at intervals along the terminal region 40 (overlap region 41) (refer to FIG. 6 and FIG. 7). The outer openings 56 may be formed in a quadrangular shape (square shape), a rectangular shape, a hexagonal shape, a circular shape, etc., in a plan view. The outer openings 56 may be formed in a band shape extending along the terminal region 40 (overlap region 41) in a plan view. Similarly to the source opening 54, the outer opening 56 may have the aspect ratio D/W (=0.5 or larger and 3 or smaller, preferably larger than 1).

The semiconductor device 1A may have a single outer opening 56. The single outer opening 56 may be formed in a band shape extending along the terminal region 40 (overlap region 41). The single outer opening 56 may have a portion extending in a band shape in the first direction X and a portion extending in a band shape in the second direction Y in a plan view.

The single outer opening 56 may be formed in a polygonal round shape having four sides parallel to the peripheral edge of the first main surface 3, cither with ends or without ends (in this embodiment, a quadrangular round shape). The single outer opening 56 may have an edge portion that connects a portion extending in the first direction X and a portion extending in the second direction Y along the terminal region 40 (overlap region 41) in a plan view in an arc shape (preferably, a quarter arc shape) (refer to FIG. 6).

The semiconductor device 1A includes a plurality of outer recesses 57 that are respectively formed in portions of the first main surface 3 exposed from the outer openings 56. The semiconductor device 1A does not necessarily include the outer recess 57. Therefore, a configuration without the outer recess 57 may be adopted.

Each of the outer recesses 57 has a planar shape that matches the planar shape of the corresponding outer opening 56, and is recessed from the first main surface 3 toward the second main surface 4 side. The outer recesses 57 are formed at an interval from the bottom portion of the terminal region 40 (overlap region 41) toward the first main surface 3 side, and respectively expose the terminal region 40 (overlap region 41). The outer recess 57 may have a depth substantially equal to the depth of the source recess 55. In a case where the single outer opening 56 is formed, a single outer recess 57 that matches the planar shape of the single outer opening 56 is formed.

The semiconductor device 1A includes at least one (in this embodiment, a plurality of) gate openings 58 formed in the interlayer film 50 in the outer peripheral region 9. The gate openings 58 are formed in a portion of the interlayer film 50 that cover the gate wiring 44. The gate openings 58 penetrate the interlayer film 50, and expose the gate wiring 44. The gate openings 58 have wall surfaces that penetrate both of the first oxide film 52 and the second oxide film 53 and are defined by both of the first oxide film 52 and the second oxide film 53. Each of the gate openings 58 has an opening end defined by the arc corner portion of the interlayer film 50.

The gate openings 58 are formed at an interval along the gate wiring 44 (refer to FIG. 6 and FIG. 7). The gate openings 58 may be formed in a quadrangular shape (square shape), a rectangular shape, a hexagonal shape, a circular shape, etc., in a plan view. The gate openings 58 may be formed in a band shape extending along the gate wiring 44 in a plan view. Similarly to the source opening 54, the gate opening 58 may have the aspect ratio D/W (=0.5 or larger and 3 or smaller, preferably larger than 1).

The semiconductor device 1A may have a single gate opening 58. The single gate opening 58 may be formed in a band shape extending along the gate wiring 44. The single gate opening 58 may have a portion extending in a band shape in the first direction X and a portion extending in a band shape in the second direction Y in a plan view.

The single gate opening 58 may be formed in a polygonal round shape having four sides parallel to the peripheral edge of the first main surface 3, either with ends or without ends (in this embodiment, a quadrangular round shape). The single gate opening 58 may have an edge portion that connects a portion extending in the first direction X and a portion extending in the second direction Y along the gate wiring 44 in a plan view in an arc shape (preferably, a quarter arc shape) (refer to FIG. 6).

Referring to FIG. 1, etc., the semiconductor device 1A includes a source pad electrode 60 arranged on the interlayer film 50. The source pad electrode 60 is a terminal electrode to which the source potential is to be applied from the outside. The source pad electrode 60 may be referred to as a “first pad electrode,” a “first main surface electrode,” a “first terminal electrode,” etc.

The source pad electrode 60 is arranged on a portion of the interlayer film 50 that covers the active region 8. The source pad electrode 60 covers the gate electrodes 32 across the interlayer film 50, and is electrically separated from the gate electrodes 32 by the interlayer film 50. The source pad electrode 60 is electrically connected to the body regions 20, the outer body region 21, the source regions 23 and 24, the contact region 25, etc., via the source openings 54.

In this embodiment, the source pad electrode 60 includes a first pad portion 60a, a second pad portion 60b, and a third pad portion 60c. The first pad portion 60a has a relatively large planar arca, and forms a main body of the source pad electrode 60. In this embodiment, the first pad portion 60a is formed in a polygonal shape (in this embodiment, quadrangular shape) having four sides parallel to the peripheral edge of the chip 2 in a plan view, and is unevenly distributed on the fourth side surface 5D side with respect to a central portion of the active region 8. The first pad portion 60a covers the gate electrodes 32 across the interlayer film 50, and is electrically connected to the body regions 20, etc., via the source openings 54.

The second pad portion 60b has a planar arca smaller than the planar area of the first pad portion 60a, and is led out in a band shape (quadrangular shape) from one end portion (end portion on the first side surface 5A side) of the first pad portion 60a in the second direction Y toward the third side surface 5C side. The second pad portion 60b covers the gate electrodes 32 across the interlayer film 50, and is electrically connected to the body regions 20, etc., via the source openings 54.

The third pad portion 60c has a planar arca smaller than the planar area of the first pad portion 60a, and is led out in a band shape (quadrangular shape) from the other end portion (end portion on the second side surface 5B side) of the first pad portion 60a in the second direction Y toward the third side surface 5C side, and opposes the second pad portion 60b in the second direction Y. The third pad portion 60c covers the gate electrodes 32 across the interlayer film 50, and is electrically connected to the body regions 20, etc., via the source openings 54.

The planar area of the third pad portion 60c may be substantially equal to the planar arca of the second pad portion 60b. As a matter of course, the planar area of the third pad portion 60c may be larger than the planar area of the second pad portion 60b, or may be smaller than the planar area of the second pad portion 60b. Either one or both of the second pad portion 60b and the third pad portion 60c may be used as a terminal portion for current monitoring.

The source pad electrode 60 does not necessarily include both of the second pad portion 60b and the third pad portion 60c at the same time. The source pad electrode 60 may include only one of the second pad portion 60b and the third pad portion 60c. As a matter of course, the source pad electrode 60 may include only the first pad portion 60a, and may not include the second pad portion 60b and the third pad portion 60c.

Referring to FIG. 8 and FIG. 9, the source pad electrode 60 includes a first underlying electrode film 61, a plurality of first embedded electrodes 62, and a first main electrode film 63. The first underlying electrode film 61 may be referred to as a “source underlying electrode film,” the first embedded electrode 62 may be referred to as a “source-embedded electrode,” and the first main electrode film 63 may be referred to as a “source main electrode film.”

The first underlying electrode film 61 forms a lower layer portion of the source pad electrode 60 (the first pad portion 60a, the second pad portion 60b, and the third pad portion 60c), and covers the interlayer film 50 in the active region 8. The first underlying electrode film 61 collectively covers a region of the interlayer film 50 in which the source openings 54 are formed in a film shape, and enters the source openings 54 from above the insulating surface 51.

The first underlying electrode film 61 includes a portion that covers the insulating surface 51 in a film shape and a portion that covers the wall surfaces of the source openings 54 in a film shape. The first underlying electrode film 61 may include a portion that covers the gate wiring 44 across the interlayer film 50. The first underlying electrode film 61 may be formed at an interval inwardly from the gate wiring 44 in a plan view.

In this embodiment, the first underlying electrode film 61 has a laminated structure including a first electrode film 64 laminated on the interlayer film 50 and a second electrode film 65 laminated on the first electrode film 64. In this embodiment, the first electrode film 64 includes a Ti film, and the second electrode film 65 includes a TiN film. The first underlying electrode film 61 does not necessarily have a laminated structure, and may have a single layer structure including one of the first electrode film 64 (Ti film) and the second electrode film 65 (TiN film).

The thickness of the first electrode film 64 may be in a range of 10 nm or thicker and 100 nm or thinner. The thickness of the first electrode film 64 may have a value in at least one range among a range of 10 nm or thicker and 25 nm or thinner, a range of 25 nm or thicker and 50 nm or thinner, a range of 50 nm or thicker and 75 nm or thinner, and a range of 75 nm or thicker and 100 nm or thinner.

The thickness of the second electrode film 65 may be in a range of 50 nm or thicker and 200 nm or thinner. The thickness of the second electrode film 65 may have a value in at least one range among a range of 50 nm or thicker and 75 nm or thinner, a range of 75 nm or thicker and 100 nm or thinner, a range of 100 nm or thicker and 125 nm or thinner, a range of 125 nm or thicker and 150 nm or thinner, a range of 150 nm or thicker and 175 nm or thinner, and a range of 175 nm or thicker and 200 nm or thinner. Preferably, the thickness of the second electrode film 65 is thicker than the thickness of the first electrode film 64.

The first electrode film 64 collectively covers a region of the interlayer film 50 in which the source openings 54 are formed in a film shape, and enters the source openings 54 from above the insulating surface 51. The first electrode film 64 includes a portion that covers the insulating surface 51 in a film shape and a portion that covers the wall surfaces of the source openings 54 in a film shape. The first electrode film 64 directly covers the insulating surface 51 (the second oxide film 53), and opposes the gate electrodes 32 across the interlayer film 50.

The first electrode film 64 covers the arc corner portion in a film shape along the arc corner portion of the interlayer film 50 (second oxide film 53), and enters the source opening 54. The first electrode film 64 includes a portion extending in an arc shape at the arc corner portion. Thereby, the film formability of the first electrode film 64 with respect to the interlayer film 50 (the wall surface of the source opening 54) is improved.

The first electrode film 64 extends along the wall surface of the source opening 54, and covers the insulating film 31, the first oxide film 52, and the second oxide film 53. The first electrode film 64 opposes the side wall of the gate electrode 32 across the interlayer film 50. The first electrode film 64 covers the first main surface 3 in a film shape at a bottom portion of each source opening 54, and is electrically connected to the first main surface 3. Specifically, the first electrode film 64 includes a portion that covers the source recess 55 in a film shape at the bottom portion of each source opening 54, and is electrically connected to the source regions 23 and 24 and the contact region 25.

The first electrode film 64 may be formed at an interval from a height position of the first main surface 3 toward the bottom portion side of the source recess 55, and cover the source recess 55 in a film shape. The first electrode film 64 may include a portion that is located on the bottom portion side of the source recess 55 with respect to the height position of the first main surface 3, and a portion that is located on the insulating film 31 side with respect to the height position of the first main surface 3.

The second electrode film 65 collectively covers a region of the interlayer film 50 which is arranged on the first electrode film 64 and in which the source openings 54 are formed in a film shape. The second electrode film 65 includes a portion that covers the insulating surface 51 in a film shape across the first electrode film 64 and a portion that covers the wall surfaces of the source openings 54 in a film shape with the first electrode film 64.

The second electrode film 65 opposes the gate electrodes 32 across the first electrode film 64 and the interlayer film 50 in a portion that covers the insulating surface 51. The second electrode film 65 covers the arc corner portion of the interlayer film 50 (second oxide film 53) in a film shape along the first electrode film 64, and enters the source opening 54. The second electrode film 65 includes a portion extending in an arc shape at the arc corner portion of the interlayer film 50. Thereby, the film formability of the second electrode film 65 with respect to the interlayer film 50 (the wall surface of the source opening 54) is improved.

The second electrode film 65 extends along the wall surface of the source opening 54, and covers the insulating film 31, the first oxide film 52, and the second oxide film 53 across the first electrode film 64. The second electrode film 65 opposes the side wall of the gate electrode 32 across the first electrode film 64 and the interlayer film 50. The second electrode film 65 includes a portion that covers the source recess 55 in a film shape at the bottom portion of each source opening 54 across the first electrode film 64, and is electrically connected to the source regions 23 and 24 and the contact region 25 via the first electrode film 64.

In a case where the first electrode film 64 is located on the bottom portion side of the source recess 55 with respect to the first main surface 3, the second electrode film 65 may include a portion that is located in the source recess 55. In a case where the first electrode film 64 includes a portion that is located above the first main surface 3, the entire second electrode film 65 is located above the source recess 55.

The first embedded electrodes 62 form an intermediate layer portion of the source pad electrode 60 (the first pad portion 60a, the second pad portion 60b, and the third pad portion 60c), and are respectively embedded in the source openings 54. The first embedded electrode 62 includes a conductive material different from the conductive material of the first underlying electrode film 61. The first embedded electrode 62 includes at least one of tungsten, molybdenum, a tungsten alloy, and a molybdenum alloy. In this embodiment, the first embedded electrode 62 includes tungsten.

In this embodiment, the first embedded electrodes 62 are respectively embedded in a one-to-one correspondence relationship with the source openings 54 via the single first underlying electrode film 61. The first embedded electrodes 62 are electrically connected to the first main surface 3 (chip 2) in the source openings 54. Specifically, the first embedded electrode 62 is electrically connected to the source regions 23 and 24 and the contact region 25 via the first underlying electrode film 61. Hereinafter, the configuration of one first embedded electrode 62 will be described.

The first embedded electrode 62 has a first embedded electrode surface 66 exposed from the source opening 54, and exposes the insulating surface 51. The first embedded electrode surface 66 may be referred to as a “source-embedded electrode film.” The first embedded electrode 62 is embedded in the source opening 54 at an interval from the insulating surface 51 toward the first main surface 3 side, and exposes a portion of the first underlying electrode film 61 (the second electrode film 65) that covers the insulating surface 51.

The first embedded electrode 62 covers the first oxide film 52 and the second oxide film 53 across the first underlying electrode film 61. The first embedded electrode 62 opposes the side wall of the gate electrode 32 in the horizontal direction. In a case where the first underlying electrode film 61 is located on the bottom portion side of the source recess 55 with respect to the first main surface 3, the first embedded electrode 62 may include a portion that is located in the source recess 55. In a case where the first underlying electrode film 61 includes a portion that is located above the first main surface 3, the entire first embedded electrode 62 is located above the source recess 55.

The first embedded electrode surface 66 is located on the first main surface 3 side from the insulating surface 51, and does not include a portion that opposes the electrode surface of the gate electrode 32 across the interlayer film 50 in the lamination direction (vertical direction Z). In this embodiment, the first embedded electrode surface 66 includes a portion that covers the arc corner portion of the interlayer film 50 across the first underlying electrode film 61.

As a matter of course, the first embedded electrode surface 66 may be located below the arc corner portion of the interlayer film 50. The first embedded electrode surface 66 is located on the insulating surface 51 side with respect to the height position of the first oxide film 52. Preferably, the first embedded electrode surface 66 is located above the electrode surface of the gate electrode 32.

The first embedded electrode surface 66 has a recess that is recessed toward the first main surface 3 (chip 2) side at a central portion. Preferably, a bottom portion of the recess is located on the insulating surface 51 side with respect to the height position of the electrode surface of the gate electrode 32. As a matter of course, a portion (for example, the recess) or the whole of the first embedded electrode surface 66 may be located below the electrode surface of the gate electrode 32. A portion (for example, the recess) or the whole of the first embedded electrode surface 66 may be located on the insulating surface 51 side with respect to the height position of the first oxide film 52.

The first main electrode film 63 forms an upper layer portion of the source pad electrode 60 (the first pad portion 60a, the second pad portion 60b, and the third pad portion 60c), and covers the first underlying electrode film 61 and the first embedded electrodes 62 in a film shape. The first main electrode film 63 includes a conductive material different from the conductive material of the first underlying electrode film 61 and the conductive material of the first embedded electrode 62.

The second principal electrode film 122 may include at least one of an Al film, an Al alloy film, a Cu film, and a Cu alloy film. The Al alloy film may include at least one of an AlSi alloy film, an AlCu alloy film, and an AlSiCu alloy film. The first main electrode film 63 has a thickness thicker than the thickness (total thickness) of the first underlying electrode film 61. The first main electrode film 63 has a thickness thicker than the thickness of the first embedded electrode 62.

The thickness of the first main electrode film 63 may be in a range of 0.5 μm or thicker and 5 μm or thinner. The thickness of the first main electrode film 63 may have a value in at least one range among a range of 0.5 μm or thicker and 1 μm or thinner, a range of 1 μm or thicker and 1.5 μm or thinner, a range of 1.5 μm or thicker and 2 μm or thinner, a range of 2 μm or thicker and 2.5 μm or thinner, a range of 2.5 μm or thicker and 3 μm or thinner, a range of 3 μm or thicker and 3.5 μm or thinner, a range of 3.5 μm or thicker and 4 μm or thinner, a range of 4 μm or thicker and 4.5 μm or thinner, and a range of 4.5 μm or thicker and 5 μm or thinner.

The first main electrode film 63 is mechanically and electrically connected to the first underlying electrode film 61 in a portion that covers the insulating surface 51, and opposes the gate electrodes 32 across the first underlying electrode film 61 and the interlayer film 50. The first main electrode film 63 is mechanically and electrically connected to the first embedded electrodes 62 in a portion that covers the source openings 54. Thereby, the first main electrode film 63 is electrically connected to the body regions 20, the outer body region 21, the source regions 23 and 24, the contact region 25, etc., via both of the first underlying electrode film 61 and the first embedded electrodes 62.

The first main electrode film 63 is connected to the first embedded electrode surface 66 with respect to the height position of the insulating surface 51 to the height position of the first main surface 3 side. The first main electrode film 63 includes a portion that covers the recess of the first embedded electrode surface 66. The first main electrode film 63 may include a portion that covers the arc corner portion of the interlayer film 50 across the first underlying electrode film 61.

The first main electrode film 63 is connected to the first embedded electrode surface 66 above the height position of the first oxide film 52. In this embodiment, the first main electrode film 63 is connected to the first embedded electrode surface 66 above the electrode surface of the gate electrode 32. That is, the first main electrode film 63 does not include a portion that opposes the gate electrode 32 in the horizontal direction. In a case where the first embedded electrode surface 66 is located below the height position of the electrode surface of the gate electrode 32 or the height position of the first oxide film 52, the first main electrode film 63 may include a portion that opposes the gate electrode 32 in the horizontal direction.

The film formability of the first main electrode film 63 with respect to the source openings 54 is improved by the first embedded electrodes 62. Thereby, a current path between the first main surface 3 and the first main electrode film 63 is appropriately secured. Such a configuration is effective in suppressing film formation defects caused by the source openings 54 and reducing wiring resistance.

The semiconductor device 1A includes a plurality of first silicide portions 67 that are respectively formed in surface portions of portions of the first main surface 3 that are exposed from the source openings 54. The first silicide portions 67 are formed in a film shape along wall surfaces (side walls and bottom walls) of the source recesses 55, and are mechanically and electrically connected to the first underlying electrode film 61. That is, the first silicide portions 67 are formed in the surface layer portions of the body regions 20, and electrically connect the first embedded electrodes 62 to the body regions 20 via the first underlying electrode film 61.

The first silicide portion 67 may include at least one among Ti silicide, Ni silicide, Co silicide, Mo silicide, and W silicide. Preferably, the first silicide portion 67 is made of Ti silicide, Ni silicide, or Co silicide.

The semiconductor device 1A includes a source finger electrode 68 that is led out from the source pad electrode 60 onto the outer peripheral region 9. The source finger electrode 68 transmits the source potential to be applied to the source pad electrode 60 to the outer peripheral region 9. In this embodiment, the source finger electrode 68 is drawn from a portion of the source pad electrode 60 (first pad portion 60a) on the fourth side surface 5D side onto a portion of the interlayer film 50 that covers the outer peripheral region 9.

The source finger electrode 68 is led out above the terminal region 40. In this embodiment, the source finger electrode 68 is formed at an interval from the low concentration region 11 toward the active region 8 side in a plan view, and opposes the high concentration region 10 (inner low concentration region 13) in the lamination direction. The source finger electrode 68 does not oppose the low concentration region 11 in the lamination direction. As a matter of course, the source finger electrode 68 may be led out from a region on the high concentration region 10 to a region on the low concentration region 11, and may not include a portion that opposes the low concentration region 11 in the lamination direction.

The source finger electrode 68 is electrically connected to the terminal region 40 via the outer openings 56. Specifically, the source finger electrode 68 is electrically connected to the overlap region 41 of the terminal region 40 via the outer openings 56. The source finger electrode 68 extends in a band shape along the terminal region 40 (overlap region 41). The source finger electrode 68 includes a portion extending in a band shape in the first direction X and a portion extending in a band shape in the second direction Y in a plan view.

In this embodiment, the source finger electrode 68 is formed in a polygonal round shape (in this embodiment, a quadrangular round shape) having four sides parallel to the peripheral edge of the first main surface 3, and surrounds the source pad electrode 60. The source finger electrode 68 may include an edge portion that connects the portion extending in the first direction X and the portion extending in the second direction Y in an arc shape (preferably, a quarter arc shape) in a plan view (refer to FIG. 6).

Similarly to the source pad electrode 60, the source finger electrode 68 includes the first underlying electrode film 61, the plurality of first embedded electrodes 62, and the first main electrode film 63. The first underlying electrode film 61 forms a lower layer portion of the source finger electrode 68, and covers the interlayer film 50 in the outer peripheral region 9. The first underlying electrode film 61 collectively covers a region of the interlayer film 50 in which the outer openings 56 are formed in a film shape, and enters the outer openings 56 from above the insulating surface 51. The first underlying electrode film 61 includes a portion that covers the insulating surface 51 in a film shape and a portion that covers the wall surfaces of the outer openings 56 in a film shape.

Similarly to the source pad electrode 60, the first underlying electrode film 61 has a laminated structure including the first electrode film 64 and the second electrode film 65. The first electrode film 64 collectively covers a region of the interlayer film 50 in which the outer openings 56 are formed in a film shape, and enters the outer openings 56 from above the insulating surface 51. The first electrode film 64 includes a portion that covers the insulating surface 51 in a film shape and a portion that covers the wall surfaces of the outer openings 56 in a film shape.

The first electrode film 64 covers the arc corner portion in a film shape along the arc corner portion of the interlayer film 50 (second oxide film 53), and enters the outer opening 56. The first electrode film 64 includes a portion extending in an arc shape at the arc corner portion. Thereby, the film formability of the first electrode film 64 with respect to the interlayer film 50 (the wall surface of the outer opening 56) is improved. The first electrode film 64 extends along the wall surface of the outer opening 56, and covers the outer peripheral insulating film 43, the first oxide film 52, and the second oxide film 53.

The first electrode film 64 covers the first main surface 3 in a film shape at a bottom portion of each outer opening 56, and is electrically connected to the first main surface 3 (chip 2). Specifically, the first electrode film 64 includes a portion that covers the outer recess 57 in a film shape at the bottom portion of each outer opening 56, and is electrically connected to the terminal region 40 (overlap region 41) in the outer recess 57.

The first electrode film 64 may be formed at an interval from a height position of the first main surface 3 toward the bottom portion side of the outer recess 57, and cover the outer recess 57 in a film shape. The first electrode film 64 may include a portion that is located on the bottom portion side of the outer recess 57 with respect to the height position of the first main surface 3, and a portion that is located on the outer peripheral insulating film 43 side with respect to the height position of the first main surface 3.

The second electrode film 65 collectively covers a region of the interlayer film 50 which is arranged on the first electrode film 64 and in which the outer openings 56 are formed in a film shape. The second electrode film 65 includes a portion that covers the insulating surface 51 in a film shape across the first electrode film 64 and a portion that covers the wall surfaces of the outer openings 56 in a film shape with the first electrode film 64.

The second electrode film 65 covers the arc corner portion of the interlayer film 50 (second oxide film 53) in a film shape along the first electrode film 64, and enters the outer opening 56. The second electrode film 65 includes a portion extending in an arc shape at the arc corner portion of the interlayer film 50 (second oxide film 53). Thereby, the film formability of the second electrode film 65 with respect to the interlayer film 50 (the wall surface of the outer opening 56) is improved. The second electrode film 65 extends along the wall surface of the outer opening 56, and covers the outer peripheral insulating film 43, the first oxide film 52, and the second oxide film 53 across the first electrode film 64.

The second electrode film 65 includes a portion that covers the outer recess 57 in a film shape across the first electrode film 64 at the bottom portion of each outer opening 56, and is electrically connected to the terminal region 40 (overlap region 41) via the first electrode film 64. In a case where the first electrode film 64 is located on the bottom portion side of the outer recess 57 with respect to the first main surface 3, the second electrode film 65 may include a portion that is located in the outer recess 57. In a case where the first electrode film 64 includes a portion that is located above the first main surface 3, the entire second electrode film 65 is located above the outer recess 57.

The first embedded electrodes 62 form a middle layer portion of the source finger electrode 68, and are respectively embedded in the outer openings 56. In this embodiment, the first embedded electrodes 62 are respectively embedded in a one-to-one correspondence relationship with the outer openings 56 via the single first underlying electrode film 61. The first embedded electrodes 62 are electrically connected to the terminal region 40 (overlap region 41) via the first underlying electrode film 61.

The first embedded electrode 62 has a first embedded electrode surface 66 exposed from the outer opening 56, and exposes the insulating surface 51. Specifically, the first embedded electrode 62 is embedded in the outer opening 56 at an interval from the insulating surface 51 toward the first main surface 3 side, and exposes a portion of the first underlying electrode film 61 (the second electrode film 65) that covers the insulating surface 51. That is, the first embedded electrode surface 66 is located on the first main surface 3 side from the insulating surface 51.

The first embedded electrode 62 covers the first oxide film 52 and the second oxide film 53 across the first underlying electrode film 61. The first embedded electrode 62 includes a portion that covers the arc corner portion of the interlayer film 50 across the first underlying electrode film 61. The first embedded electrode 62 may be embedded at an interval from the arc corner portion of the interlayer film 50 toward the outer peripheral insulating film 43 side, and expose the entire region of the arc corner portion. The first embedded electrode surface 66 is located on the insulating surface 51 side with respect to the height position of the first oxide film 52 in the outer opening 56. As a matter of course, the first embedded electrode surface 66 may be located on the outer peripheral insulating film 43 side with respect to the height position of the first oxide film 52.

In a case where the first underlying electrode film 61 is located on the bottom portion side of the outer recess 57 with respect to the first main surface 3, the first embedded electrode 62 may include a portion that is located in the outer recess 57. In a case where the first underlying electrode film 61 includes a portion that is located above the first main surface 3, the entire first embedded electrode 62 is located above the outer recess 57.

The first main electrode film 63 forms an upper layer portion of the source finger electrode 68, and covers the first underlying electrode film 61 and the first embedded electrodes 62 in a film shape. The first main electrode film 63 is mechanically and electrically connected to the first underlying electrode film 61 in a portion that covers the insulating surface 51, and is mechanically and electrically connected to the first embedded electrodes 62 in a portion that covers the outer openings 56. The first main electrode film 63 is electrically connected to the terminal region 40 (overlap region 41) via the first underlying electrode film 61 and the first embedded electrodes 62.

The first main electrode film 63 is connected to the first embedded electrode surface 66 with respect to the height position of the insulating surface 51 to the height position of the first main surface 3 side. The first main electrode film 63 is connected to the first embedded electrode surface 66 above the height position of the first oxide film 52. The first main electrode film 63 includes a portion that covers the recess of the first embedded electrode surface 66.

The first main electrode film 63 may include a portion that covers the arc corner portion of the interlayer film 50 across the first underlying electrode film 61. In a case where the first embedded electrode 62 is located below the first oxide film 52, the first main electrode film 63 may be connected to the first embedded electrode 62 in a region below the first oxide film 52.

The film formability of the first main electrode film 63 with respect to the outer openings 56 is improved by the first embedded electrodes 62. Thereby, a current path between the terminal region 40 (overlap region 41) and the first main electrode film 63 is appropriately secured. Such a configuration is effective in suppressing film formation defects caused by the outer openings 56 and reducing wiring resistance.

The semiconductor device 1A includes a plurality of second silicide portions 69 that are respectively formed in surface portions of portions of the first main surface 3 that are exposed from the outer openings 56. The second silicide portions 69 are formed in a film shape along wall surfaces (side walls and bottom walls) of the outer recesses 57, and are mechanically and electrically connected to the first underlying electrode film 61. That is, the second silicide portions 69 are formed in the surface layer portion of the terminal region 40 (overlap region 41), and electrically connect the first embedded electrodes 62 to the terminal region 40 (overlap region 41) via the first underlying electrode film 61.

The second silicide portion 69 may include at least one among Ti silicide, Ni silicide, Co silicide, Mo silicide, and W silicide. Preferably, the second silicide portion 69 is made of Ti silicide, Ni silicide, or Co silicide. It is particularly preferable that the second silicide portion 69 is made of the same type of silicide as the first silicide portion 67.

The semiconductor device 1A includes a gate finger electrode 70 that is selectively drawn onto the interlayer film 50. The gate finger electrode 70 transmits the gate potential to the gate wiring 44. The gate finger electrode 70 is drawn onto a portion of the interlayer film 50 that covers the gate wiring 44 (that is, on the outer peripheral region 9), and is electrically connected to the gate wiring 44 via the gate openings 58.

The gate finger electrode 70 is arranged in a region between the source pad electrode 60 and the source finger electrode 68 at an interval from the source pad electrode 60 and the source finger electrode 68. The gate finger electrode 70 extends in a band shape along the gate wiring 44. The gate finger electrode 70 includes a portion extending in a band shape in the first direction X and a portion extending in a band shape in the second direction Y in a plan view.

In this embodiment, the gate finger electrode 70 is formed in a band shape with ends that has four sides parallel to the peripheral edge of the first main surface 3, and surrounds the source pad electrode 60. The gate finger electrode 70 may include an edge portion that connects the portion extending in the first direction X and the portion extending in the second direction Y in an arc shape (preferably, a quarter arc shape) in a plan view (refer to FIG. 6). The gate finger electrode 70 has a pair of open ends through which the source finger electrode 68 pass on the fourth side surface 5D side.

Referring to FIG. 10 and FIG. 11, the gate finger electrode 70 includes a second underlying electrode film 71, at least one (in this embodiment, a plurality of) second embedded electrodes 72, and a second main electrode film 73. The second underlying electrode film 71 may be referred to as a “gate underlying electrode film,” the second embedded electrode 72 may be referred to as a “gate embedded electrode,” and the second main electrode film 73 may be referred to as a “gate main electrode film.”

The second underlying electrode film 71 forms a lower layer portion of the gate finger electrode 70, and covers the interlayer film 50 in the outer peripheral region 9. The second underlying electrode film 71 collectively covers a region of the interlayer film 50 in which the gate openings 58 are formed in a film shape, and enters the gate openings 58 from above the insulating surface 51. The second underlying electrode film 71 includes a portion that covers the insulating surface 51 in a film shape and a portion that covers the wall surfaces of the gate openings 58 in a film shape.

The second underlying electrode film 71 has a laminated structure including a first electrode film 74 laminated on the interlayer film 50 and a second electrode film 75 laminated on the first electrode film 74. Preferably, the first electrode film 74 includes the same type of conductive material as the first electrode film 64 on the source side, and the second electrode film 75 includes the same type of conductive material as the second electrode film 65 on the source side. In this embodiment, the first electrode film 74 includes a Ti film, and the second electrode film 75 includes a TiN film.

The second underlying electrode film 71 does not necessarily have a laminated structure, and may have a single layer structure including one of the first electrode film 74 (Ti film) and the second electrode film 75 (TiN film). The first electrode film 74 may have a thickness substantially equal to the thickness of the first electrode film 64 on the source side. The second electrode film 75 may have a thickness substantially equal to the thickness of the second electrode film 65 on the source side.

The first electrode film 74 collectively covers a region of the interlayer film 50 in which the gate openings 58 are formed in a film shape, and enters the gate openings 58 from above the insulating surface 51. That is, the first electrode film 74 includes a portion that covers the insulating surface 51 in a film shape and a portion that covers the wall surfaces of the gate openings 58 in a film shape.

The first electrode film 74 covers the arc corner portion in a film shape along the arc corner portion of the interlayer film 50 (second oxide film 53), and enters the gate opening 58. The first electrode film 74 includes a portion extending in an arc shape at the arc corner portion. Thereby, the film formability of the first electrode film 74 with respect to the interlayer film 50 (the wall surface of the gate opening 58) is improved.

The first electrode film 74 extends along the wall surface of the gate opening 58, and covers the first oxide film 52 and the second oxide film 53. The first electrode film 74 covers the gate wiring 44 in a film shape at the bottom portion of each gate opening 58, and is electrically connected to the gate wiring 44.

The second electrode film 75 collectively covers a region of the interlayer film 50 which is arranged on the first electrode film 74 and in which the gate openings 58 are formed in a film shape. That is, the second electrode film 75 includes a portion that covers the insulating surface 51 in a film shape across the first electrode film 74 and a portion that covers the wall surfaces of the gate openings 58 in a film shape across the first electrode film 74.

The second electrode film 75 covers the arc corner portion of the interlayer film 50 (second oxide film 53) in a film shape along the first electrode film 74, and enters the gate opening 58. The second electrode film 75 includes a portion extending in an arc shape at the arc corner portion of the interlayer film 50 (second oxide film 53). Thereby, the film formability of the second electrode film 75 with respect to the interlayer film 50 (the wall surface of the gate opening 58) is improved.

The second electrode film 75 extends along the wall surface of the gate opening 58, and covers the first oxide film 52 and the second oxide film 53 across the first electrode film 74. The second electrode film 75 includes a portion that covers the gate wiring 44 in a film shape across the first electrode film 74 at the bottom portion of each gate opening 58, and is electrically connected to the gate wiring 44 via the first electrode film 74.

The second embedded electrodes 72 form a middle layer portion of the gate finger electrode 70, and are respectively embedded in the gate openings 58. The second embedded electrode 72 includes a conductive material different from the conductive material of the second underlying electrode film 71. The second embedded electrode 72 includes at least one of tungsten, molybdenum, a tungsten alloy, and a molybdenum alloy. Preferably, the second embedded electrode 72 includes the same type of conductive material as the conductive material of the first embedded electrode 62. In this embodiment, the second embedded electrode 72 includes tungsten.

In this embodiment, the second embedded electrodes 72 are respectively embedded in a one-to-one correspondence relationship with the gate openings 58 via the single second underlying electrode film 71. The second embedded electrodes 72 are electrically connected to the gate wiring 44 via the second underlying electrode film 71 in the gate openings 58.

The second embedded electrode 72 has a second embedded electrode surface 76 exposed from the gate opening 58, and exposes the insulating surface 51. The second embedded electrode surface 76 may be referred to as a “gate embedded electrode surface.” The second embedded electrode 72 is embedded in the gate opening 58 at an interval from the insulating surface 51 toward the first main surface 3 side, and exposes a portion of the second underlying electrode film 71 (the second electrode film 75) that covers the insulating surface 51. That is, the second embedded electrode surface 76 is located on the first main surface 3 side from the insulating surface 51.

The second embedded electrode 72 covers the first oxide film 52 and the second oxide film 53 across the second underlying electrode film 71. The second embedded electrode 72 includes a portion that covers the arc corner portion of the interlayer film 50 across the second underlying electrode film 71. The second embedded electrode 72 may be embedded at an interval from the arc corner portion of the interlayer film 50 toward the gate wiring 44 side, and expose the entire region of the arc corner portion. The second embedded electrode surface 76 is located on the insulating surface 51 side with respect to the height position of the first oxide film 52. As a matter of course, the second embedded electrode surface 76 may be located on the gate wiring 44 side with respect to the height position of the first oxide film 52.

The second main electrode film 73 forms an upper layer portion of the gate finger electrode 70, and covers the second underlying electrode film 71 and the second embedded electrodes 72 in a film shape. The second main electrode film 73 includes a conductive material different from the conductive material of the second underlying electrode film 71 and the conductive material of the second embedded electrode 72.

The second main electrode film 73 may include at least one of an Al film, an Al alloy film, a Cu film, and a Cu alloy film. The Al alloy film may include at least one of an AlSi alloy film, an AlCu alloy film, and an AlSiCu alloy film. Preferably, the second main electrode film 73 includes the same type of conductive material as the conductive material of the first main electrode film 63. The second main electrode film 73 may have a thickness substantially equal to the thickness of the first main electrode film 63.

The second main electrode film 73 is mechanically and electrically connected to the second underlying electrode film 71 in a portion that covers the insulating surface 51, and is mechanically and electrically connected to the second embedded electrodes 72 in a portion that covers the gate openings 58. Thereby, the second main electrode film 73 is electrically connected to the gate wiring 44 via the second underlying electrode film 71 and the second embedded electrodes 72.

The second main electrode film 73 is connected to the second embedded electrode 72 at to the height position of the first main surface 3 side with respect to the height position of the insulating surface 51. The second main electrode film 73 is connected to the second embedded electrode surface 76 above the height position of the first oxide film 52. The second main electrode film 73 includes a portion that covers the recess of the second embedded electrode surface 76.

The second main electrode film 73 may include a portion that covers the arc corner portion of the interlayer film 50 across the second underlying electrode film 71. In a case where the second embedded electrode 72 is located below the first oxide film 52, the second main electrode film 73 may be connected to the second embedded electrode 72 in a region below the first oxide film 52.

The film formability of the second main electrode film 73 with respect to the gate openings 58 is improved by the second embedded electrodes 72. Thereby, a current path between the gate wiring 44 and the second main electrode film 73 is appropriately secured. Such a configuration is effective in suppressing film formation defects caused by the gate openings 58 and reducing wiring resistance.

The semiconductor device 1A includes a gate pad electrode 80 that is arranged on the interlayer film 50. The gate pad electrode 80 is a terminal electrode to which the gate potential is to be applied from the outside. The gate pad electrode 80 may be referred to as a “second pad electrode,” a “second main surface electrode,” a “second terminal electrode,” etc. The gate pad electrode 80 is arranged in a region between the source pad electrode 60 and the source finger electrode 68 at an interval from the source pad electrode 60 and the source finger electrode 68.

In this embodiment, the gate pad electrode 80 is arranged in a region on the third side surface 5C side with respect to the first pad portion 60a, and is interposed between the second pad portion 60b and the third pad portion 60c. That is, the gate pad electrode 80 opposes the first pad portion 60a in the first direction X, and opposes the second pad portion 60b and the third pad portion 60c in the second direction Y.

The gate pad electrode 80 is formed in a polygonal shape (in this embodiment, quadrangular shape) having four sides parallel to the peripheral edge of the chip 2 in a plan view. The gate pad electrode 80 has a plane area smaller than a plane area of the source pad electrode 60 (first pad portion 60a). The gate pad electrode 80 may have a plane arca smaller than the plane arca of the second pad portion 60b (third pad portion 60c).

The gate pad electrode 80 is arranged on a portion that covers the active region 8 and the outer peripheral region 9, and is connected to the gate finger electrode 70. The gate pad electrode 80 may cover the gate electrodes 32 across the interlayer film 50, or may cover the gate wiring 44 across the interlayer film 50.

Similarly to the gate finger electrode 70, the gate pad electrode 80 includes the second underlying electrode film 71 and the second main electrode film 73. The second underlying electrode film 71 forms a lower layer portion of the gate pad electrode 80, and covers the interlayer film 50 in a film shape. Similarly to the gate finger electrode 70, the second underlying electrode film 71 has a laminated structure including the first electrode film 74 and the second electrode film 75. The first electrode film 74 covers the interlayer film 50 in a film shape, and the second electrode film 75 covers the first electrode film 74 in a film shape. The second main electrode film 73 forms an upper layer portion of the gate pad electrode 80, and covers the second underlying electrode film 71 in a film shape.

Although not specifically illustrated, the gate pad electrode 80 may include a plurality of second embedded electrodes 72 similarly to the gate finger electrode 70. In this case, similarly to the gate finger electrode 70, the gate pad electrode 80 may be electrically connected to the gate wiring 44 via the second embedded electrodes 72.

In a case where the gate electrodes 32 are arranged below the gate pad electrode 80, the gate pad electrode 80 may be electrically connected to the gate electrodes 32 via the second embedded electrodes 72. As a matter of course, the gate pad electrode 80 may not include the second embedded electrodes 72. That is, the gate pad electrode 80 may not include an electrical connection portion with respect to the gate electrodes 32 and an electrical connection portion with respect to the gate wiring 44 in the region immediately below.

The gate potential to be applied to the gate pad electrode 80 is to be applied to the gate wiring 44 via the gate finger electrode 70. The gate potential is transmitted to the gate electrodes 32 via a wiring path (current path) along the gate wiring 44. Thereby, the gate electrodes 32 are turned on, and on/off of the channel regions 26 and 27 is controlled.

The semiconductor device 1A includes a drain pad electrode 85 that covers the second main surface 4. The drain pad electrode 85 is a terminal electrode to which a drain potential is to be applied from the outside. The drain pad electrode 85 may be referred to as a “third pad electrode,” a “third main surface electrode,” a “third terminal electrode,” etc. The drain pad electrode 85 is electrically connected to the base region 14.

The drain pad electrode 85 includes a portion that opposes the high concentration region 10 (inner low concentration region 13) across the base region 14, and a portion that opposes the low concentration region 11 across the base region 14. The drain pad electrode 85 may cover the entire region of the second main surface 4 such as to be continuous with the peripheral edge (the first to fourth side surfaces 5A to 5D) of the second main surface 4. The drain pad electrode 85 may partially cover the second main surface 4 such as to expose the peripheral edge portions of the second main surface 4.

A breakdown voltage that can be applied between the source pad electrode 60 and the drain pad electrode 85 (between the first main surface 3 and the second main surface 4) may be in a range of 500 V or higher and 3000 V or lower. The breakdown voltage may have a value in at least one range among a range of 500 V or higher and 1000 V or lower, a range of 1000 V or higher and 1500 V or lower, a range of 1500 V or higher and 2000 V or lower, a range of 2000 V or higher and 2500 V or lower, and a range of 2500 V or higher and 3000 V or lower.

As described above, the semiconductor device 1A includes the chip 2, the n-type high concentration region 10, and the n-type low concentration region 11. The chip 2 has the first main surface 3. The high concentration region 10 has a relatively high first impurity concentration, and is formed in the surface layer portion of the first main surface 3 on the inner portion side of the chip 2. The low concentration region 11 has a second impurity concentration lower than the first impurity concentration of the high concentration region 10, and is formed in the surface layer portion of the first main surface 3 on the peripheral edge portion side of the chip 2.

According to this configuration, the semiconductor device 1A having a novel configuration can be provided. According to the semiconductor device 1A, a resistance value on the inner portion side of the chip 2 can be reduced using the high concentration region 10, and a withstand voltage of the peripheral edge portion of the chip 2 can be improved using the low concentration region 11.

Preferably, the chip 2 includes SiC as an example of a wide bandgap semiconductor. In the case of the chip 2 including SiC, an extremely high voltage is to be applied due to characteristics (physical properties) of the chip 2, and a withstand voltage can be reduced due to the electric field in the peripheral edge portion of the chip 2. In this regard, in the case of the semiconductor device 1A, a withstand voltage on the peripheral edge portion side of the chip 2 including SiC is improved using the low concentration region 11.

The chip 2 may have the first to fourth side surfaces 5A to 5D. In this case, the high concentration region 10 may be formed at an interval from at least one of the first to fourth side surfaces 5A to 5D. The low concentration region 11 may be exposed from at least one of the first to fourth side surfaces 5A to 5D. According to this configuration, the formation region of the low concentration region 11 is expanded to a range in which the region is exposed from at least one of the first to fourth side surfaces 5A to 5D. Thereby, the withstand voltage of the peripheral edge portion of the chip 2 is appropriately improved.

Preferably, the low concentration region 11 extends in a band shape along the high concentration region 10 in a plan view. According to this configuration, the withstand voltage on the peripheral edge portion side of the chip 2 is improved using the low concentration region 11 extending in a band shape. Preferably, the low concentration region 11 surrounds the high concentration region 10 in a plan view. According to this configuration, the withstand voltage on the peripheral edge portion side of the chip 2 is improved over the entire periphery of the high concentration region 10.

Preferably, the low concentration region 11 is connected to the high concentration region 10. According to this configuration, electrical continuity between the high concentration region 10 and the low concentration region 11 is secured. Thereby, discontinuity of the electric field between the high concentration region 10 and the low concentration region 11 is suppressed, and the withstand voltage of the peripheral edge portion of the chip 2 is appropriately improved. In this case, the low concentration region 11 forms a region boundary portion 12 with the high concentration region 10 that extends in the thickness direction of the chip 2. The region boundary portion 12 may extend to be substantially perpendicular to the first main surface 3.

The semiconductor device 1A may include the n-type inner low concentration region 13. The inner low concentration region 13 has a third impurity concentration lower than the first impurity concentration of the high concentration region 10, and may be formed in a region below the high concentration region 10 in the inner portion of the chip 2. According to this configuration, a resistance value on the inner portion side of the chip 2 can be reduced using the high concentration region 10, and the withstand voltage on the inner portion side of the chip 2 can be improved using the inner low concentration region 13.

In this case, preferably, the inner low concentration region 13 is connected to the low concentration region 11 in the peripheral edge portion of the chip 2. According to this configuration, electrical continuity between the low concentration region 11 and the inner low concentration region 13 is secured. Thereby, discontinuity of the electric field between the low concentration region 11 and the inner low concentration region 13 is suppressed, and the withstand voltage of the peripheral edge portion of the chip 2 is appropriately improved.

The semiconductor device 1A may include the p-type body region 20 (first impurity region) that is formed in the surface layer portion of the high concentration region 10 in a region on the inner portion side of the high concentration region 10. The body region 20 forms a pn-junction portion with the high concentration region 10, and expands a depletion layer to the high concentration region 10 when a reverse bias voltage is applied. According to this configuration, a range of the depletion layer is expanded toward the peripheral edge portion side of the chip 2 by the low concentration region 11. Thereby, the withstand voltage on the peripheral edge portion side of the chip 2 is appropriately improved.

The semiconductor device 1A may include the p-type outer body region 21 (second impurity region) that is formed in any one or both of the surface layer portion of the high concentration region 10 and the surface layer portion of the low concentration region 11 in the region on the peripheral edge portion side of the chip 2. The outer body region 21 may be formed in the surface layer portion of the high concentration region 10, may form a pn-junction portion with the high concentration region 10.

In this case, the outer body region 21 expands the depletion layer to the high concentration region 10 when a reverse bias voltage is applied. According to this configuration, a range of the depletion layer is expanded toward the peripheral edge portion side of the chip 2 by the low concentration region 11. Thereby, the withstand voltage on the peripheral edge portion side of the chip 2 is appropriately improved.

The outer body region 21 may be formed such as to expand the depletion layer integrated with the depletion layers of the body regions 20. The outer body region 21 may be connected to the body region 20. The outer body region 21 may have a p-type impurity concentration substantially equal to the p-type impurity concentration of the body region 20.

The semiconductor device 1A may include the p-type terminal region 40 (third impurity region) that is formed in any one or both of the surface layer portion of the high concentration region 10 and the surface layer portion of the low concentration region 11. The terminal region 40 may be formed in the high concentration region 10, and form a pn-junction portion with the high concentration region 10. In this case, the terminal region 40 expands the depletion layer to the high concentration region 10 when a reverse bias voltage is applied. According to this configuration, a range of the depletion layer is expanded toward the peripheral edge portion side of the chip 2 by the low concentration region 11. Thereby, the withstand voltage on the peripheral edge portion side of the chip 2 is appropriately improved.

The terminal region 40 may be formed to expand the depletion layer integrated with the depletion layers of the body regions 20. The terminal region 40 may be formed to expand the depletion layer integrated with the depletion layer of the outer body region 21. The terminal region 40 may be connected to the outer body region 21. The terminal region 40 may have a p-type impurity concentration different from the p-type impurity concentration of the body region 20.

The terminal region 40 may include a lead-out portion that is led out from the high concentration region 10 to the low concentration region 11. The lead-out portion of the terminal region 40 forms a pn-junction portion with the low concentration region 11, and expands the depletion layer to the low concentration region 11 when a reverse bias voltage is applied. According to this configuration, the depletion layer appropriately extends from the terminal region 40 to the low concentration region 11. Thereby, the withstand voltage on the peripheral edge portion side of the chip 2 is appropriately improved.

The semiconductor device 1A may include the p-type field region 42 (fourth impurity region) that is formed in the surface layer portion of the low concentration region 11. The field region 42 forms a pn-junction portion with the low concentration region 11, and expands the depletion layer to the low concentration region 11 when a reverse bias voltage is applied. The range of the depletion layer of the field region 42 is expanded by the low concentration region 11. Thereby, the withstand voltage on the peripheral edge portion side of the chip 2 is appropriately improved.

Preferably, the field region 42 is formed at an interval from the high concentration region 10 toward the peripheral edge side of the chip 2. Preferably, the field region 42 is formed at an interval from the body region 20 toward the peripheral edge side of the chip 2. Preferably, the field region 42 is formed at an interval from the outer body region 21 toward the peripheral edge side of the chip 2. Preferably, the field region 42 is formed at an interval from the terminal region 40 toward the peripheral edge side of the chip 2.

The semiconductor device 1A may include the n-type base region 14. The base region 14 has a fourth impurity concentration higher than the first impurity concentration of the high concentration region 10, and may be formed in a region below the high concentration region 10 on the inner portion side of the chip 2. The base region 14 may be led out from the inner portion of the chip 2 toward the peripheral edge portion of the chip 2, and may include a portion that is located in a region below the low concentration region 11.

From another viewpoint, the semiconductor device 1A includes the chip 2, the active region 8, the outer peripheral region 9, the high concentration region 10, and the low concentration region 11. The chip 2 has the first main surface 3. The active region 8 is provided in the inner portion of the first main surface 3. The outer peripheral region 9 is provided in the peripheral edge portion of the first main surface 3.

The high concentration region 10 has a first impurity concentration, and is formed in the surface layer portion of the first main surface 3 in the active region 8. The low concentration region 11 has a second impurity concentration lower than the first impurity concentration of the high concentration region 10, and is formed in the surface layer portion of the first main surface 3 in the outer peripheral region 9. According to this configuration, the semiconductor device 1A having a novel configuration can be provided. According to the semiconductor device 1A, the resistance value on the active region 8 side can be reduced using the high concentration region 10, and the withstand voltage on the outer peripheral region 9 side can be improved using the low concentration region 11.

Preferably, the chip 2 includes SiC as an example of a wide bandgap semiconductor. In the case of the chip 2 including SiC, an extremely high voltage is to be applied due to characteristics (physical properties) of the chip 2, and a withstand voltage can be reduced due to the electric field in the peripheral edge portion of the chip 2. In this regard, in the case of the semiconductor device 1A, the withstand voltage on the outer peripheral region 9 side of the chip 2 including SiC is improved using the low concentration region 11.

The chip 2 may have the first to fourth side surfaces 5A to 5D. In this case, the high concentration region 10 may be formed at an interval from at least one of the first to fourth side surfaces 5A to 5D. The low concentration region 11 may be exposed from at least one of the first to fourth side surfaces 5A to 5D. According to this configuration, the formation region of the low concentration region 11 is expanded to a range in which the region is exposed from at least one of the first to fourth side surfaces 5A to 5D. Thereby, the withstand voltage on the outer peripheral region 9 side is appropriately improved.

Preferably, the low concentration region 11 extends in a band shape along the high concentration region 10 in a plan view. According to this configuration, the withstand voltage on the outer peripheral region 9 side is improved using the low concentration region 11 extending in a band shape. Preferably, the low concentration region 11 surrounds the high concentration region 10 in a plan view. According to this configuration, the withstand voltage on the outer peripheral region 9 side is improved over the entire periphery of the high concentration region 10.

Preferably, the low concentration region 11 is connected to the high concentration region 10. According to this configuration, electrical continuity between the high concentration region 10 and the low concentration region 11 is secured. Thereby, discontinuity of the electric field between the high concentration region 10 and the low concentration region 11 is suppressed, and the withstand voltage on the outer peripheral region 9 side is appropriately improved. In this case, the low concentration region 11 forms a region boundary portion 12 with the high concentration region 10 that extends in the thickness direction of the chip 2. The region boundary portion 12 may extend to be substantially perpendicular to the first main surface 3.

The semiconductor device 1A may include the n-type inner low concentration region 13. The inner low concentration region 13 has a third impurity concentration lower than the first impurity concentration of the high concentration region 10, and may be formed in a region below the high concentration region 10 on the active region 8 side. According to this configuration, the resistance value on the active region 8 side can be reduced using the high concentration region 10, and the withstand voltage on the active region 8 side can be improved using the inner low concentration region 13.

In this case, preferably, the inner low concentration region 13 is connected to the low concentration region 11 on the outer peripheral region 9 side. According to this configuration, electrical continuity between the low concentration region 11 and the inner low concentration region 13 is secured. Thereby, discontinuity of the electric field between the low concentration region 11 and the inner low concentration region 13 is suppressed, and the withstand voltage on the outer peripheral region 9 side is appropriately improved.

The semiconductor device 1A may include the p-type body region 20 (first impurity region) that is formed in the surface layer portion of the high concentration region 10 on the active region 8 side. The body region 20 forms a pn-junction portion with the high concentration region 10, and expands a depletion layer to the high concentration region 10 when a reverse bias voltage is applied. According to this configuration, a range of the depletion layer is expanded toward the outer peripheral region 9 side by the low concentration region 11. Thereby, the withstand voltage on the outer peripheral region 9 side is appropriately improved.

The semiconductor device 1A may include the p-type outer body region 21 (second impurity region) that is formed in any one or both of the surface layer portion of the high concentration region 10 and the surface layer portion of the low concentration region 11 in a region on the outer peripheral region 9 side. The outer body region 21 may be formed in the surface layer portion of the high concentration region 10, may form a pn-junction portion with the high concentration region 10.

In this case, the outer body region 21 expands the depletion layer to the high concentration region 10 when a reverse bias voltage is applied. According to this configuration, a range of the depletion layer is expanded toward the outer peripheral region 9 side by the low concentration region 11. Thereby, the withstand voltage on the outer peripheral region 9 side is appropriately improved.

The outer body region 21 may be formed such as to expand the depletion layer integrated with the depletion layers of the body regions 20. The outer body region 21 may be connected to the body region 20. The outer body region 21 may have a p-type impurity concentration substantially equal to the p-type impurity concentration of the body region 20.

The semiconductor device 1A may include the p-type terminal region 40 (third impurity region) that is formed in any one or both of the surface layer portion of the high concentration region 10 and the surface layer portion of the low concentration region 11 in a region on the outer peripheral region 9 side. The terminal region 40 may be formed in the high concentration region 10, and form a pn-junction portion with the high concentration region 10.

In this case, the terminal region 40 expands the depletion layer to the high concentration region 10 when a reverse bias voltage is applied. According to this configuration, a range of the depletion layer is expanded toward the outer peripheral region 9 side by the low concentration region 11. Thereby, the withstand voltage on the outer peripheral region 9 side is appropriately improved.

The terminal region 40 may be formed to expand the depletion layer integrated with the depletion layers of the body regions 20. The terminal region 40 may be formed to expand the depletion layer integrated with the depletion layer of the outer body region 21. The terminal region 40 may be connected to the outer body region 21. The terminal region 40 may have a p-type impurity concentration different from the p-type impurity concentration of the body region 20.

The terminal region 40 may include a lead-out portion that is led out from the high concentration region 10 to the low concentration region 11. The lead-out portion of the terminal region 40 forms a pn-junction portion with the low concentration region 11, and expands the depletion layer to the low concentration region 11 when a reverse bias voltage is applied. According to this configuration, the depletion layer appropriately extends from the terminal region 40 to the low concentration region 11. Thereby, the withstand voltage on the outer peripheral region 9 side is appropriately improved.

The semiconductor device 1A may include the p-type field region 42 (fourth impurity region) that are formed in the surface layer portion of the low concentration region 11 in the outer peripheral region 9. The field region 42 forms a pn-junction portion with the low concentration region 11, and expands the depletion layer to the low concentration region 11 when a reverse bias voltage is applied. The range of the depletion layer of the field region 42 is expanded by the low concentration region 11. Thereby, the withstand voltage on the outer peripheral region 9 side is appropriately improved.

Preferably, the field region 42 is formed at an interval from the high concentration region 10 toward the peripheral edge side of the chip 2. Preferably, the field region 42 is formed at an interval from the body region 20 toward the peripheral edge side of the chip 2. Preferably, the field region 42 is formed at an interval from the outer body region 21 toward the peripheral edge side of the chip 2. Preferably, the field region 42 is formed at an interval from the terminal region 40 toward the peripheral edge side of the chip 2.

Preferably, the field region 42 extends in a band shape along the high concentration region 10 in a plan view. According to this configuration, the depletion layer expands in a band shape from the field region 42 toward the low concentration region 11. Thereby, the withstand voltage on the outer peripheral region 9 side is appropriately improved. Preferably, the field region 42 surrounds the high concentration region 10 in a plan view. According to this configuration, the depletion layer expands from the field region 42 toward the low concentration region 11 such as to surround the high concentration region 10. Thereby, the withstand voltage on the outer peripheral region 9 side is appropriately improved.

The field regions 42 may be formed at an interval in the surface layer portion of the low concentration region 11. According to this configuration, the depletion layers expand from the field regions 42 toward the low concentration region 11. Thereby, the withstand voltage on the outer peripheral region 9 side is appropriately improved.

The semiconductor device 1A may include the n-type base region 14. The base region 14 has a fourth impurity concentration higher than the first impurity concentration of the high concentration region 10, and may be formed in a region below the high concentration region 10 in the active region 8. The base region 14 is led out from the active region 8 toward the outer peripheral region 9, and may include a portion that is located in a region below the low concentration region 11.

The semiconductor device 1A may include the transistor structure Tr as an example of the device structure formed in the active region 8. In this case, the transistor structure Tr may include the high concentration region 10. According to this configuration, a resistance value of the transistor structure Tr can be reduced using the high concentration region 10, and a withstand voltage of the transistor structure Tr can be improved using the low concentration region 11.

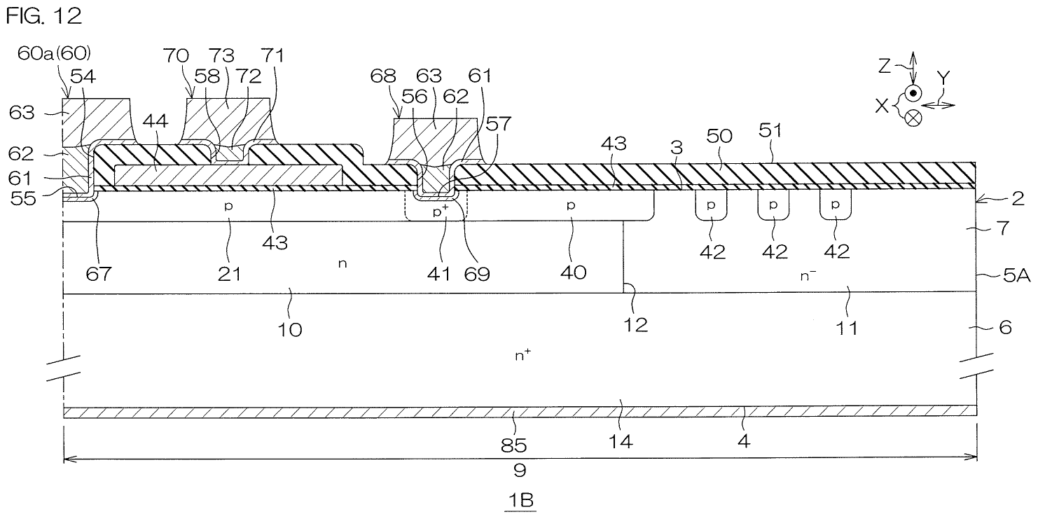

FIG. 12 is a cross-sectional view illustrating a semiconductor device 1B according to a second embodiment. The semiconductor device 1B has a layout obtained by modifying the high concentration region 10 according to the semiconductor device 1A. Specifically, the high concentration region 10 is formed in the entire thickness range of the second semiconductor layer 7 between the first main surface 3 and the bottom portion of the second semiconductor layer 7 (the first semiconductor layer 6), and is connected to the first semiconductor layer 6. That is, in this embodiment, the semiconductor device 1B does not include the inner low concentration region 13.

In this embodiment, the high concentration region 10 is formed to be substantially perpendicular to the first main surface 3 in a cross-sectional view. For example, the high concentration region 10 may be formed by introducing n-type impurities into the entire thickness range of the n-type second semiconductor layer 7.

The low concentration region 11 is formed in the same layout as in the case of the semiconductor device 1A. In this embodiment, the inner edge portion of the low concentration region 11 is connected to the peripheral edge portion of the high concentration region 10 over the entire thickness range of the high concentration region 10. That is, the region boundary portion 12 traverses the depth position of the intermediate portion of the second semiconductor layer 7 in the thickness direction. In this embodiment, a lower end portion of the region boundary portion 12 is connected to the first semiconductor layer 6.

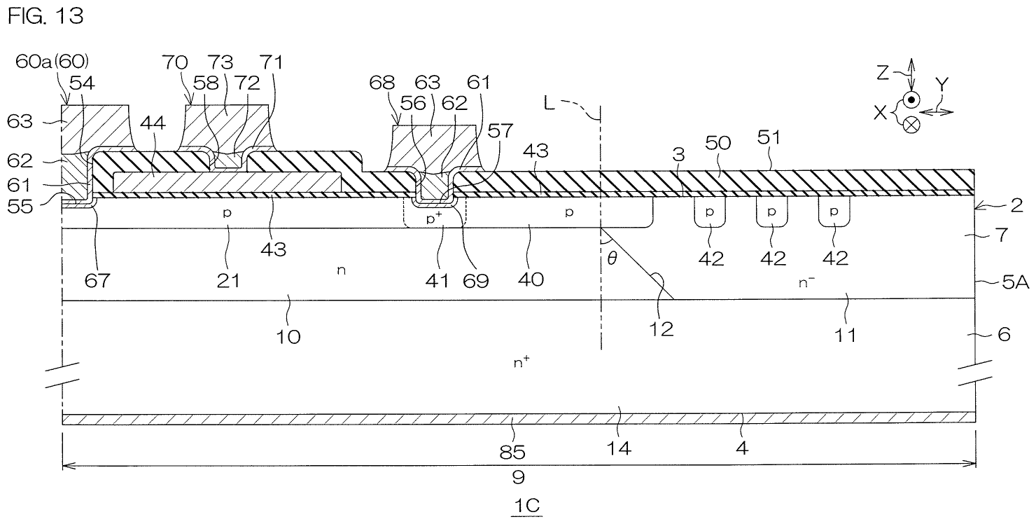

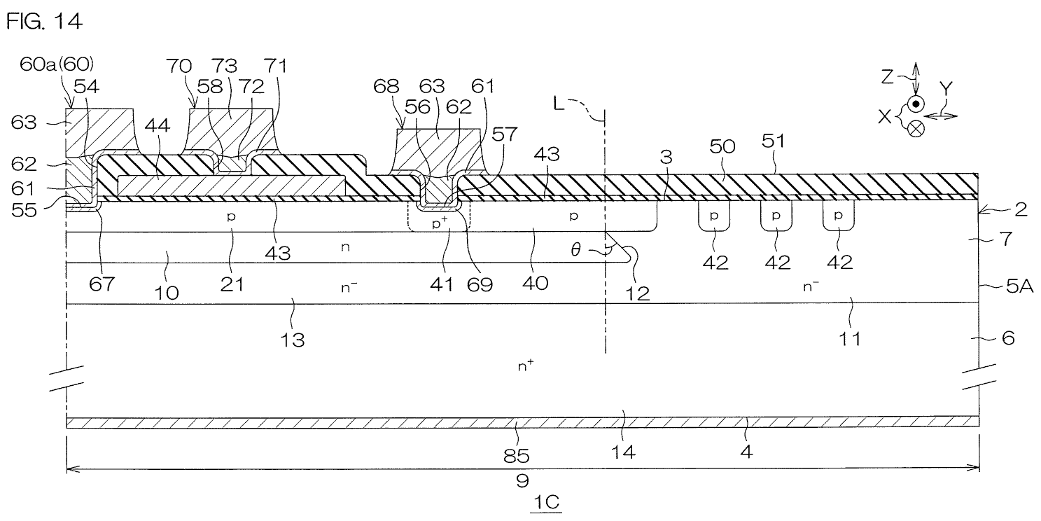

FIG. 13 is a cross-sectional view illustrating a semiconductor device 1C according to a third embodiment. FIG. 14 is a cross-sectional view illustrating a modification example of the semiconductor device 1C illustrated in FIG. 13. The semiconductor device 1C has a layout obtained by modifying the high concentration region 10 according to the semiconductor device 1B.

Specifically, the high concentration region 10 is formed in a tapered shape in which the width in the horizontal direction gradually increases from the first main surface 3 toward the thickness direction in a cross-sectional view. That is, the peripheral edge portion of the high concentration region 10 is inclined obliquely downward from the inner portion (active region 8) of the chip 2 toward the peripheral edge portion (outer peripheral region 9) side of the chip 2. The peripheral edge portion (inclined peripheral edge portion) of the high concentration region 10 is located in the outer peripheral region 9.

Such a configuration is effective in reducing the resistance value of the current spreading path in a case of considering a current (that is, current spreading) flowing in the oblique direction between the inner portion of the chip 2 and the peripheral edge portion of the chip 2. For example, the inclined portion of the high concentration region 10 may be formed by introducing n-type impurities in a direction inclined with respect to the first main surface 3 by an oblique ion implantation method.

The low concentration region 11 includes an inner edge portion that is inclined obliquely downward along the peripheral edge portion (inclined peripheral edge portion) of the high concentration region 10. That is, the low concentration region 11 is formed in a tapered shape in which the width in the horizontal direction gradually decreases from the first main surface 3 toward the thickness direction in a cross-sectional view. Such a configuration is effective in reducing the resistance value of the current spreading path and increasing the withstand voltage on the peripheral edge portion side of the chip 2.

The low concentration region 11 forms a region boundary portion 12 that is inclined obliquely downward with the high concentration region 10. The region boundary portion 12 includes an upper end portion on the first main surface 3 side, a lower end portion on the second main surface 4 side, and an inclined portion between the upper end portion and the lower end portion. The upper end portion is located on the inner portion side of the chip 2 in the outer peripheral region 9. The lower end portion is located on the peripheral edge portion side of the chip 2 in the outer peripheral region 9. The inclined portion is inclined obliquely downward from the upper end portion toward the lower end portion in the outer peripheral region 9.

An inclination angle θ (absolute value) of the inclined portion may be larger than 0° and 75° or smaller. The inclination angle θ is an angle formed by the inclined portion and a virtual vertical line L in a case where the virtual vertical line L (virtual perpendicular line) perpendicular to the first main surface 3 in a cross-sectional view is set to pass through the upper end portion of the region boundary portion 12.

The inclination angle θ may have a value in at least one range among a range larger than 0° and equal to or smaller 15°, a range of 15° or larger and 30° or smaller, a range of 30° or larger and 45° or smaller, a range of 45° or larger and 60° or smaller, and a range of 60° or larger and 75° or smaller. Preferably, the inclination angle θ is in a range of 20° or larger and 60° or smaller. It is particularly preferable that the inclination angle θ is in a range of 30° or larger and 50° or smaller.

Preferably, at least the innermost field region 42 among the field regions 42 is formed in the surface layer portion of the low concentration region 11 at an interval from the upper end portion of the high concentration region 10 (the upper end portion of the region boundary portion 12) toward the peripheral edge side of the chip 2. The innermost field region 42 may oppose the inclined portion of the high concentration region 10 (the inclined portion of the region boundary portion 12) in the thickness direction across a portion of the low concentration region 11.

It is particularly preferable that the field regions 42 are formed in the surface layer portion of the low concentration region 11 at an interval from the lower end portion of the high concentration region 10 (the lower end portion of the region boundary portion 12) toward the peripheral edge side of the chip 2. That is, it is particularly preferable that the field regions 42 do not oppose the high concentration region 10 in the thickness direction.

As illustrated in FIG. 14, the semiconductor device 1C may include an inner low concentration region 13. That is, as in the case of the semiconductor device 1A, the high concentration region 10 may be formed at an interval from a bottom portion of the second semiconductor layer 7 toward the first main surface side, and may oppose the first semiconductor layer 6 across a portion of the second semiconductor layer 7. In this case, the inner low concentration region 13 passes below the lower end portion of the high concentration region 10 (the lower end portion of the region boundary portion 12), and is connected to the region on the bottom portion side of the low concentration region 11 in the outer peripheral region 9.

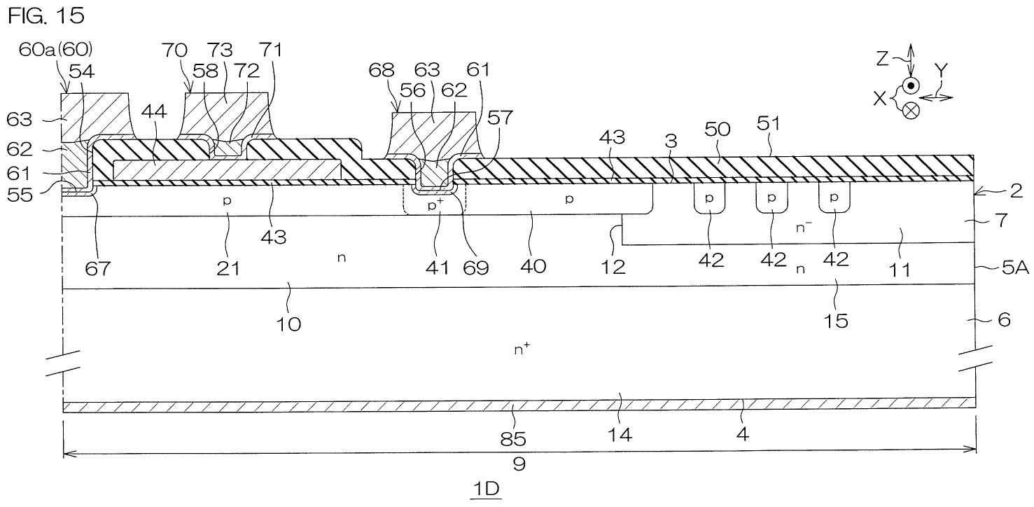

FIG. 15 is a cross-sectional view illustrating a semiconductor device 1D according to a fourth embodiment. The semiconductor device 1D has a layout obtained by modifying the layout of the chip 2 according to the semiconductor device 1C. Specifically, in this embodiment, the low concentration region 11 is formed at an interval from the bottom portion of the second semiconductor layer 7 toward the first main surface 3 side, and includes a bottom portion located in the second semiconductor layer 7.

The low concentration region 11 may traverse the depth position of the intermediate portion of the second semiconductor layer 7 in the thickness direction. That is, a thickness of the low concentration region 11 may be equal to or thicker than ½ of the thickness of the second semiconductor layer 7. As a matter of course, the low concentration region 11 may be formed at an interval from a depth position of an intermediate portion of the second semiconductor layer 7 toward the first main surface 3 side. That is, a thickness of the low concentration region 11 may be thinner than ½ of the thickness of the second semiconductor layer 7.

In this embodiment, the semiconductor device 1D includes an n-type outer high concentration region 15 that is formed in a region below the low concentration region 11 in the surface layer portion of the first main surface 3. The outer high concentration region 15 may be referred to as a “fifth region,” a “fourth drift region,” a “second high concentration drift region,” etc. The outer high concentration region 15 has a fifth impurity concentration higher than the second impurity concentration of the low concentration region 11. The fifth impurity concentration may be 1×10¹⁵ cm⁻³ or higher and 5×10¹⁶ cm⁻³ or lower.

The outer high concentration region 15 is formed on the peripheral edge portion side of the chip 2 with respect to the high concentration region 10. The outer high concentration region 15 extends in a layer shape along the low concentration region 11 in the outer peripheral region 9, and is connected to the low concentration region 11 in the thickness direction. Thereby, the outer high concentration region 15 is electrically connected to the low concentration region 11.

The outer high concentration region 15 is formed as a low resistance region (second low resistance region) having a resistance value lower than that of the low concentration region 11 in the outer peripheral region 9. Such a configuration is effective in reducing the resistance value of the current spreading path in a case of considering a current (that is, current spreading) flowing in the oblique direction between the inner portion of the chip 2 and the peripheral edge portion of the chip 2.

The outer high concentration region 15 is formed in a region between the peripheral edge of the first main surface 3 and the high concentration region 10 in the outer peripheral region 9, and extends in a band shape along the high concentration region 10 (active region 8) in a plan view. The outer high concentration region 15 includes a portion extending in a band shape in the first direction X and a portion extending in a band shape in the second direction Y in a plan view, and defines the high concentration region 10 (active region 8) from a plurality of directions. In this embodiment, the outer high concentration regions 15 are formed in annular shapes (in this embodiment, a quadrangular round shape) that surround the high concentration region 10 (active region 8) in a plan view. Preferably, the outer high concentration region 15 is formed in the entire region below the low concentration region 11.

The outer high concentration region 15 has an outer edge portion on the peripheral edge side of the first main surface 3 and an inner edge portion on the inner portion side of the first main surface 3. The inner edge portion of the outer high concentration region 15 is connected to the peripheral edge portion of the high concentration region 10. In this embodiment, the outer high concentration region 15 is connected to the high concentration region 10 in the outer peripheral region 9. Thereby, the outer high concentration region 15 is electrically connected to the high concentration region 10.

Preferably, the fifth impurity concentration of the outer high concentration region 15 is substantially equal to the first impurity concentration of the region on the bottom portion side of the high concentration region 10. Preferably, the outer edge portion of the outer high concentration region 15 is exposed from at least one of the first to fourth side surfaces 5A to 5D. In this embodiment, the outer edge portion of the outer high concentration region 15 is exposed from all of the first to fourth side surfaces 5A to 5D.

In this embodiment, the outer high concentration region 15 is formed in the second semiconductor layer 7. That is, the semiconductor device 1D has a multilayer structure including the low concentration region 11 and the outer high concentration region 15 in the peripheral edge portion of the second semiconductor layer 7 (outer peripheral region 9). For example, the outer high concentration region 15 may be formed by introducing n-type impurities into a portion (a region on the bottom portion side) of the n-type second semiconductor layer 7.

The outer high concentration region 15 is formed in the entire thickness range of the second semiconductor layer 7 between the bottom portion of the second semiconductor layer 7 (the first semiconductor layer 6) and the bottom portion of the low concentration region 11, and is connected to the first semiconductor layer 6. In a case where the low concentration region 11 traverses the depth position of the intermediate portion of the second semiconductor layer 7 in the thickness direction, the thickness of the outer high concentration region 15 is thinner than ½ of the thickness of the second semiconductor layer 7. In a case where the low concentration region 11 is formed on the first main surface 3 side from the intermediate portion of the second semiconductor layer 7, the thickness of the outer high concentration region 15 is thicker than ½ of the thickness of the second semiconductor layer 7.

As in the case of the semiconductor device 1A, the field regions 42 are formed in the surface layer portion of the low concentration region 11. In this embodiment, the field regions 42 are formed at an interval from the bottom portion of the low concentration region 11 toward the first main surface 3 side, and oppose the outer high concentration region 15 across a portion of the low concentration region 11.

Preferably, the field regions 42 are formed at an interval from the intermediate portion of the low concentration region 11 toward the first main surface 3 side. That is, the thickness of the field regions 42 may be thinner than ½ of the thickness of the low concentration region 11. As a matter of course, the field regions 42 may traverse the intermediate portion of the low concentration region 11 in the thickness direction. That is, the thickness of the field regions 42 may be equal to or thicker than ½ of the thickness of the low concentration region 11.

In this embodiment, the drain pad electrode 85 includes a portion that opposes the high concentration region 10 across the base region 14, and a portion that opposes the low concentration region 11 (outer high concentration region 15) across the base region 14.

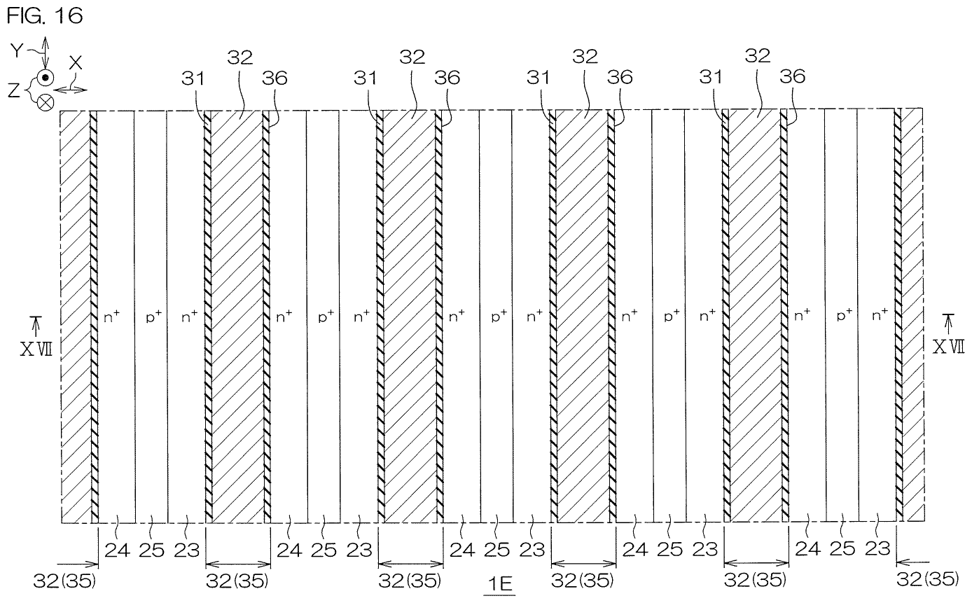

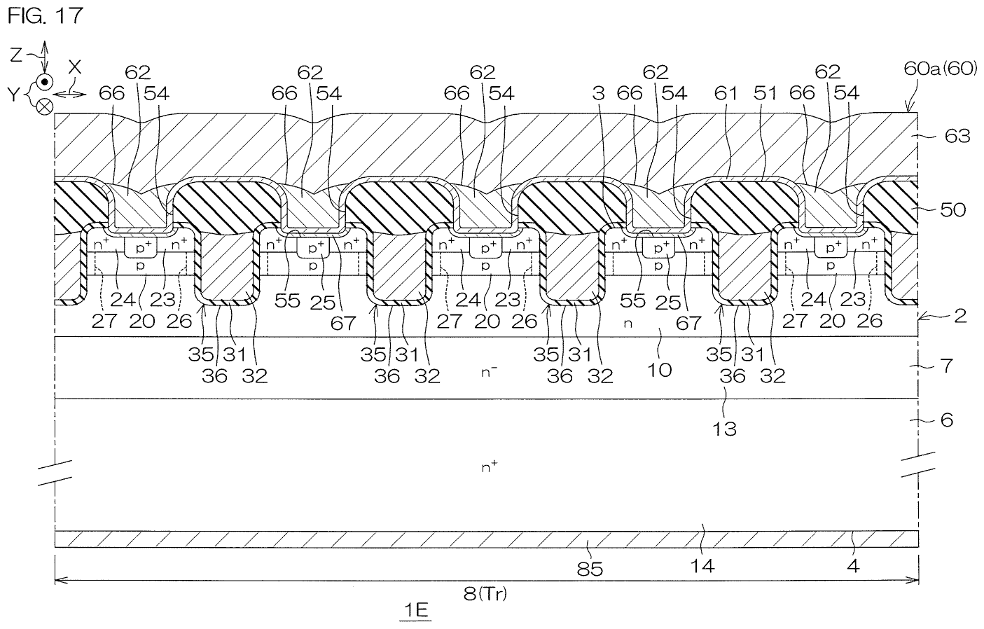

FIG. 16 is an enlarged plan view illustrating a main portion of the active region 8 of the semiconductor device 1E according to the fifth embodiment. FIG. 17 is a cross-sectional view taken along line XVII-XVII illustrated in FIG. 16. FIG. 17 illustrates an example in which the configuration of the semiconductor device 1A (the high concentration region 10, the low concentration region 11, and the like) is applied to the semiconductor device 1E. As a matter of course, the configurations (the high concentration region 10, the low concentration region 11, the outer high concentration region 15, and the like) of the semiconductor devices 1B to 1D may be applied to the semiconductor device 1E.

Referring to FIG. 16 and FIG. 17, the semiconductor device 1E is a semiconductor switching device having the transistor structure Tr of a trench-gate-type as an example of the device structure in the active region 8 instead of the transistor structure Tr of the planar-gate-type.

The semiconductor device 1E includes a single body region 20 instead of the body regions 20. The single body region 20 is formed in the surface layer portion of the first main surface 3 over the entire active region 8. The single body region 20 is formed in the surface layer portion of the high concentration region 10. The single body region 20 is formed at an interval from the bottom portion of the high concentration region 10 toward the first main surface 3 side, and opposes the inner low concentration region 13 (base region 14) across a portion of the high concentration region 10.

Preferably, the single body region 20 is formed at an interval from the intermediate portion of the high concentration region 10 toward the first main surface 3 side. As a matter of course, the single body region 20 may traverse the depth position of the intermediate portion of the high concentration region 10 in the thickness direction. The single body region 20 is exposed from the first main surface 3.

The single body region 20 forms a pn-junction portion (a pn-junction diode, a body diode) with the high concentration region 10. The single body region 20 expands the depletion layer to the high concentration region 10 when a reverse bias voltage is applied. The depletion layer extends from the high concentration region 10 toward the low concentration region 11 in the horizontal direction along the first main surface 3.

As in the case of the semiconductor device 1A, the outer body region 21 described above is formed in the surface layer portion of the first main surface 3 (high concentration region 10) in the outer peripheral region 9. In this embodiment, the outer body region 21 is connected to the single body region 20 over the entire active region 8. The outer body region 21 can be regarded as being formed by the peripheral edge portion of the single body region 20.

The semiconductor device 1E has a plurality of gate structures 35 of a trench-electrode-type instead of the gate structures 30 of the planar-electrode-type in the active region 8. The gate structures 35 are arranged at intervals in the first direction X, and are respectively formed in a band shape extending in the second direction Y. That is, the gate structures 35 are arranged in a stripe shape extending in the second direction Y. The extension direction of the gate structures 35 coincides with the off direction of the SiC single crystal.

In this embodiment, the gate structures 35 are formed at an interval from the bottom portion of the high concentration region 10 toward the first main surface 3 side, and oppose the inner low concentration region 13 (base region 14) across a portion of the high concentration region 10. That is, the gate structures 35 are formed to be shallower than the high concentration region 10, and oppose the low concentration region 11 in the horizontal direction.

Each of the gate structures 35 includes a trench 36, an insulating film 31, and a gate electrode 32. The trench 36 is formed in the first main surface 3, and defines wall surface (a side wall and a bottom wall) of the gate structure 35. The insulating film 31 covers the wall surface of the trench 36 in a film shape. The gate electrode 32 is embedded in the trench 36 across the insulating film 31.

The source regions 23 and 24 described above are formed on both sides of the gate structures 35 in the surface layer portion of the single body region 20. The first source region 23 is formed along the side wall of the corresponding gate structure 35 on one side, and opposes the gate electrode 32 across the insulating film 31. The second source region 24 is formed along the side wall of the corresponding gate structure 35 on the other side, and opposes the gate electrode 32 across the insulating film 31.

Each of the source regions 23 and 24 extends in a band shape along the extension direction of the gate structures 35. Each of the source regions 23 and 24 is formed at an interval from the bottom portion of the single body region 20 toward the first main surface 3 side, and opposes the high concentration region 10 across a portion of the single body region 20.

Each of the contact regions 25 described above is formed in a region between the source regions 23 and 24 in the surface layer portion of the single body region 20. Each of the contact regions 25 extends in a band shape along the extension direction of the gate structures 35. Each of the contact regions 25 is formed at an interval from the bottom portion of the single body region 20 toward the first main surface 3 side, and opposes the high concentration region 10 across a portion of the single body region 20.

Each of the channel regions 26 and 27 described above is defined in a region between the bottom portion (high concentration region 10) of the single body region 20 and the source regions 23 and 24. The first channel region 26 is defined in a region between the bottom portion (high concentration region 10) of the single body region 20 and the first source region 23, and forms a current path extending along the side wall of the gate structure 35 in the lamination direction. The second channel region 27 is defined in a region between the bottom portion (high concentration region 10) of the single body region 20 and the second source region 24, and forms a current path extending along the side wall of the gate structure 35 in the lamination direction.

When the gate potential is to be applied to the gate electrode 32, the channel regions 26 and 27 enter into an ON state, and a drain current flows between the high concentration region 10 and the source regions 23 and 24 via the channel regions 26 and 27 (body region 20). As described above, the transistor structure Tr of the trench-gate-type including the high concentration region 10 is formed in the inner portion (active region 8) of the chip 2.

As in the case of the semiconductor device 1A, the semiconductor device 1E includes the terminal region 40 (overlap region 41), the field regions 42, the outer peripheral insulating film 43, the gate wiring 44, the interlayer film 50, the source openings 54, the source recesses 55, the outer openings 56, the outer recesses 57, the gate openings 58, the source pad electrode 60, the first silicide portions 67, the source finger electrode 68, the second silicide portions 69, the gate finger electrode 70, the gate pad electrode 80, and the drain pad electrode 85. A description of these configurations is similar to the description of the semiconductor device 1A, and thus, the description thereof will be omitted.

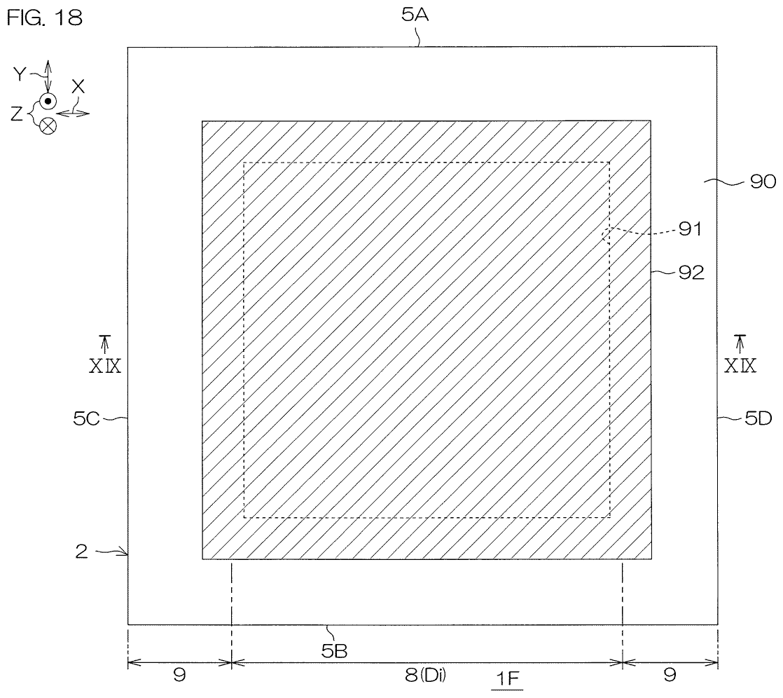

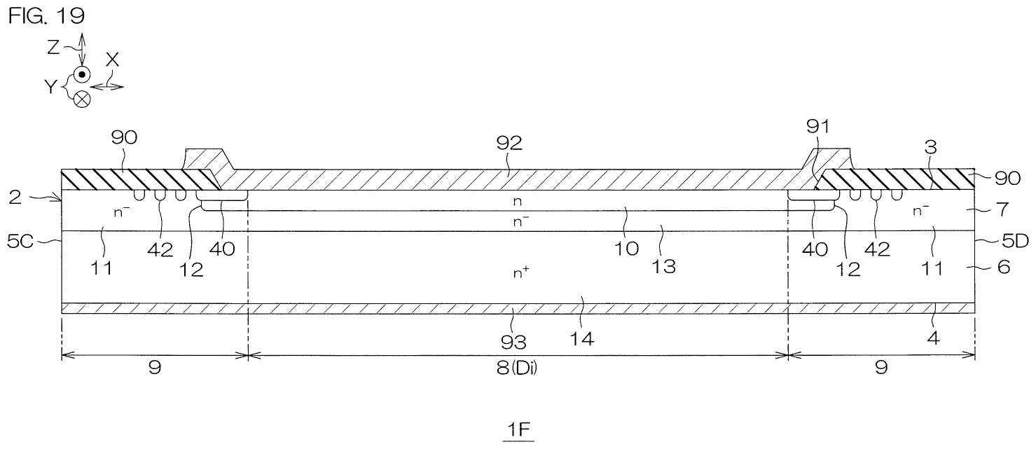

FIG. 18 is a plan view illustrating a semiconductor device 1F according to a sixth embodiment. FIG. 19 is a cross-sectional view taken along line XIX-XIX illustrated in FIG. 18. The semiconductor device 1F is a semiconductor rectifier device having a diode structure Di as an example of a device structure instead of the transistor structure Tr. In this embodiment, the diode structure Di is a Schottky barrier diode (SBD) structure.

Referring to FIG. 18 and FIG. 19, as in the semiconductor device 1A, the semiconductor device 1F includes the chip 2, the first semiconductor layer 6, the second semiconductor layer 7, the active region 8, the outer peripheral region 9, the high concentration region 10, the low concentration region 11, the region boundary portion 12, the inner low concentration region 13, the terminal region 40, and the field regions 42. A description of these configurations is similar to the description of the semiconductor device 1A, and thus, the description thereof will be omitted.

The semiconductor device 1F includes an interlayer film 90 that selectively covers the first main surface 3. The interlayer film 90 may have a single layer structure or a laminated structure including at least one of a silicon oxide film, a silicon nitride film, and a silicon oxynitride film. In this embodiment, the interlayer film 90 has a single layer structure including a silicon oxide film.

The interlayer film 90 covers the low concentration region 11, the terminal region 40, and the field regions 42 in the outer peripheral region 9. In this embodiment, the interlayer film 90 is continuous with the peripheral edge of the first main surface 3 (the first to fourth side surfaces 5A to 5D). As a matter of course, the interlayer film 90 may be formed at an interval inwardly from the peripheral edge of the first main surface 3, and may expose the second semiconductor layer 7 (low concentration region 11) from the peripheral edge portion of the first main surface 3.

The semiconductor device 1F includes a contact opening 91 that exposes the high concentration region 10 and is formed in the interlayer film 90. In this embodiment, the contact opening 91 has opening wall surface located on the terminal region 40, and exposes inner edge portion of the high concentration region 10 and the terminal region 40. The opening wall surface is formed in a polygonal shape (in this embodiment, a quadrangular shape) having four sides parallel to the peripheral edge of the chip 2 in a plan view, and expose the inner peripheral portion of the terminal region 40 over the entire periphery.

The semiconductor device 1F includes an anode pad electrode 92 arranged on the first main surface 3. The anode pad electrode 92 is a terminal electrode to which an anode potential is to be applied from the outside. The anode pad electrode 92 may be referred to as a “first pad electrode,” a “first main surface electrode,” a “first terminal electrode,” etc. The anode pad electrodes 92 is arranged at an interval inwardly from the peripheral edge of the chip 2. The anode pad electrode 92 is formed in a polygonal shape (in this embodiment, quadrangular shape) along the peripheral edge of the chip 2 in a plan view.

The anode pad electrode 92 enters the contact opening 91 from above the interlayer film 90, and is electrically connected to the inner edge portions of the high concentration region 10 and the terminal region 40 in the contact opening 91. The anode pad electrode 92 forms a Schottky junction with the high concentration region 10. Thereby, the diode structure Di including the high concentration region 10 is formed. The anode pad electrode 92 includes a portion that opposes the high concentration region 10 across the terminal region 40 in the contact opening 91.

The anode pad electrode 92 includes a peripheral edge portion that covers the terminal region 40 across the interlayer film 90. That is, the peripheral edge portion of the anode pad electrode 92 includes a portion that opposes the high concentration region 10 in the lamination direction. The peripheral edge portion of the anode pad electrode 92 may include a portion that traverses the region boundary portion 12 in the horizontal direction and covers the low concentration region 11 across the interlayer film 90.

The peripheral edge portion of the anode pad electrode 92 may be formed at an interval inwardly from the innermost field region 42. The peripheral edge portion of the anode pad electrode 92 may include a portion that covers the innermost field region 42 across the interlayer film 90. The peripheral edge portion of the anode pad electrode 92 may cover the field regions 42 across the interlayer film 90.

The semiconductor device 1F includes a cathode pad electrode 93 that covers the second main surface 4. The cathode pad electrode 93 is a terminal electrode to which a cathode potential is to be applied from the outside. The cathode pad electrode 93 may be referred to as a “second pad electrode,” a “second main surface electrode,” a “second terminal electrode,” etc. The cathode pad electrode 93 is electrically connected to the base region 14.

In this embodiment, the cathode pad electrode 93 includes a portion that opposes the high concentration region 10 across the base region 14, and a portion that opposes the low concentration region 11 across the base region 14. The cathode pad electrode 93 may cover the entire region of the second main surface 4 such as to be continuous with the peripheral edge (the first to fourth side surfaces 5A to 5D) of the second main surface 4. The cathode pad electrode 93 may partially cover the second main surface 4 such as to expose the peripheral edge portions of the second main surface 4.

A breakdown voltage that can be applied between the anode pad electrode 92 and the cathode pad electrode 93 (between the first main surface 3 and the second main surface 4) may be in a range of 500 V or higher and 3000 V or lower. The breakdown voltage may have a value in at least one range among a range of 500 V or higher and 1000 V or lower, a range of 1000 V or higher and 1500 V or lower, a range of 1500 V or higher and 2000 V or lower, a range of 2000 V or higher and 2500 V or lower, and a range of 2500 V or higher and 3000 V or lower.

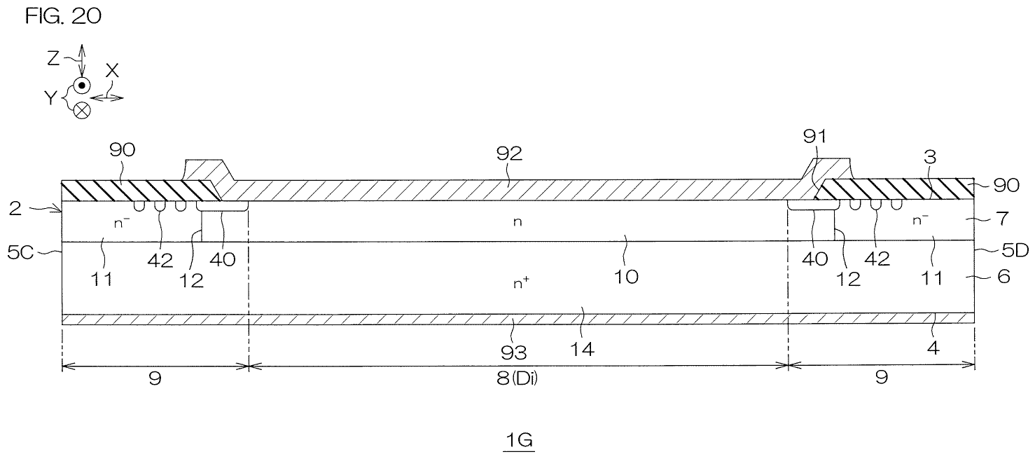

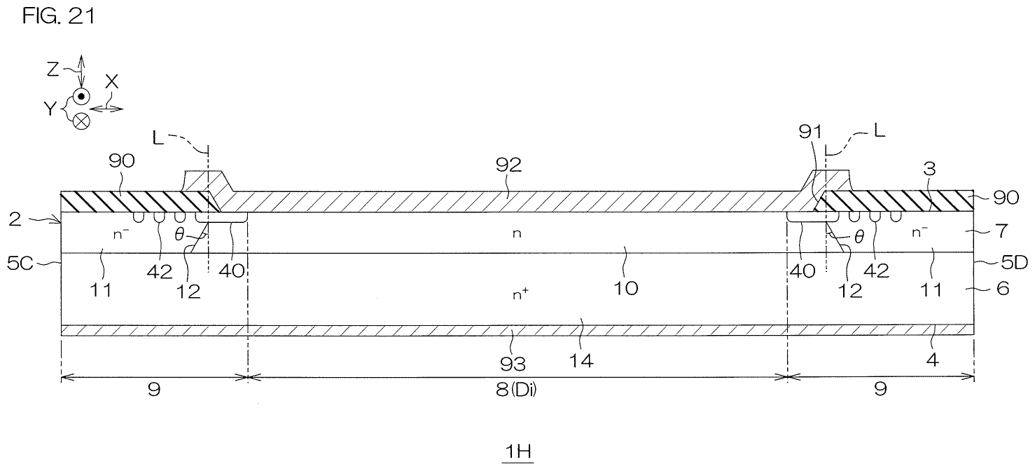

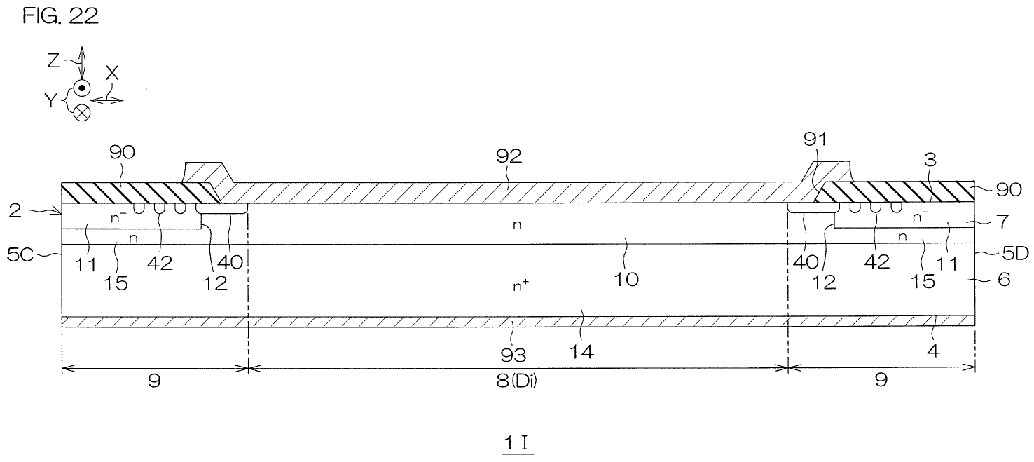

The configurations (refer to FIG. 12 to FIG. 15) of the semiconductor devices 1B to 1D according to the second to fourth embodiments described above can be applied to the configuration (refer to FIG. 19) of the semiconductor device 1F according to the sixth embodiment. In FIG. 20 to FIG. 22, these configurations are illustrated as seventh to ninth embodiments. FIG. 20 is a cross-sectional view illustrating a semiconductor device 1G according to a seventh embodiment. FIG. 21 is a cross-sectional view illustrating a semiconductor device 1H according to an eighth embodiment. FIG. 22 is a cross-sectional view illustrating a semiconductor device 1I according to a ninth embodiment.

Referring to FIG. 20, the semiconductor device 1G has a configuration in which the high concentration region 10 and the low concentration region 11 of the semiconductor device 1B (refer to FIG. 12) are combined with the semiconductor device 1F. Referring to FIG. 21, the semiconductor device 1H has a configuration in which the high concentration region 10 and the low concentration region 11 of the semiconductor device 1C (refer to FIG. 13 and FIG. 14) are combined with the semiconductor device 1F. Referring to FIG. 22, the semiconductor device 1I has a configuration in which the high concentration region 10, the low concentration region 11, and the outer high concentration region 15 of the semiconductor device 1D (refer to FIG. 15) are combined with the semiconductor device 1F.

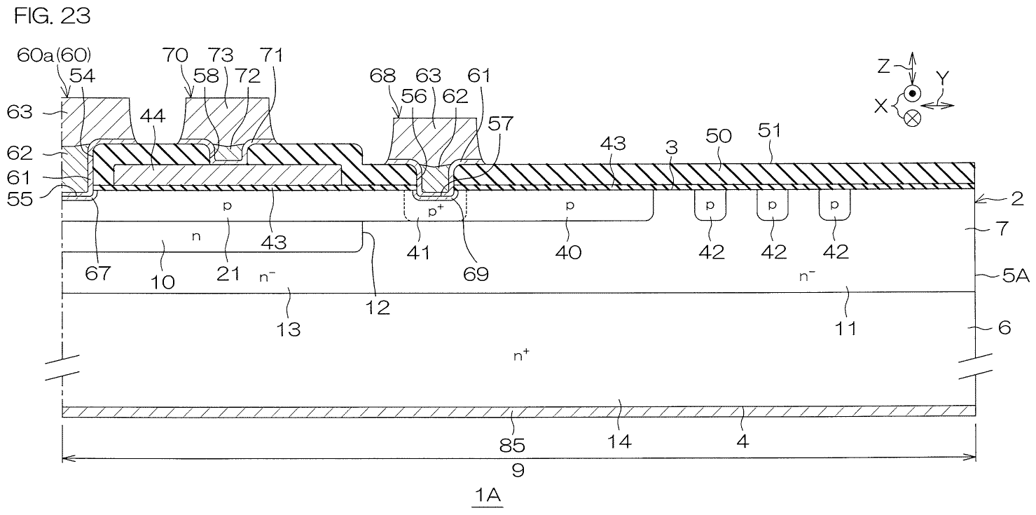

Hereinafter, modification examples in which the semiconductor devices 1A to 1I according to the first to ninth embodiments are applied will be described. FIG. 23 is a cross-sectional view illustrating a modification example of the outer body region 21. FIG. 23 illustrates a configuration in which the configuration according to the modification example is applied to the semiconductor device 1A (first embodiment). On the other hand, the configuration according to the modification example can be applied to all of the semiconductor devices 1A to 1I (first to ninth embodiments).

In each of the embodiments described above, an example is illustrated in which the outer body region 21 is formed at an interval inwardly from the peripheral edge of the high concentration region 10. On the other hand, as illustrated in FIG. 23, the outer edge portion of the outer body region 21 may traverse the peripheral edge portion of the high concentration region 10, and may be located in the low concentration region 11.

That is, the outer body region 21 may be located in the surface layer portion of the low concentration region 11 in the outer peripheral region 9, and may include a portion (outer edge portion) that forms a pn-junction portion with the low concentration region 11. In this configuration, the depletion layer expands directly from the outer body region 21 to the low concentration region 11. Therefore, the range of the depletion layer is appropriately expanded in the peripheral edge portion (outer peripheral region 9) of the chip 2.

In this case, the terminal region 40 is located on the peripheral edge side of the chip 2 with respect to the peripheral edge portion of the high concentration region 10 in the surface layer portion of the low concentration region 11. That is, the entire terminal region 40 is located in the surface layer portion of the low concentration region 11. The inner edge portion of the terminal region 40 is connected to the outer edge portion of the outer body region 21 in the surface layer portion of the low concentration region 11. That is, the terminal region 40 forms the overlap region 41 with the outer body region 21 in the surface layer portion of the low concentration region 11.

In this configuration, the depletion layer expands directly from the entire terminal region 40 to the low concentration region 11. Therefore, the range of the depletion layer is appropriately expanded in the peripheral edge portion (outer peripheral region 9) of the chip 2. As a matter of course, the terminal region 40 has a p-type impurity concentration substantially equal to the p-type impurity concentration of the outer body region 21, and may be formed as a portion (lead-out portion) of the outer body region 21.

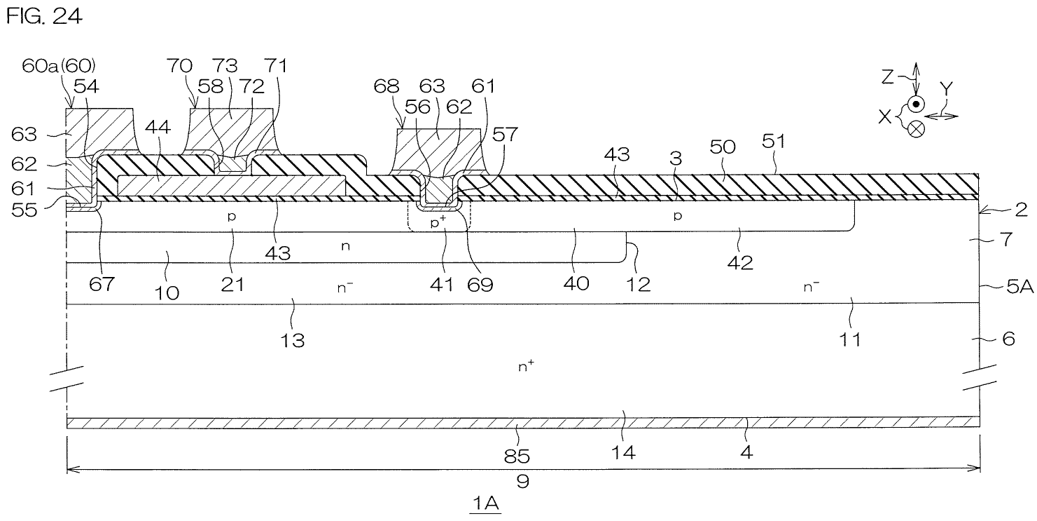

FIG. 24 is a cross-sectional view illustrating a modification example of the field region 42. FIG. 24 illustrates a configuration in which the configuration according to the modification example is applied to the semiconductor device 1A (first embodiment). On the other hand, the configuration according to the modification example can be applied to all of the semiconductor devices 1A to 1I (first to ninth embodiments). In each of the embodiments described above, an example is illustrated in which the field regions 42 are formed in the surface layer portion of the low concentration region 11. On the other hand, as illustrated in FIG. 24, a single field region 42 may be formed in the surface layer portion of the low concentration region 11.

The single field region 42 is formed in a region between the terminal region 40 and the outer body region 21 at an interval inwardly from the peripheral edge of the first main surface 3. The single field region 42 extends in a band shape along the terminal region 40 in a plan view. The single field region 42 includes a portion extending in a band shape in the first direction X and a portion extending in a band shape in the second direction Y in a plan view, and defines the active region 8 from a plurality of directions.

The single field region 42 surrounds the terminal region 40 in a plan view, and is defined in a polygonal round shape (in this embodiment, a quadrangular round shape) having four sides parallel to the peripheral edge of the first main surface 3. The single field region 42 may include an edge portion that connects the portion extending in the first direction X and the portion extending in the second direction Y in an arc shape (preferably, a quarter arc shape) in a plan view.

A ratio of the width of the single field region 42 to the width of the low concentration region 11 may be equal to or larger than 0.1 and smaller than 1. The ratio of the width may have a value in at least one range among a range of 0.1 or larger and 0.2 or smaller, a range of 0.2 or larger and 0.4 or smaller, a range of 0.4 or larger and 0.6 or smaller, a range of 0.6 or larger and 0.8 or smaller, and a range of 0.8 or larger and smaller than 1.

The single field region 42 is formed at an interval from the bottom portion of the low concentration region 11 toward the first main surface 3 side, and opposes the base region 14 across a portion of the low concentration region 11. The single field region 42 is formed at an interval from the depth position of the bottom portion of the high concentration region 10 toward the first main surface 3 side. Preferably, the single field region 42 is formed at an interval from the depth position of the intermediate portion of the high concentration region 10 toward the first main surface 3 side. As a matter of course, the single field region 42 may traverse the depth position of the intermediate portion of the high concentration region 10 in the thickness direction.

The single field region 42 includes an inner edge portion on the terminal region 40 side and an outer edge portion on the peripheral edge side of the first main surface 3. In this embodiment, the inner edge portion of the single field region 42 is connected to the outer edge portion of the terminal region 40. Thereby, the single field region 42 is electrically connected to the terminal region 40. In this embodiment, the inner edge portion of the single field region 42 is connected to the outer edge portion of the terminal region 40 over the entire periphery.

In a case where the single field region 42 has a p-type impurity concentration substantially equal to the p-type impurity concentration of the terminal region 40, the single field region 42 may be led out as a lead-out portion of the terminal region 40 from the terminal region 40 to the surface layer portion of the low concentration region 11. That is, the terminal region 40 may include the single field region 42 as a lead-out portion. As a matter of course, the single field region 42 may be formed at an interval from the terminal region 40.

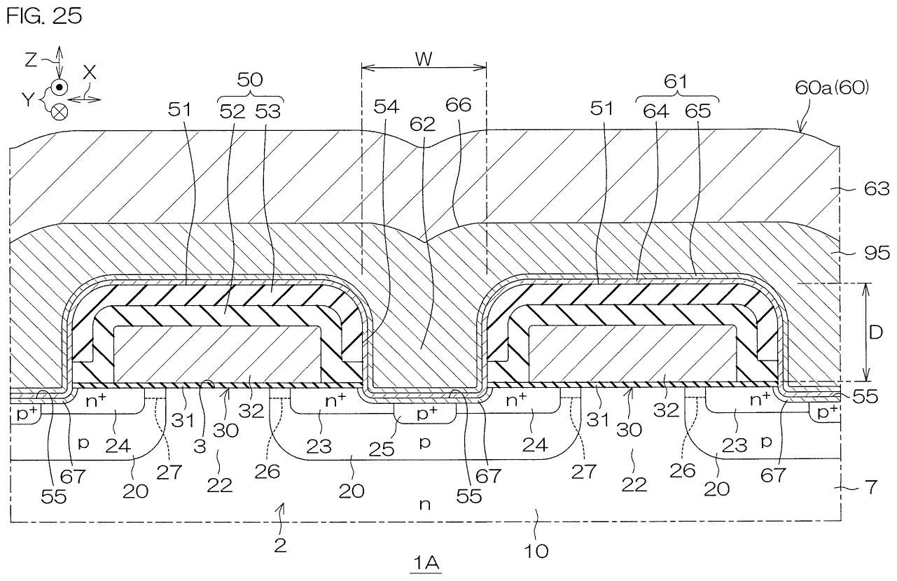

FIG. 25 is a cross-sectional view illustrating a first modification example of the source pad

electrode 60. FIG. 25 illustrates a configuration in which the configuration according to the modification example is applied to the semiconductor device 1A (first embodiment). On the other hand, the configuration according to the modification example can be applied to all of the semiconductor devices 1A to 1E (first to fifth embodiments).

In the first to fifth embodiments described above, the first embedded electrodes 62 are embedded in the source openings 54 such as to expose the insulating surface 51. However, as illustrated in FIG. 25, the source pad electrode 60 may include the first embedded electrodes 62 that are led out from the source openings 54 onto the insulating surface 51 and cover the insulating surface 51.

The first embedded electrodes 62 cover the first underlying electrode film 61 on the insulating surface 51, and includes a portion that covers the insulating surface 51 across the first underlying electrode film 61. That is, each of the first embedded electrodes 62 has the first embedded electrode surface 66 exposed from the source openings 54 above the insulating surface 51. The first embedded electrodes 62 includes a portion that opposes the gate electrode 32 across the first underlying electrode film 61 and the interlayer film 50 in the lamination direction (vertical direction Z).

The first embedded electrodes 62 are integrated on the insulating surface 51, and one intermediate electrode 95 is formed. The intermediate electrode 95 (the first embedded electrodes 62) covers the entire region of the first underlying electrode film 61. The electrode surface (first embedded electrode surface 66) of the intermediate electrode 95 is located above the insulating surface 51.

In this embodiment, the first main electrode film 63 is mechanically and electrically connected to the first embedded electrode surfaces 66 of the first embedded electrodes 62 (intermediate electrode 95) above the insulating surface 51. The first main electrode film 63 includes a portion that opposes the insulating surface 51 across the first embedded electrodes 62 (intermediate electrode 95). In this embodiment, the first main electrode film 63 does not include a mechanical connection portion with the first underlying electrode film 61.

The configuration of the first embedded electrodes 62 (intermediate electrode 95) according to the modification example can also be applied to the first embedded electrodes 62 of the source finger electrode 68. Similarly, the configuration of the first embedded electrodes 62 (intermediate electrode 95) according to the modification example can also be applied to the second embedded electrodes 72 of the gate finger electrode 70.

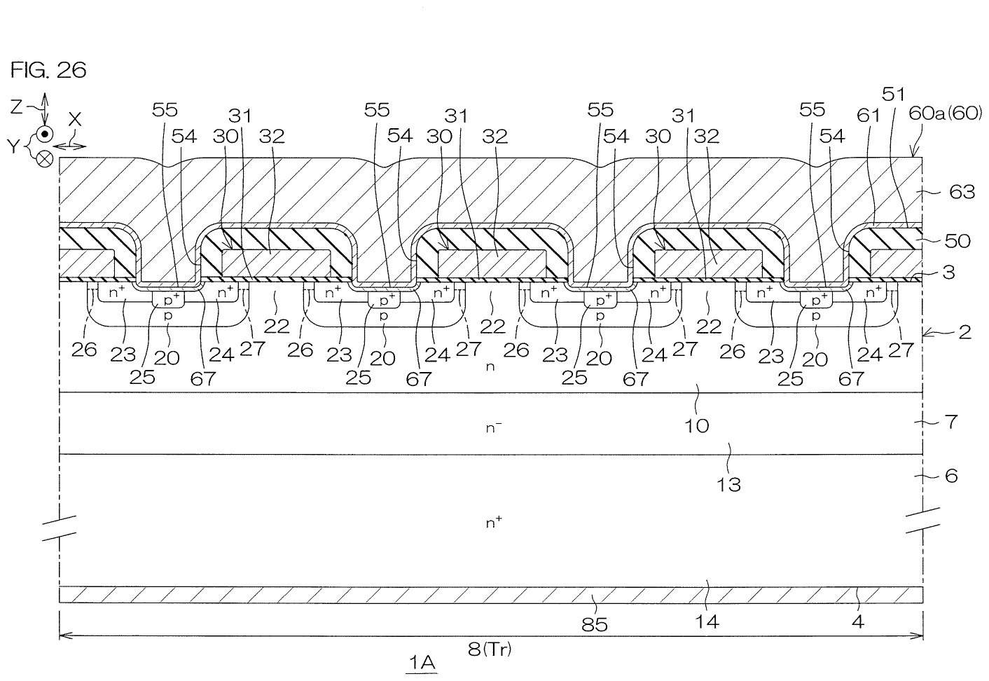

FIG. 26 is a cross-sectional view illustrating a second modification example of the source pad electrode 60. FIG. 26 illustrates a configuration in which the configuration according to the modification example is applied to the semiconductor device 1A (first embodiment). On the other hand, the configuration according to the modification example can be applied to all of the semiconductor devices 1A to 1E (first to fifth embodiments).

In the first to fifth embodiments described above, the source pad electrode 60 includes the first embedded electrodes 62. However, the source pad electrode 60 does not necessarily include the first embedded electrodes 62. In this case, the first main electrode film 63 of the source pad electrode 60 enters the source openings 54 from above the interlayer film 50, and is electrically connected to the body regions 20, etc., in the source openings 54.

Similarly, the source finger electrode 68 does not necessarily include the first embedded electrodes 62. In this case, the first main electrode film 63 of the source finger electrode 68 enters the outer openings 56 from above the interlayer film 50, and is electrically connected to the terminal region 40 (overlap region 41) in the outer openings 56.

Similarly, the gate finger electrode 70 does not necessarily include the second embedded electrodes 72. In this case, the second main electrode film 73 of the gate finger electrode 70 enters the gate openings 58 from above the interlayer film 50, and is electrically connected to the gate wiring 44 in the gate openings 58.

The semiconductor devices 1A to 1E may include the first embedded electrodes 62 for the source pad electrode 60, but may not include the first embedded electrodes 62 for the source finger electrode 68. The semiconductor devices 1A to 1E may include the first embedded electrodes 62 for the source finger electrode 68, but may not include the first embedded electrodes 62 for the source pad electrode 60.

The semiconductor devices 1A to 1E may include the first embedded electrodes 62 for the source pad electrode 60, but may not include the second embedded electrodes 72. The semiconductor devices 1A to 1E may include the second embedded electrodes 72, but may not include the first embedded electrodes 62 for the source pad electrode 60. The semiconductor devices 1A to 1E may include the first embedded electrodes 62 for the source finger electrode 68, but may not include the second embedded electrodes 72. The semiconductor devices 1A to 1E may include the second embedded electrodes 72, but may not include the first embedded electrodes 62 for the source finger electrode 68.

The above-described embodiments (including the modification examples) can be implemented in still other forms. For example, in the above-described embodiments, a configuration in which the relationship between the a-axis direction and the m-axis direction is interchanged may be adopted. A specific configuration in this case can be obtained by interchanging “a-axis direction (off direction)” and “m-axis direction (direction orthogonal to off direction)” in the above description and the accompanying drawings.

In the above-described embodiments, a structure in which the conductivity type of the “n-type” semiconductor region is inverted to the “p-type” and the conductivity type of the “p-type” semiconductor region is inverted to the “n-type” may be adopted. A specific configuration in this case can be obtained by replacing the “n-type” with the “p-type” at the same time as replacing the “p-type” with the “n-type” in the above descriptions and accompanying drawings.

In the embodiments described above, the chip 2 including an SiC single crystal is adopted. On the other hand, the chip 2 may include a single crystal of a wide bandgap semiconductor other than the SiC single crystal. The wide bandgap semiconductor is a semiconductor having a bandgap greater than a bandgap of silicon. Examples of the single crystal of the wide bandgap semiconductor include gallium nitride, gallium oxide, and diamond. As a matter of course, the chip 2 may include a silicon single crystal.

Similarly, the first semiconductor region 6 may include a single crystal of a wide bandgap semiconductor other than the SiC single crystal. The first semiconductor layer 6 may include gallium nitride, gallium oxide, diamond, etc. As a matter of course, the first semiconductor layer 6 may include a silicon single crystal.

Similarly, the second semiconductor layer 7 may include a single crystal of a wide bandgap semiconductor other than the SiC single crystal. The second semiconductor layer 7 may include gallium nitride, gallium oxide, diamond, etc. As a matter of course, the second semiconductor layer 7 may include a silicon single crystal.

In the first to fifth embodiments described above, the n-type base region 14 is illustrated. However, a p-type base region 14 may be adopted instead of the n-type base region 14. In this case, an insulated gate bipolar transistor (IGBT) structure is formed in place of the MISFET structure. In this case, in the above descriptions, the “source” of the MISFET structure is replaced with an “emitter” of the IGBT structure and the “drain” of the MISFET structure is replaced with a “collector” of the IGBT structure. The p-type base region 14 may be an impurity region including p-type impurities introduced into the surface layer portion of the second main surface 4 of the chip 2 (n-type chip 2) by an ion implantation method.

In the sixth to ninth embodiments described above, the Schottky barrier diode (SBD) structure is illustrated as an example of the diode structure Di. However, the diode structure Di may include at least one of a pn-junction diode, a pin junction diode, a Zener diode, and a fast recovery diode. In these cases, the diode structure Di may include one or more p-type anode regions that form a pn-junction portion with the high concentration region 10 in the surface layer portion of the high concentration region 10.

Hereinafter, examples of features extracted from this description and the attached drawings are indicated. Hereinafter, the alphanumeric characters, etc., in parentheses represent the corresponding components, etc., in the embodiments described above, but are not intended to limit the scope of each clause to the embodiments described above. The “semiconductor device” in the following clauses may be replaced with an “SiC semiconductor device,” a “wide bandgap semiconductor device,” a “semiconductor switching device,” an “MISFET device,” an “IGBT device,” a “semiconductor rectifier device,” etc., as needed.
[A1] A semiconductor device (1A to 1I) comprising: a chip (2) that has a main surface (3); a high concentration region (10) of a first conductivity type (n-type) that is formed in a surface layer portion of the main surface (3) on an inner portion side of the chip (2); and a low concentration region (11) of the first conductivity type (n-type) that is formed in the surface layer portion of the main surface (3) on a peripheral edge portion side of the chip (2), and has an impurity concentration lower than an impurity concentration of the high concentration region (10).
[A2] The semiconductor device (1A to 1I) according to A1, wherein the chip (2) includes SiC.
[A3] The semiconductor device (1A to 1I) according to A1 or A2, wherein the chip (2) has a side surface (5A to 5D), the high concentration region (10) is formed at an interval from the side surface (5A to 5D), and the low concentration region (11) is exposed from the side surface (5A to 5D).
[A4] The semiconductor device (1A to 1I) according to any one of A1 to A3, wherein the low concentration region (11) extends in a band shape along the high concentration region (10) in a plan view.
[A5] The semiconductor device (1A to 1I) according to any one of A1 to A4, wherein the low concentration region (11) surrounds the high concentration region (10) in a plan view.
[A6] The semiconductor device (1A to 1I) according to any one of A1 to A5, wherein the low concentration region (11) is connected to the high concentration region (10).
[A7] The semiconductor device (1A to 1I) according to any one of A1 to A6, further comprising: an inner low concentration region (13) of the first conductivity type (n-type) that is formed in a region below the high concentration region (10) on the inner portion side of the chip (2), and has an impurity concentration lower than the impurity concentration of the high concentration region (10).
[A8] The semiconductor device (1A to 1I) according to A7, wherein the inner low concentration region (13) is connected to the low concentration region (11) on the peripheral edge portion side of the chip (2).
[A9] The semiconductor device (1A to 1I) according to any one of A1 to A8, further comprising: an outer high concentration region (15) of a first conductivity type (n-type) that is formed in a region below the low concentration region (11) on the peripheral edge portion side of the chip (2), and has an impurity concentration higher than the impurity concentration of the low concentration region (11).
[A10] The semiconductor device (1A to 1I) according to A9, wherein the outer high concentration region (15) is connected to the high concentration region (10) on the inner portion side of the chip (2).
[A11] The semiconductor device (1A to 1I) according to any one of A1 to A10, further comprising: a base region (14) of the first conductivity type (n-type) that is formed in a region below the high concentration region (10) on the inner portion side of the chip (2), and has an impurity concentration higher than the impurity concentration of the high concentration region (10).
[A12] The semiconductor device (1A to 1I) according to any one of A1 to A11, further comprising: impurity regions (20, 21, 40) of a second conductivity type (p-type) that is formed in a surface layer portion of the high concentration region (10).
[A13] The semiconductor device (1A to 1I) according to any one of A1 to A12, further comprising: a field region (42) of a second conductivity type (p-type) and is formed in a surface layer portion of the low concentration region (11).
[A14] A semiconductor device (1A to 1I) comprising: a chip (2) that has a main surface (3); an active region (8) that is provided in an inner portion of the main surface (3); an outer peripheral region (9) that is provided in a peripheral edge portion of the main surface (3); a high concentration region (10) of the first conductivity type (n-type) and is formed in a surface layer portion of the main surface (3) in the active region (8); and a low concentration region (11) of the first conductivity type (n-type) that is formed in the surface layer portion of the main surface (3) in the outer peripheral region (9), and has an impurity concentration lower than an impurity concentration of the high concentration region (10).
[A15] The semiconductor device (1A to 1I) according to A14, wherein the chip (2) includes SiC.
[A16] The semiconductor device (1A to 1I) according to A14 or A15, further comprising: a field region (42) of a second conductivity type (p-type) that is formed in a surface layer portion of the low concentration region (11) in the outer peripheral region (9).
[A17] The semiconductor device (1A to 1I) according to A16, wherein the field region (42) is formed in the surface layer portion of the low concentration region (11) at an interval from the high concentration region (10).
[A18] The semiconductor device (1A to 1I) according to any one of A14 to A17, further comprising: an impurity region (20, 21, 40) of a second conductivity type that is formed in a surface layer portion of the high concentration region (10) in the active region (8).
[A19] The semiconductor device (1A to 1I) according to any one of A14 to A18, further comprising: a terminal region (40) of a second conductivity type (p-type) that is formed in any one or both of a surface layer portion of the high concentration region (10) and a surface layer portion of the low concentration region (11) in the outer peripheral region (9).
[A20] The semiconductor device (1A to 1I) according to any one of A14 to A19, further comprising: a device structure (Tr, Di) that includes the high concentration region (10) and is formed in the active region (8).

While specific embodiments have been described in detail above, these are merely specific examples used to clarify the technical contents. The various technical ideas extracted from this description can be combined as appropriate with each other without being limited by the order of description, the order of configuration examples, the order of modification examples, etc., in this description.

What is claimed is:

1. A semiconductor device comprising:
a chip that has a main surface;
a high concentration region of a first conductivity type that is formed in a surface layer portion of the main surface on an inner portion side of the chip; and
a low concentration region of the first conductivity type that is formed in the surface layer portion of the main surface on a peripheral edge portion side of the chip, and has an impurity concentration lower than an impurity concentration of the high concentration region.

2. The semiconductor device according to claim 1,
wherein the chip includes SiC.

3. The semiconductor device according to claim 1,
wherein the chip has a side surface,
the high concentration region is formed at an interval from the side surface, and
the low concentration region is exposed from the side surface.

4. The semiconductor device according to claim 1,
wherein the low concentration region extends in a band shape along the high concentration region in a plan view.

5. The semiconductor device according to claim 4,
wherein the low concentration region surrounds the high concentration region in a plan view.

6. The semiconductor device according to claim 1,
wherein the low concentration region is connected to the high concentration region.

7. The semiconductor device according to claim 1, further comprising:
an inner low concentration region of the first conductivity type that is formed in a region below the high concentration region on the inner portion side of the chip, and has an impurity concentration lower than the impurity concentration of the high concentration region.

8. The semiconductor device according to claim 7,
wherein the inner low concentration region is connected to the low concentration region on the peripheral edge portion side of the chip.

9. The semiconductor device according to claim 1, further comprising:
an outer high concentration region of the first conductivity type that is formed in a region below the low concentration region on the peripheral edge portion side of the chip, and have an impurity concentration higher than the impurity concentration of the low concentration region.

10. The semiconductor device according to claim 9,
wherein the outer high concentration region is connected to the high concentration region on the inner portion side of the chip.

11. The semiconductor device according to claim 1, further comprising:
a base region of the first conductivity type that is formed in a region below the high concentration region on the inner portion side of the chip, and has an impurity concentration higher than the impurity concentration of the high concentration region.

12. The semiconductor device according to claim 1, further comprising:
an impurity region of a second conductivity type that is formed in a surface layer portion of the high concentration region.

13. The semiconductor device according to claim 1, further comprising:
a field region of a second conductivity type that is formed in a surface layer portion of the low concentration region.

14. A semiconductor device comprising:
a chip that has a main surface;
an active region that is provided in an inner portion of the main surface;
an outer peripheral region that is provided in a peripheral edge portion of the main surface;
a high concentration region of a first conductivity type that is formed in a surface layer portion of the main surface in the active region; and
low concentration region of the first conductivity type that is formed in the surface layer portion of the main surface in the outer peripheral region, and has an impurity concentration lower than an impurity concentration of the high concentration region.

15. The semiconductor device according to claim 14,
wherein the chip includes SiC.

16. The semiconductor device according to claim 14, further comprising:
a field region of a second conductivity type that is formed in a surface layer portion of the low concentration region in the outer peripheral region.

17. The semiconductor device according to claim 16,
wherein the field region is formed in the surface layer portion of the low concentration region at an interval from the high concentration region.

18. The semiconductor device according to claim 14, further comprising:
an impurity region of a second conductivity type and is formed in a surface layer portion of the high concentration region in the active region.

19. The semiconductor device according to claim 14, further comprising:
a terminal region of a second conductivity type that is formed in any one or both of a surface layer portion of the high concentration region and a surface layer portion of the low concentration region in the outer peripheral region.

20. The semiconductor device according to claim 14, further comprising:
a device structure that includes the high concentration region and is formed in the active region.
